(19) United States
(12) Patent Application Publication
(10) Pub. No.: US 2026/0353636 A1
(43) Pub. Date: Nov. 5, 2026

(54) SEMICONDUCTOR DEVICE INCLUDING BACK GATE ELECTRODE STRUCTURE AND METHOD OF FABRICATING THE SAME

(71) Applicant: SAMSUNG ELECTRONICS CO., LTD., Suwon-si (KR)

(72) Inventor: Moonyoung JEONG, Suwon-si (KR)

(73) Assignee: SAMSUNG ELECTRONICS CO., LTD., Suwon-si (KR)

(21) Appl. No.: 19/441,244

(22) Filed: Jan. 6, 2026

(30) Foreign Application Priority Data
May 2, 2025 (KR) 10-2025-0058153

(51) Int. Cl. H10B 12/00; H10D 1/68; H10D 30/60; H10W 90/00

(52) U.S. Cl. CPC H10B 12/315; H10B 12/05; H10B 12/09; H10B 12/482; H10B 12/488; H10B 12/50; H10D 1/716; H10D 30/611; H10W 90/734

(57) ABSTRACT

A semiconductor device includes a bit line extending in a first direction, a word line extending in a second direction that intersecting the first direction, the word line being above the bit line in a third direction intersecting the first direction and the second direction, a back gate electrode structure above the bit line in the third direction, spaced apart from the word line in the first direction, and extending in the second direction, and an active pattern, on the bit line, between the word line and the back gate electrode structure in the first direction and extending in the third direction, where a height of the back gate electrode structure in the third direction is smaller than a height of the word line in the third direction.

### CROSS-REFERENCE TO RELATED APPLICATION

This application is based on and claims priority to Korean Patent Application No. 10-2025-0058153, filed on May 2, 2025, in the Korean Intellectual Property Office, the disclosure of which is incorporated herein by reference in its entirety.

### BACKGROUND

The disclosure relates to a semiconductor device and a method of fabricating the same.

To ensure high performance and inexpensive price, increasing the integration density of semiconductor devices is required. Since the integration density of semiconductor devices is a main factor in pricing a product, increased integration density is needed in particular.

The integration density of two-dimensional (2D) or planar semiconductor devices is generally determined by an area occupied by a unit memory cell, and thus, is largely affected by a level of the fine patterning technology. However, since high-priced equipment is used for fine patterning, the integration density of 2D semiconductor devices is increasing but still limited. Accordingly, semiconductor devices including a vertical channel transistor (VCT) in which a channel extends vertically are suggested.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor device in which electrical reliability may be enhanced.

One or more example embodiments provide a semiconductor device in which a risk of leakage current may be reduced.

Additional aspects will be set forth in part in the description which follows and, in part, will be apparent from the description, or may be learned by practice of the presented embodiments.

According to an aspect of an example embodiment, a semiconductor device may include a bit line extending in a first direction, a word line extending in a second direction that intersecting the first direction, the word line being above the bit line in a third direction intersecting the first direction and the second direction, a back gate electrode structure above the bit line in the third direction, spaced apart from the word line in the first direction, and extending in the second direction, and an active pattern, on the bit line, between the word line and the back gate electrode structure in the first direction and extending in the third direction, where a height of the back gate electrode structure in the third direction is smaller than a height of the word line in the third direction, and where the back gate electrode structure includes least one back gate work function adjustment pattern and a back gate body pattern contacting the at least one back gate work function adjustment pattern in the third direction.

According to an aspect of an example embodiment, a semiconductor device may include a plurality of bit lines extending in a first direction and spaced apart from each other in a second direction intersecting the first direction, a back gate electrode structure extending in the second direction and being above the plurality of bit lines in a third direction intersecting the first direction and the second direction, a first active pattern on the plurality of bit lines, at a first side of the back gate electrode structure in the first direction and extending in the third direction, a second active pattern on the plurality of bit lines, at a second side of the back gate electrode structure in the first direction and extending in the third direction, a first word line above the plurality of bit lines in the third direction, at the first side of the back gate electrode structure and spaced apart from the back gate electrode structure in the first direction with the first active pattern in–between in the first direction, and a second word line above the plurality of bit lines in the third direction, at the second side of the back gate electrode structure and spaced apart from the back gate electrode structure in the first direction with the second active pattern in-between in the first direction, where the back gate electrode structure includes a first back gate work function adjustment pattern, a back gate body pattern, and a second back gate work function adjustment pattern, which are stacked in sequence in the third direction and a work function of each of the first back gate work function adjustment pattern and the second back gate work function adjustment pattern is greater than a work function of the back gate body pattern.

According to an aspect of an example embodiment, a semiconductor device may include a bit line extending in a first direction, a word line extending in a second direction intersecting the first direction, the word line being above the bit line in a third direction intersecting the first direction and the second direction, a back gate electrode structure above the bit line in the third direction, spaced apart from the word line in the first direction and extending in the second direction, an active pattern on the bit line, between the word line and the back gate electrode structure in the first direction and extending in the third direction, and a data storage pattern above the active pattern in the third direction and connected to the active pattern, where a first surface and a second surface of the back gate electrode structure in the third direction are between a first surface and a second surface of the word line in the third direction, the back gate electrode structure includes a first back gate work function adjustment pattern, a back gate body pattern, and a second back gate work function adjustment pattern, which are stacked in sequence in the third direction, and a work function of each of the first back gate work function adjustment pattern and the second back gate work function adjustment pattern is greater than a work function of the back gate body pattern.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram showing a schematic layout of a semiconductor device according to some example embodiments;

FIG. 2 is a diagram showing cross-sections taken along A-A and B-B of FIG. 1;

FIG. 3 is a diagram showing cross-sections taken along C-C and D-D of FIG. 1;

FIG. 4 is an enlarged view of part P of FIG. 2;

FIG. 5 is an enlarged view of part P of FIG. 2 for illustrating a semiconductor device according to example embodiments;

FIG. 6 is an enlarged view of part P of FIG. 2 for illustrating a semiconductor device according to example embodiments;

FIG. 7 is an enlarged view of part P of FIG. 2 for illustrating a semiconductor device according to example embodiments;

FIG. 8 is an enlarged view of part P of FIG. 2 for illustrating a semiconductor device according to example embodiments;

FIG. 9 is an enlarged view of part P of FIG. 2 for illustrating a semiconductor device according to example embodiments;

FIG. 10 is an enlarged view of part P of FIG. 2 for illustrating a semiconductor device according to example embodiments;

FIG. 11 is an enlarged view of part P of FIG. 2 for illustrating a semiconductor device according to example embodiments;

FIG. 12 is an enlarged view of part P of FIG. 2 for illustrating a semiconductor device according to example embodiments;

FIG. 13 is an enlarged view of part P of FIG. 2 for illustrating a semiconductor device according to example embodiments;

FIG. 14 is an enlarged view of part P of FIG. 2 for illustrating a semiconductor device according to example embodiments;

FIG. 15 is an enlarged view of part P of FIG. 2 for illustrating a semiconductor device according to example embodiments;

FIG. 16 is an enlarged view of part P of FIG. 2 for illustrating a semiconductor device according to example embodiments;

FIG. 17 is an enlarged view of part P of FIG. 2 for illustrating a semiconductor device according to example embodiments; and

FIGS. 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 4950, 51, 52, 53, 54, 55, 56, 57, 58, 59, 60, 61, 62, 63, 64, 65, 66, 67, 68, 69, 70 and 71 are diagrams illustrating operations of a method of fabricating a semiconductor device according to some example embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, "at least one of a, b, and c," should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

Terms such as first, second, etc. may be used to describe various components, but are used only for the purpose of distinguishing one component from another component. These terms do not limit the difference in the material or structure of the components.

The terms of a singular form may include plural forms unless otherwise specified. In addition, when a certain part “includes” a certain component, it means that other components may be further included rather than excluding other components unless otherwise stated.

The use of the term “the” and similar designating terms may correspond to both the singular and the plural.

Operations of a method may be performed in an appropriate order unless explicitly described in terms of order. In addition, the use of all illustrative terms (e.g., etc.) is merely for describing technical ideas in detail, and the scope is not limited by these examples or illustrative terms unless limited by the claims.

Hereinafter, example embodiments of the present disclosure are described with reference to the accompanying drawings.

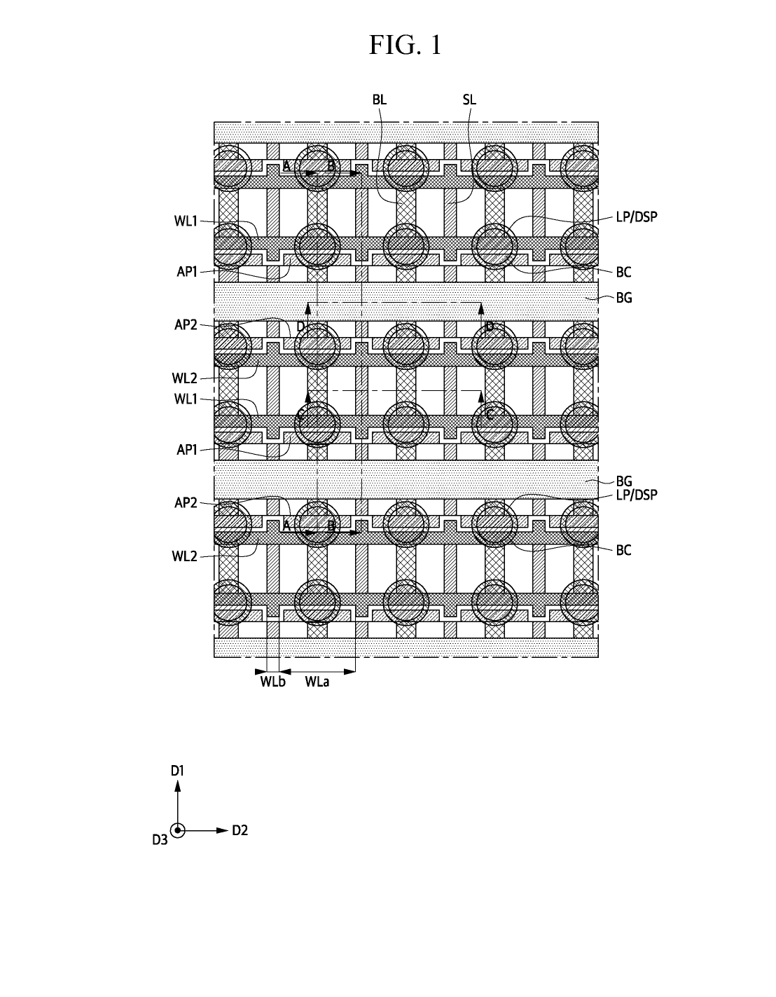

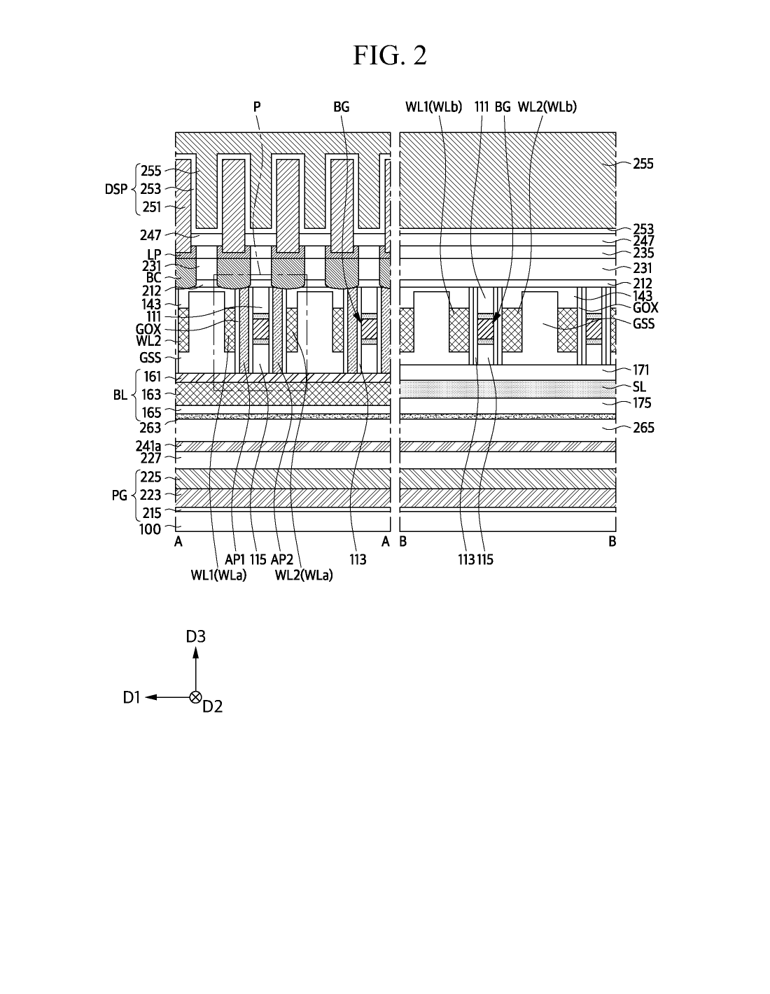

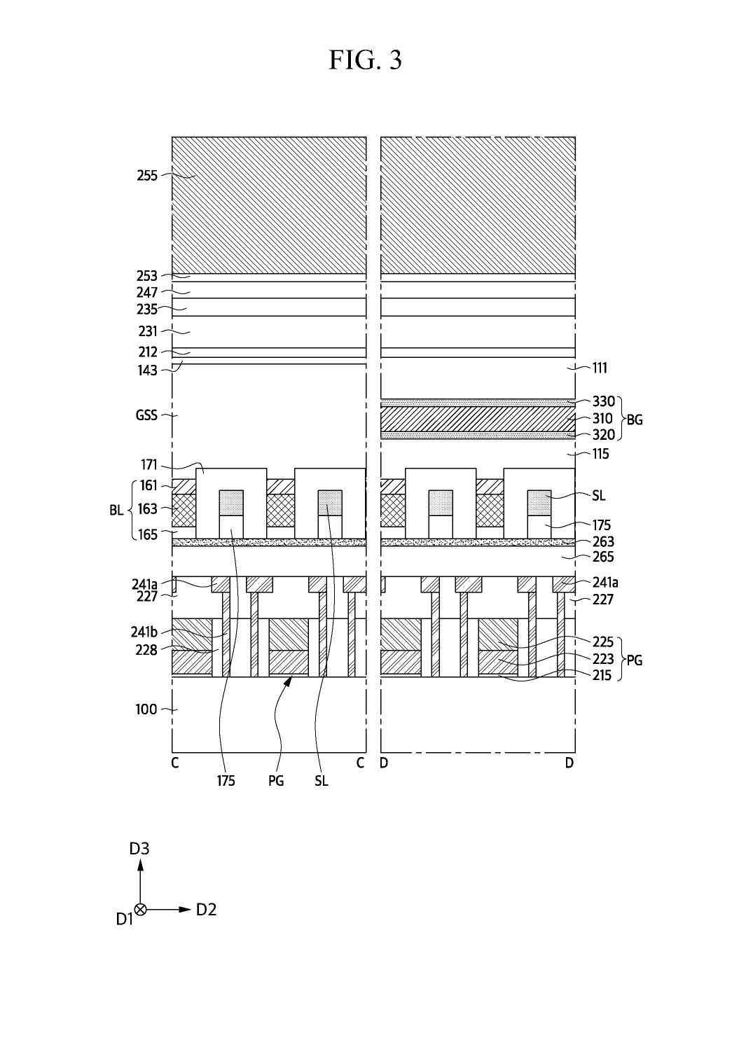

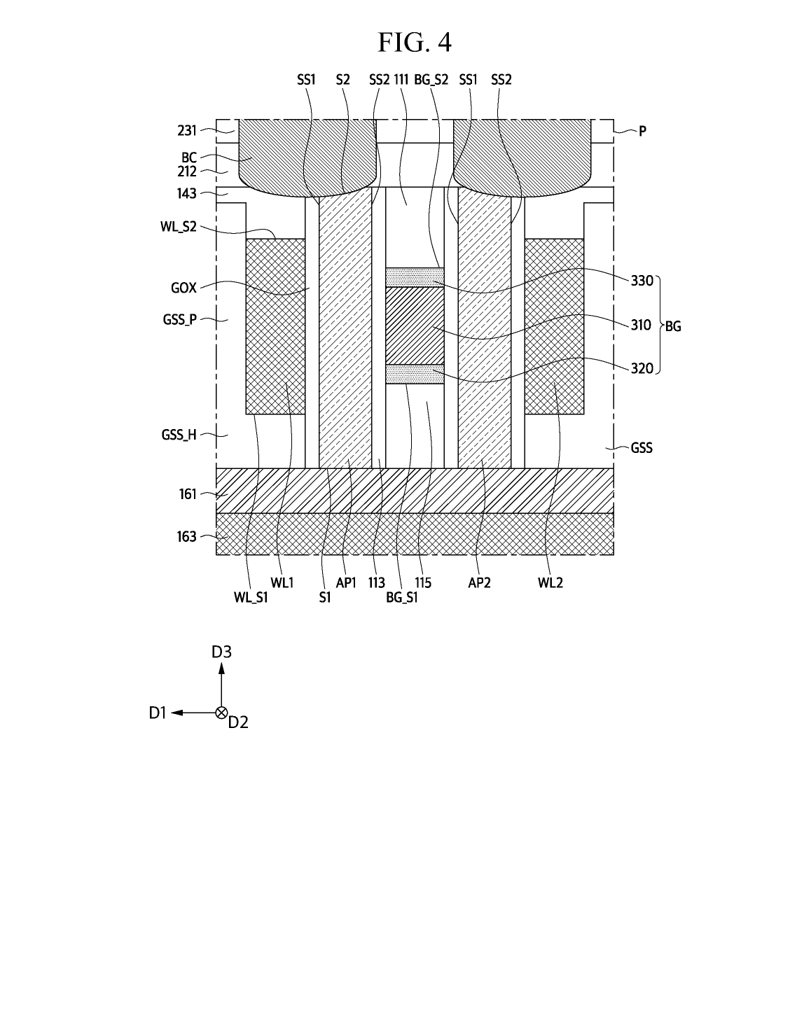

FIG. 1 is a diagram showing a schematic layout of a semiconductor device according to some example embodiments. FIG. 2 is a diagram showing cross-sections taken along A-A and B-B of FIG. 1. FIG. 3 is a diagram showing cross-sections taken along C-C and D-D of FIG. 1. FIG. 4 is an enlarged view of part P of FIG. 2.

Referring to FIGS. 1 - 4, the semiconductor device according to some example embodiments may include a bit line BL, a plurality of word lines WL1 and WL2, a back gate electrode structure BG, a shielding line SL, a plurality of active patterns AP1 and AP2, and a data storage pattern DSP.

According to some example embodiments, a substrate 100 may be, as an example, a silicon substrate. As another example, the substrate 100 may include silicon germanium, indium antimonide, lead telluride, indium arsenide, indium phosphide, gallium arsenide, or gallium antimonide, but is not limited thereto. The substrate 100 may include a cell array region where the data storage pattern DSP is disposed and a peripheral circuit region defined on the periphery of the cell array region.

According to some example embodiments, a peri-gate structure PG may be disposed on the substrate 100. The peri-gate structure PG may be disposed across the cell array region and the peripheral circuit region. The peri-gate structure PG may be included in a sensing transistor, a transmission transistor, and a driver transistor. For example, the peri-gate structure PG included in the sensing transistor may be disposed on the cell array region of the substrate 100, but is not limited thereto. The type of a transistor of a peripheral circuit disposed on the substrate 100 of the cell array region may vary depending on a design layout of the semiconductor device.

According to some example embodiments, the peri-gate structure PG may include a peri-gate insulating layer 215, a peri-gate conductive pattern 223, and a peri-gate mask pattern 225. The peri-gate insulating layer 215 may include a silicon oxide layer, a silicon oxynitride layer, a high-permittivity insulating layer having a dielectric constant higher than that of a silicon oxide layer, or a combination thereof. For example, the high-permittivity insulating layer may include, but is not limited to, metal oxide, metal oxynitride, metal silicon oxide, metal silicon oxynitride, or a combination thereof. The peri-gate conductive pattern 223 may include a conductive material, for example, a doped semiconductor material, conductive metal nitride, conductive metal silicon nitride, metal carbonitride, conductive metal silicide, conductive metal oxide, a two-dimensional (2D) material, metal, or a combination thereof. The peri-gate mask pattern 225 may include an insulating material.

In the semiconductor device according to some example embodiments, the 2D material may be a metallic material and/or a semiconductor material. The 2D material may include a 2D allotrope or a 2D compound and include, for example, graphene, molybdenum disulfide (MoS2), molybdenum diselenide (MoSe2), tungsten diselenide (WSe2), tungsten disulfide (WS2), or a combination thereof, but is not limited thereto. Since the 2D materials described above are enumerated merely for example, the 2D material that may be included in the semiconductor device of the present disclosure is not limited to the above materials.

According to some example embodiments, a first peri-lower insulating layer 227 and a second peri-lower insulating layer 228 may be disposed above the substrate 100. Each of the first peri-lower insulating layer 227 and the second peri-lower insulating layer 228 may include an insulating material. For example, each of the first peri-lower insulating layer 227 and the second peri-lower insulating layer 228 may include at least one of silicon nitride (SiN), silicon oxynitride (SiON), silicon oxide (SiO2), silicon carbonitride (SiCN), silicon oxycarbonitride (SiOCN), and a combination thereof.

According to some example embodiments, a peri-wiring line 241a and a peri-contact plug 241b may be disposed in the first peri-lower insulating layer 227 and the second peri-lower insulating layer 228. The peri-wiring line 241a and the peri-contact plug 241b are illustrated as different layers but are not limited thereto. A boundary between the peri-wiring line 241a and the peri-contact plug 241b may not be defined. Each of the peri-wiring line 241a and the peri-contact plug 241b may include a conductive material.

According to some example embodiments, a peri-upper insulating layer 265 may be disposed above the peri-wiring line 241a and the peri-contact plug 241b. The peri-upper insulating layer 265 may include an insulating material. For example, the peri-upper insulating layer 265 may include at least one of silicon nitride (SiN), silicon oxynitride (SiON), silicon oxide (SiO2), silicon carbonitride (SiCN), silicon oxycarbonitride (SiOCN), and a combination thereof. A peri-upper insulating layer including a multilayer may be disposed above the peri-wiring line 241a and the peri-contact plug 241b.

According to some example embodiments, a bonding insulating layer 263 may be disposed on the peri-upper insulating layer 265. The bonding insulating layer 263 may be used for wafer bonding. The bonding insulating layer 263 may include, for example, silicon carbonitride (SiCN).

According to some example embodiments, the bit line BL may be disposed above the peri-gate structure PG. For example, the bit line BL may be disposed on the bonding insulating layer 263.

According to some example embodiments, the bit line BL may extend along a first direction D1. The bit line BL may be provided as a plurality of bit lines BL. The plurality of bit lines BL may be spaced apart from each other in a second direction D2. The bit line BL may include a long side wall extending in the first direction D1 and a short side wall extending in the second direction D2. The bit line BL may extend from the cell array region to the peripheral circuit region. An end portion of the bit line BL may be disposed above the peripheral circuit region.

According to some example embodiments, the bit line BL may include a bit line mask pattern 165, a metal pattern 163, and a semiconductor pattern 161, which are stacked in sequence above the substrate 100. The bit line BL may include one of the semiconductor pattern 161 and the metal pattern 163.

According to some example embodiments, the bit line mask pattern 165 may contact the bonding insulating layer 263. The bit line mask pattern 165 may include an insulating material such as silicon nitride and silicon oxynitride.

According to some example embodiments, the metal pattern 163 may be disposed between the bit line mask pattern 165 and the semiconductor pattern 161. The metal pattern 163 may be disposed on the bit line mask pattern 165 and disposed below the semiconductor pattern 161. The metal pattern 163 may include a conductive material including metal. The metal pattern 163 may include, for example, at least one of conductive metal nitride, conductive metal silicon nitride, metal carbonitride, conductive metal silicide, conductive metal oxide, a 2D material, and metal.

According to some example embodiments, the semiconductor pattern 161 may be disposed on the metal pattern 163. The semiconductor pattern 161 may be disposed below the plurality of active patterns AP1 and AP2. The semiconductor pattern 161 may be connected to the plurality of active patterns AP1 and AP2. The semiconductor pattern 161 may include a conductive semiconductor material. The semiconductor pattern 161 may include at least one of polysilicon, polysilicon germanium, poly-germanium, amorphous silicon, amorphous silicon germanium, and amorphous germanium.

According to some example embodiments, a bit line shielding structure 171, SL, and 175 may be disposed above the substrate 100. The bit line shielding structure 171, SL, and 175 may be disposed on the bonding insulating layer 263 and contacting the bonding insulating layer 263. The bit line shielding structure 171, SL, and 175 may be disposed adjacent to the bit line BL. The bit line shielding structure 171, SL, and 175 may be disposed adjacent to the bit line BL in the second direction D2. For example, the bit line shielding structure 171, SL, and 175 may be disposed between the plurality of bit lines BL along the second direction D2. As the bit line shielding structure 171, SL, and 175 is disposed between the plurality of bit lines BL adjacent in the second direction D2, a coupling noise between the bit lines BL may be reduced. The bit line shielding structure 171, SL, and 175 may be disposed below the plurality of word lines WL1 and WL2.

According to some example embodiments, the bit line shielding structure 171, SL, and 175 may include the shielding line SL and a bit line shielding insulating layer 171 and 175. The bit line shielding insulating layer 171 and 175 may include a shielding insulating liner 171 and a shielding insulating capping layer 175. The bit line shielding insulating layer 171 and 175 may surround the perimeter of the shielding line SL. The shielding line SL may be disposed within the bit line shielding insulating layer 171 and 175.

According to some example embodiments, the shielding line SL may extend from the cell array region to the peripheral circuit region. An end portion of the shielding line SL may be disposed above the peripheral circuit region. The shielding line SL may include a conductive material. The shielding line SL may include, for example, at least one of conductive metal nitride, conductive metal silicon nitride, metal carbonitride, conductive metal silicide, conductive metal oxide, a 2D material, and metal.

According to some example embodiments, each of the shielding insulating liner 171 and the shielding insulating capping layer 175 may include an insulating material. If the shielding insulating liner 171 and the shielding insulating capping layer 175 include an identical material, a boundary between the shielding insulating liner 171 and the shielding insulating capping layer 175 may not be defined.

According to some example embodiments, with respect to the bonding insulating layer 263, a height of a conductive bit line 161 and 163 in a third direction D3 is illustrated as being greater than a height of the shielding line SL in the third direction D3, but is not limited thereto.

According to some example embodiments, the shielding line SL may include a first surface and a second surface disposed opposite to each other in the third direction D3. The first surface of the shielding line SL may be a surface facing the bonding insulating layer 263. The metal pattern 163 may include a first surface and a second surface disposed opposite to each other in the third direction D3. The first surface of the metal pattern 163 may be a surface facing the bonding insulating layer 263. With respect to the bonding insulating layer 263, a height of the second surface of the shielding line SL is illustrated as being greater than a height of the second surface of the metal pattern 163, but is not limited thereto. The first surface of the shielding line SL is illustrated as being planar, but is not limited thereto. The first surface of the shielding line SL may be a concavely curved surface.

According to some example embodiments, the plurality of active patterns AP1 and AP2 may include a first active pattern AP1 and a second active pattern AP2. The first active pattern AP1 and the second active pattern AP2 may be disposed on the bit line BL. The first active pattern AP1 and the second active pattern AP2 may be disposed alternately along the first direction D1.

According to some example embodiments, the first active pattern AP1 and the second active pattern AP2 may be provided as a plurality of first active patterns AP1 and a plurality of second active patterns AP2, respectively. The plurality of first active patterns AP1 may be spaced apart from each other in the second direction D2. The plurality of first active patterns AP1 may be spaced apart at predetermined intervals. The plurality of second active patterns AP2 mayAP2 spaced apart from each other in the second direction D2. The plurality of second active patterns AP2 mayAP2 spaced apart at predetermined intervals. The plurality of first active patterns AP1 and the plurality of second active patterns AP2 may be disposed with respect to each other two-dimensionally along the first direction D1 and the second direction D2. The first active pattern AP1 and the second active pattern AP2 may extendAP2 the third direction D3. The third direction D3 may be a direction intersecting with an upper surface of the substrate 100. The semiconductor device according to example embodiments of the present disclosure may include memory cells including a vertical channel transistor (VCT).

According to some example embodiments, the first active pattern AP1 and the second active pattern AP2 may be disposed between a first word line WL1 and a second word line WL2 adjacent in the first direction D1. The first active pattern AP1 may be disposed between second portions WLb of the first word line WL1 adjacent in the second direction D2 and disposed at a side of a first portion WLa of the first word line WL1 in the first direction D1. The second active pattern AP2 may be disposed between the second portions WLb of the second word line WL2 adjacent in the second direction D2 and disposed at a side of the first portion WLa of the second word line WL2 in the first direction D1.

According to some example embodiments, the plurality of active patterns AP1 and AP2 may include, for example, a single-crystal semiconductor material. As an example, each of the first active pattern AP1 and the second active pattern AP2 may include single-crystal silicon.

According to some example embodiments, each of the first active pattern AP1 and the second active pattern AP2 may have a length in the second direction D2, a width in the first direction D1, and a height in the third direction D3. Each of the first active pattern AP1 and the second active pattern AP2 may have a substantially uniform width. A width of the first active pattern AP1 may be identical to a width of the second active pattern AP2.

According to some example embodiments, the width of the first active pattern AP1 and the width of the second active pattern AP2 may range from a few nanometers (nm) to tens of nm. For example, the width of the first active pattern AP1 and the width of the second active pattern AP2 may range from 1 nm to 30 nm, or from 1 nm to 10 nm, but are not limited thereto. A length of each of the plurality of active patterns AP1 and AP2 mayAP2 greater than a line width of the bit line BL. In other words, a length of each of the first active pattern AP1 andAP1e second active pattern AP2 aloAP2the second direction D2 may be greater than a width of the bit line BL in the second direction D2.

Referring to FIG. 4, each of the first active pattern AP1 and the second active pattern AP2 may include a first surface S1 and a second surface S2 disposed opposite to each other in the third direction D3. The first surface S1 of each of the first active pattern AP1 and the second active pattern AP2 may face the bit line BL. As used here, “face the bit line BL” may indicate that, among surfaces of the component, the surface that faces the bit line BL is the surface that is closest to the bit line BL in the third direction D3 (or other directions as will be apparent from the drawings). In a more general definition, as described herein, when a component includes multiple surfaces and one surface is described to face another component (or another surface), it may indicate that the surface that faces the other component is the surface that is closest to that other component among the surfaces when viewed in a respective direction. For example, the first surface S1 of each of the first active pattern AP1 andAP1e second active pattern AP2 may contact the semiconductor pattern 161 of the bit line BL. If the semiconductor pattern 161 is omitted, the first surface S1 of each of the first active pattern AP1 andAP1e second active pattern AP2 may contact the metal pattern 163.

According to some example embodiments, each of the first active pattern AP1 and the second active pattern AP2 may include a first side surface SS1 and a second side surface SS2 disposed opposite to each other in the first direction D1. The second side surface SS2 of the first active pattern AP1 may face the first side surface SS1 of the second active pattern AP2. The first side surface SS1 of the first active pattern AP1 may face the first word line WL1 along the first direction D1. The second side surface SS2 of the second active pattern AP2 mayAP2ce the second word line WL2 along the first direction D1.

According to some example embodiments, each of the first active pattern AP1 and the second active pattern AP2 may include a first dopant region adjacent to the bit line BL and a second dopant region adjacent to a contact pattern BC. Each of the first active pattern AP1 and the second active pattern AP2 may include a channel region between the first dopant region and the second dopant region. The first dopant region and the second dopant region may be regions doped with a dopant within the first active pattern AP1 and the second active pattern AP2. EaAP2of the first active pattern AP1 and the second active pattern AP2 mayAP2t include at least one of the first dopant region and the second dopant region.

According to some example embodiments, when operating the semiconductor device, channel regions of the plurality of active patterns AP1 and AP2 may be controlled by the plurality of word lines WL1 and WL2 and a plurality of back gate electrode structures BG. Since the plurality of active patterns AP1 and AP2 include a single-crystal semiconductor material, the leakage current characteristics of the semiconductor device may be improved.

According to some example embodiments, the plurality of word lines WL1 and WL2 may be disposed above the bit line BL and the shielding line SL. The plurality of word lines WL1 and WL2 may include the first word line WL1 and the second word line WL2. Each of the first word line WL1 and the second word line WL2 may extend in the second direction D2. The first word line WL1 and the second word line WL2 may be disposed alternately in the first direction D1.

According to some example embodiments, the first word line WL1 may be disposed on the first side surface SS1 of the first active pattern AP1. The first word line WL1 may be disposed between a gate separation pattern GSS and the first active pattern AP1. The second word line WL2 may be disposed on the second side surface SS2 of the second active pattern AP2. The second word line WL2 may be disposed between the gate separation pattern GSS and the second active pattern AP2.

According to some example embodiments, the first word line WL1 and the second word line WL2 may be spaced apart from the bit line BL and the contact pattern BC in the third direction D3. The first word line WL1 and the second word line WL2 may be positioned between the bit line BL and the contact pattern BC. The first word line WL1 and the second word line WL2 may be disposed on a horizontal portion GSS_H of the gate separation pattern. The first word line WL1 and the second word line WL2 may be disposed between the horizontal portion GSS_H of the gate separation pattern and the contact pattern BC.

According to some example embodiments, each of the first word line WL1 and the second word line WL2 may have a width in the first direction D1. A width of the first word line WL1 and a width of the second word line WL2 above the bit line BL may be different from a width of the first word line WL1 and a width of the second word line WL2 above the shielding line SL. For example, the width of the first word line WL1 and the width of the second word line WL2 above the bit line BL may be smaller than the width of the first word line WL1 and the width of the second word line WL2 above the shielding line SL.

According to some example embodiments, each of the first word line WL1 and the second word line WL2 may include the first portion WLa of the word line and the second portion WLb of the word line disposed alternately along the second portion D2. A width of the first portion WLa of the word line in the first direction D1 may be smaller than a width of the second portion WLb of the word line in the first direction D1. As an example, the first portion WLa of the word line may be disposed above the bit line BL. The second portion WLb of the word line may be disposed above the shielding line SL.

According to some example embodiments, the first portion WLa of the word line may not overlap with the plurality of active patterns AP1 and AP2 in the second direction D2. The first portion WLa of the word line may be disposed at a side of each of the plurality of active patterns AP1 and AP2 in the first direction D1. The second portion WLb of the word line extend over the plurality of active patterns AP1 and AP2. At least part of the second portion WLb of the word line may be disposed at a side of each of the plurality of active patterns AP1 and AP2 in the second direction D2.

According to some example embodiments, each of the first word line WL1 and the second word line WL2 may include a first surface WL_S1 and a second surface WL_S2 disposed opposite to each other in the third direction D3. The first surface WL_S1 of each of the first word line WL1 and the second word line WL2 may face the bit line BL. The second surface WL_S2 of each of the first word line WL1 and the second word line WL2 may face the data storage pattern DSP.

According to some example embodiments, a description of the second word line WL2 is substantially identical to a description of the first word line WL1, and thus, the first word line WL1 is mainly described below. A height of the first word line WL1 along the third direction D3 may be greater than a height of the back gate electrode structure BG along the third direction D3. However, example embodiments are not limited thereto. As an example, the height of the first word line WL1 aloWL1the third direction D3 may be identical to the height of the back gate electrode structure BG along the third direction D3. As another example, the height of the first word line WL1 aloWL1the third direction D3 may be smaller than the height of the back gate electrode structure BG along the third direction D3.

According to some example embodiments, with respect to the bit line BL, the first surface WL_S1 of the first word line WL1 may be disposed lower than a first surface BG_S1 of the back gate electrode structure. With respect to the bit line BL, a height of the first surface WL_S1 of the first word line WL1 may be smaller than a height of the first surface BG_S1 of the back gate electrode structure. However, example embodiments are not limited thereto. As an example, the first surface WL_S1 of the first word line WL1 may be disposed higher than the first surface BG_S1 of the back gate electrode structure. As another example, the first surface WL_S1 of the first word line WL1 mayWL1 disposed on the same plane as the first surface BG_S1 of the back gate electrode structure. As used herein, “on the same plane” may refer to components or surfaces being substantially coplanar when viewed from a particular direction, with “substantially” allowing minor variances in the level and consistency of said surfaces.

According to some example embodiments, with respect to the bit line BL, the second surface WL_S2 of the first word line WL1 may be disposed higher than a second surface BG_S2 of the back gate electrode structure. With respect to the bit line BL, a height of the second surface WL_S2 of the first word line WL1 may be greater than a height of the second surface BG_S2 of the back gate electrode structure. However, example embodiments are not limited thereto. As an example, the second surface WL_S2 of the first word line WL1 may be disposed lower than the second surface BG_S2 of the back gate electrode structure. As another example, the second surface WL_S2 of the first word line WL1 may be disposed on the same plane as the second surface BG_S2 of the back gate electrode structure.

According to some example embodiments, a height of each of the first word line WL1 and the second word line WL2 along the third direction D3 may be greater than the height of the back gate electrode structure BG along the third direction D3. The height of each of the first word line WL1 and the second word line WL2 along the third direction D3 may be smaller than heights of the first active pattern AP1 and the second active pattern AP2 along the third direction D3.

According to some example embodiments, the first word line WL1 and the second word line WL2 may include a conductive material. The first word line WL1 and the second word line WL2 may include, for example, at least one of doped polysilicon, conductive metal nitride, conductive metal silicon nitride, metal carbonitride, conductive metal silicide, conductive metal oxide, a 2D material, and metal.

According to some example embodiments, the first surface WL_S1 of each of the first word line WL1 and the second word line WL2 may be a plane. As an example, the first surface WL_S1 of each of the first word line WL1 and the second word line WL2 may be rounded in a concave shape with respect to an upper surface of the bit line BL. As another example, the first surface WL_S1 of each of the first word line WL1 and the second word line WL2 may be rounded in a convex shape toward the upper surface of the bit line BL.

According to some example embodiments, the second surface WL_S2 of each of the first word line WL1 and the second word line WL2 may be a plane. The second surface WL_S2 of each of the first word line WL1 and the second word line WL2 may have a concavely curved surface with respect to a lower surface of the data storage pattern DSP.

According to some example embodiments, a gate insulating pattern GOX may be disposed between the first word line WL1 and the first active pattern AP1 and between the second word line WL2 and the second active pattern AP2. The gate insulating pattern GOX may extend in the second direction D2 to be parallel to the first word line WL1 and the second word line WL2.

According to some example embodiments, the gate insulating pattern GOX may include a silicon oxide layer, a silicon oxynitride layer, a high-permittivity insulating layer having a dielectric constant higher than that of a silicon oxide layer, or a combination thereof.

According to some example embodiments, the gate insulating pattern GOX may extend along the first side surface SS1 of the first active pattern AP1 and extend along the second side surface SS2 of the second active pattern AP2. The gate insulating pattern GOX between the first active pattern AP1 and the first word line WL1 may be separated from the gate insulating pattern GOX between the second active pattern AP2 and the second word line WL2.

According to some example embodiments, a gate capping pattern 143 may be disposed between the first word line WL1 and the contact pattern BC and between the second word line WL2 and the contact pattern BC. The gate capping pattern 143 may cover the second surface WL_S2 of each of the first word line WL1 and the second word line WL2. FIG. 2 illustrates that the gate capping pattern 143 extends on the gate separation pattern GSS in the first direction D1 such that a portion of the gate capping pattern 143 disposed on the first word line WL1 is connected to a portion of the gate capping pattern 143 disposed on the second word line WL2, but example embodiments are not limited thereto. For example, the gate capping pattern 143 on the first word line WL1 and the gate capping pattern 143 on the second word line WL2 may be spaced apart from each other in the first direction D1 with the gate separation pattern GSS in between. In other words, the gate capping pattern 143 may not be disposed on the gate separation pattern GSS. In this case, an upper surface of the gate separation pattern GSS, an upper surface of the gate capping pattern 143 on the first word line WL1, and an upper surface of the gate capping pattern 143 on the second word line WL2 may be disposed on the same plane.

According to some example embodiments, the gate capping pattern 143 may include an insulating material. For example, the gate capping pattern 143 may include at least one of silicon oxide (SiO2), silicon nitride (SiN), silicon oxynitride (SiON), silicon carbonitride (SiCN), silicon oxycarbonitride (SiOCN), and a combination thereof.

According to some example embodiments, the gate separation pattern GSS may be disposed on the bit line BL. The gate separation pattern GSS may be disposed between the bit line BL and the contact pattern BC. The gate separation pattern GSS may contact the bit line BL.

According to some example embodiments, the gate separation pattern GSS may be disposed between the first word line WL1 and the second word line WL2 adjacent in the first direction D1. The first word line WL1 and the second word line WL2 may be separated from each other by the gate separation pattern GSS. The gate separation pattern GSS may extend between the first word line WL1 and the second word line WL2 in the second direction D2.

According to some example embodiments, the gate separation pattern GSS may include the horizontal portion GSS_H and a protruding portion GSS_P. The protruding portion GSS_P of the gate separation pattern may protrude from the horizontal portion GSS_H of the gate separation pattern in the third direction D3.

According to some example embodiments, the horizontal portion GSS_H of the gate separation pattern may be closer than the protruding portion GSS_P of the gate separation pattern to the bit line BL. The horizontal portion GSS_H of the gate separation pattern may be disposed below the plurality of word lines WL1 and WL2. The horizontal portion GSS_H of the gate separation pattern may cover the first surface WL_S1 of each of the first word line WL1 and the second word line WL2. The horizontal portion GSS_H of the gate separation pattern may contact the bit line BL. A width of the horizontal portion GSS_H of the gate separation pattern in the first direction D1 may be greater than a width of the protruding portion GSS_P of the gate separation pattern in the first direction D1.

According to some example embodiments, the protruding portion GSS_P of the gate separation pattern may be disposed at a side of each of the plurality of word lines WL1 and WL2 in the first direction D1. The protruding portion GSS_P of the gate separation pattern may be disposed between a side surface of the first word line WL1 and a side surface of the second word line WL2, which face each other along the first direction D1.

According to some example embodiments, the gate separation pattern GSS may include an insulating material. For example, the gate separation pattern GSS may include at least one of silicon oxide (SiO2), silicon nitride (SiN), silicon oxynitride (SiON), silicon carbonitride (SiCN), silicon oxycarbonitride (SiOCN), and a combination thereof. The gate separation pattern GSS may include a plurality of insulating layers.

According to some example embodiments, the contact pattern BC may penetrate a contact separation insulating pattern 231 and a contact etch stop layer 212. The contact pattern BC may be connected to each of the first active pattern AP1 and the second active pattern AP2. The contact pattern BC may be connected to the second surface S2 of each of the first active pattern AP1 and the second active pattern AP2. With respect to a plane defined in the first direction D1 and the second direction D2, the contact pattern BC may have various shapes such as circles, ellipses, rectangles, squares, rhombuses, and hexagons.

According to some example embodiments, the contact pattern BC may include a conductive material. The contact pattern BC may include, for example, at least one of doped polysilicon, conductive metal nitride, conductive metal silicon nitride, metal carbonitride, conductive metal silicide, conductive metal oxide, a 2D material, and metal.

According to some example embodiments, the contact etch stop layer 212 and the contact separation insulating pattern 231 may be disposed above the gate capping pattern 143 and a back gate separation pattern 111. The contact etch stop layer 212 and the contact separation insulating pattern 231 may surround a side surface of the contact pattern BC. Each of the contact etch stop layer 212 and the contact separation insulating pattern 231 may include an insulating material.

According to some example embodiments, a landing pad LP may be disposed on the contact pattern BC. The landing pad LP may be provided as a plurality of landing pads LP. With respect to a plane defined in the first direction D1 and the second direction D2, the plurality of landing pads LP may be arranged in a matrix form along the first direction D1 and the second direction D2. An upper surface of the landing pad LP may be disposed on substantially the same plane as an upper surface of a pad separation insulating pattern 235. With respect to a plane defined in the first direction D1 and the second direction D2, the landing pad LP may have various shapes such as circles, ellipses, rectangles, squares, rhombuses, and hexagons.

According to some example embodiments, the pad separation insulating pattern 235 may be disposed between the plurality of landing pads LP. The pad separation insulating pattern 235 may surround side surfaces of the plurality of landing pads LP. The pad separation insulating pattern 235 may include an insulating material.

According to some example embodiments, the landing pad LP may include a conductive material. For example, the landing pad LP may include at least one of doped polysilicon, conductive metal nitride, conductive metal silicon nitride, metal carbonitride, conductive metal silicide, conductive metal oxide, a 2D material, and metal.

According to some example embodiments, the data storage pattern DSP may be disposed on each of the landing pads LP. The data storage pattern DSP may be electrically connected to each of the plurality of active patterns AP1 and AP2. The data storage pattern DSP may be arranged in a matrix form along the first direction D1 and the second direction D2 as illustrated in FIG. 1. The data storage pattern DSP may entirely or partially cover the landing pad LP in the third direction D3. The data storage pattern DSP may contact the whole or a portion of the upper surface of the landing pad LP.

According to some example embodiments, the data storage pattern DSP may be a capacitor. The data storage pattern DSP may include a first electrode 251, a second electrode 255, and a capacitor dielectric layer 253 interposed between the first electrode 251 and the second electrode 255. The first electrode 251 may contact the landing pad LP. In a plan view, the first electrode 251 may have various shapes such as circles, ellipses, rectangles, squares, rhombuses, and hexagons. The data storage pattern DSP may entirely or partially cover the landing pad LP. The data storage pattern DSP may contact the whole or a portion of the upper surface of the landing pad LP. The first electrode 251 may penetrate an upper etch stop layer 247. The upper etch stop layer 247 may include an insulating material.

According to some example embodiments, the data storage pattern DSP may be a variable resistor pattern that may switch between two resistance states due to electric pulses applied to a memory element. For example, the data storage pattern DSP may include a phase-change material whose crystalline state changes depending on the amount of current, perovskite compounds, transition metal oxide, magnetic materials, ferromagnetic materials, or antiferromagnetic materials.

According to some example embodiments, the back gate electrode structure BG may be disposed above the bit line BL and the shielding line SL. The back gate electrode structure BG may be provided as the plurality of back gate electrode structures BG. The plurality of back gate electrode structures BG may be spaced apart from each other in the first direction D1. The plurality of back gate electrode structures BG may be spaced apart at predetermined intervals. The back gate electrode structure BG may extend in the second direction D2. The back gate electrode structure BG may intersect with the bit line BL.

According to some example embodiments, the back gate electrode structure BG may be disposed between the first active pattern AP1 and the second active pattern AP2 adjacent to each other in the first direction D1. The first active pattern AP1 may be disposed at one side of the back gate electrode structure BG along the first direction D1, and the second active pattern AP2 may be disposed at the other side of the back gate electrode structure BG. The height of the back gate electrode structure BG in the third direction D3 may be smaller than heights of the plurality of active patterns AP1 and AP2 in the third direction D3. The height of the back gate electrode structure BG along the third direction D3 may be smaller than heights of the plurality of word lines WL1 and WL2 along the third direction D3.

According to some example embodiments, the back gate electrode structure BG may be spaced apart from the plurality of word lines WL1 and WL2 in the first direction D1. The back gate electrode structure BG may be disposed between the first word line WL1 and the second word line WL2.

According to some example embodiments, the back gate electrode structure BG may be disposed between the second side surface SS2 of the first active pattern AP1 and the first side surface SS1 of the second active pattern AP2. The first active pattern AP1 may be disposed between the first word line WL1 and the back gate electrode structure BG. The second active pattern AP2 may be disposed between the second word line WL2 and the back gate electrode structure BG. Between the back gate electrode structures BG adjacent in the first direction D1, a pair of the first word line WL1 and the second word line WL2 may be disposed.

According to some example embodiments, the back gate electrode structure BG may include the first surface BG_S1 and the second surface BG_S2 disposed opposite to each other in the third direction D3. The first surface BG_S1 of the back gate electrode structure may face the bit line BL. The second surface BG_S2 of the back gate electrode structure may face the data storage pattern DSP. The first surface BG_S1 of the back gate electrode structure and the second surface BG_S2 of the back gate electrode structure are illustrated as planes, but are not limited thereto. For example, the first surface BG_S1 of the back gate electrode structure and the second surface BG_S2 of the back gate electrode structure may be curved surfaces.

According to some example embodiments, the back gate electrode structure BG may be overlapped by the plurality of word lines WL1 and WL2 when viewed in plan from the first direction D1. The first surface BG_S1 of the back gate electrode structure BG may be between a first surface WL_S1 and a second surface WL_S2 of each of the plurality of word lines WL1 and WL2 in the third direction D3. The second surface BG_S2 of the back gate electrode structure BG may be between a first surface WL_S1 and a second surface WL_S2 of each of the plurality of word lines WL1 and WL2 in the third direction D3. In other words, when viewed in the third direction D3, first surface BG_S1 of the back gate electrode structure BG and the second surface BG_S2 of the back gate electrode structure BG may be between the upper and lower surfaces of the word lines.

According to some example embodiments, the back gate electrode structure BG may include a back gate body pattern 310 and back gate work function adjustment patterns 320 and 330. The back gate body pattern 310 may be between the back gate work function adjustment patterns 320 and 330 in the third direction D3. That is, the back gate body pattern 310 may be above the first back gate work function adjustment pattern 320 and below the second back gate work function adjustment pattern 330 in the third direction D3, with each component having substantially equal widths in the first direction D1.

According to some example embodiments, the back gate body pattern 310 may be disposed between a first back gate work function adjustment pattern 320 and a second back gate work function adjustment pattern 330. The back gate body pattern 310 may be overlapped by the plurality of word lines WL1 and WL2 and the plurality of active patterns AP1 and AP2 when viewed in plan from the first direction D1. The back gate body pattern 310 may include, for example, at least one of titanium nitride (TiN), tungsten (W), and molybdenum (Mo).

According to some example embodiments, the back gate work function adjustment patterns 320 and 330 may include the first back gate work function adjustment pattern 320 and the second back gate work function adjustment pattern 330. The back gate work function adjustment patterns 320 and 330 may be respectively above and below the back gate body pattern 310 in the third direction D3. The back gate work function adjustment patterns 320 and 330 may contact the back gate body pattern 310. The first back gate work function adjustment pattern 320 and the second back gate work function adjustment pattern 330 may be spaced apart from each other with the back gate body pattern 310 in between. The first back gate work function adjustment pattern 320 may be disposed between the back gate body pattern 310 and the bit line BL. The second back gate work function adjustment pattern 330 may be disposed between the back gate body pattern 310 and the data storage pattern DSP.

According to some example embodiments, the back gate work function adjustment patterns 320 and 330 may be disposed on one or both ends of the back gate electrode structure BG along the third direction D3. The two ends of the back gate electrode structure BG along the third direction D3 may be the first surface BG_S1 and the second surface BG_S2 of the back gate electrode structure. For example, the back gate electrode structure BG may have a first end facing the bit line BL and a second end disposed opposite to the first end in the third direction D3. The first end of the back gate electrode structure BG may be the first surface BG_S1 of the back gate electrode structure. The second end of the back gate electrode structure BG may be the second surface BG_S2 of the back gate electrode structure. For example, the first back gate work function adjustment pattern 320 may be disposed on the first end. The second back gate work function adjustment pattern 330 may be disposed on the second end of the back gate electrode structure BG.

According to some example embodiments, the back gate work function adjustment patterns 320 and 330 may define one of the first surface BG_S1 and the second surface BG_S2 of the back gate electrode structure. For example, the first back gate work function adjustment pattern 320 may define the first surface BG_S1 of the back gate electrode structure. A lower surface of the first back gate work function adjustment pattern 320 may be the first surface BG_S1 of the back gate electrode structure. The second back gate work function adjustment pattern 330 may define the second surface BG_S2 of the back gate electrode structure. An upper surface of the second back gate work function adjustment pattern 330 may be the second surface BG_S2 of the back gate electrode structure.

According to some example embodiments, the back gate work function adjustment patterns 320 and 330 may be overlapped by the plurality of word lines WL1 and WL2 and the plurality of active patterns AP1 and AP2 when viewed in plan from the first direction D1. With respect to the bit line BL, the lower surface of the first back gate work function adjustment pattern 320 may be disposed higher than the first surface WL_S1 of each of the plurality of word lines WL1 and WL2. With respect to the bit line BL, a height of the lower surface of the first back gate work function adjustment pattern 320 may be greater than the height of the first surface WL_S1 of each of the plurality of word lines WL1 and WL2. With respect to the bit line BL, the upper surface of the second back gate work function adjustment pattern 330 may be disposed lower than the second surface WL_S2 of each of the plurality of word lines WL1 and WL2. With respect to the bit line BL, a height of the upper surface of the second back gate work function adjustment pattern 330 may be smaller than the height of the second surface WL_S2 of each of the plurality of word lines WL1 and WL2.

According to some example embodiments, the first back gate work function adjustment pattern 320 and the second back gate work function adjustment pattern 330 may include a material different from a material of the back gate body pattern 310. The first back gate work function adjustment pattern 320 and the second back gate work function adjustment pattern 330 may include a material having a work function greater than that of the back gate body pattern 310. The first back gate work function adjustment pattern 320 and the second back gate work function adjustment pattern 330 may include, for example, at least one of polysilicon doped with an impurity, lanthanum oxide (LaO), and titanium aluminum carbide (TiAlC). However, example embodiments are not limited thereto.

According to some example embodiments, the back gate electrode structure BG may block an electric field of an inactive word line to enhance the electrical reliability of the VCT. When operating the semiconductor device, voltage may be applied to the back gate electrode structure BG such that a threshold voltage of the VCT may be adjusted. A negative voltage may be applied to the back gate electrode structure BG to adjust the threshold voltage of the VCT. As the negative voltage is applied to the back gate electrode structure BG, gate-induced drain leakage (GIDL) of the VCT may deteriorate. As the back gate electrode structure BG has a multilayer structure having different materials, the GIDL characteristics of the VCT may be improved. Accordingly, the electrical reliability of the semiconductor device according to some example embodiments of the present disclosure may be enhanced.

According to some example embodiments, the first back gate work function adjustment pattern 320 and the second back gate work function adjustment pattern 330 may mitigate dynamic leakage that may occur when a relatively low magnitude of voltage is applied to the back gate electrode structure BG and the plurality of word lines WL1 and WL2. When a relatively low magnitude of voltage is applied to the back gate electrode structure BG and the plurality of word lines WL1 and WL2, the occurrence of GIDL may decrease but the occurrence of dynamic leakage induced by a gate electrode may increase. Even though a relatively low magnitude of voltage is applied to the back gate electrode structure BG and the plurality of word lines WL1 and WL2, the occurrence of dynamic leakage induced by the gate electrode may be decreased by the first back gate work function adjustment pattern 320 and the second back gate work function adjustment pattern 330 of which work functions are relatively high. Therefore, a risk of leakage current may be reduced and electrical reliability may be enhanced in the semiconductor device according to some example embodiments of the present disclosure.

According to some example embodiments, the back gate separation pattern 111 may be disposed between the first active pattern AP1 and the second active pattern AP2 adjacent in the first direction D1. The back gate separation pattern 111 may extend in the second direction D2 to be parallel to the back gate electrode structure BG. The back gate separation pattern 111 may be disposed on the second surface BG_S2 of the back gate electrode structure. The back gate separation pattern 111 may be disposed on the second back gate work function adjustment pattern 330.

According to some example embodiments, the back gate separation pattern 111 may include an insulating material. The back gate separation pattern 111 may include, for example, a silicon oxide layer, a silicon oxynitride layer, or a silicon nitride layer, but is not limited thereto.

According to some example embodiments, a back gate side insulating pattern 113 may be disposed between the back gate electrode structure BG and the first active pattern AP1 and between the back gate electrode structure BG and the second active pattern AP2. The back gate side insulating pattern 113 may be disposed between the back gate separation pattern 111 and the first active pattern AP1 and between the back gate separation pattern 111 and the second active pattern AP2. The back gate side insulating pattern 113 may be disposed between a back gate capping pattern 115 and the first active pattern AP1 and between the back gate capping pattern 115 and the second active pattern AP2.

According to some example embodiments, the back gate side insulating pattern 113 may include an insulating material. The back gate side insulating pattern 113 may include, for example, a silicon oxide layer, a silicon oxynitride layer, a high-permittivity insulating layer having a dielectric constant higher than that of a silicon oxide layer, or a combination thereof.

According to some example embodiments, the back gate capping pattern 115 may be disposed between the bit line BL and the back gate electrode structure BG. The back gate capping pattern 115 may be disposed between the first active pattern AP1 and the second active pattern AP2 adjacent in the first direction D1. The back gate capping pattern 115 may be below the back gate electrode structure BG in the third direction D3 and extend in the second direction D2. The back gate capping pattern 115 may be disposed on the first surface BG_S1 of the back gate electrode structure. The back gate capping pattern 115 may be disposed below the first back gate work function adjustment pattern 320. A thickness of the back gate capping pattern 115 on the bit line shielding structure 171, SL, and 175 along the third direction D3 may be different from a thickness of the back gate capping pattern 115 on the bit line BL along the third direction D3. For example, the thickness of the back gate capping pattern 115 on the bit line shielding structure 171, SL, and 175 along the third direction D3 may be smaller than the thickness of the back gate capping pattern 115 on the bit line BL along the third direction D3.

According to some example embodiments, the back gate capping pattern 115 may include an insulating material. The back gate capping pattern 115 may include, for example, at least one of a silicon oxide layer, a silicon oxynitride layer, and a silicon nitride layer, but is not limited thereto.

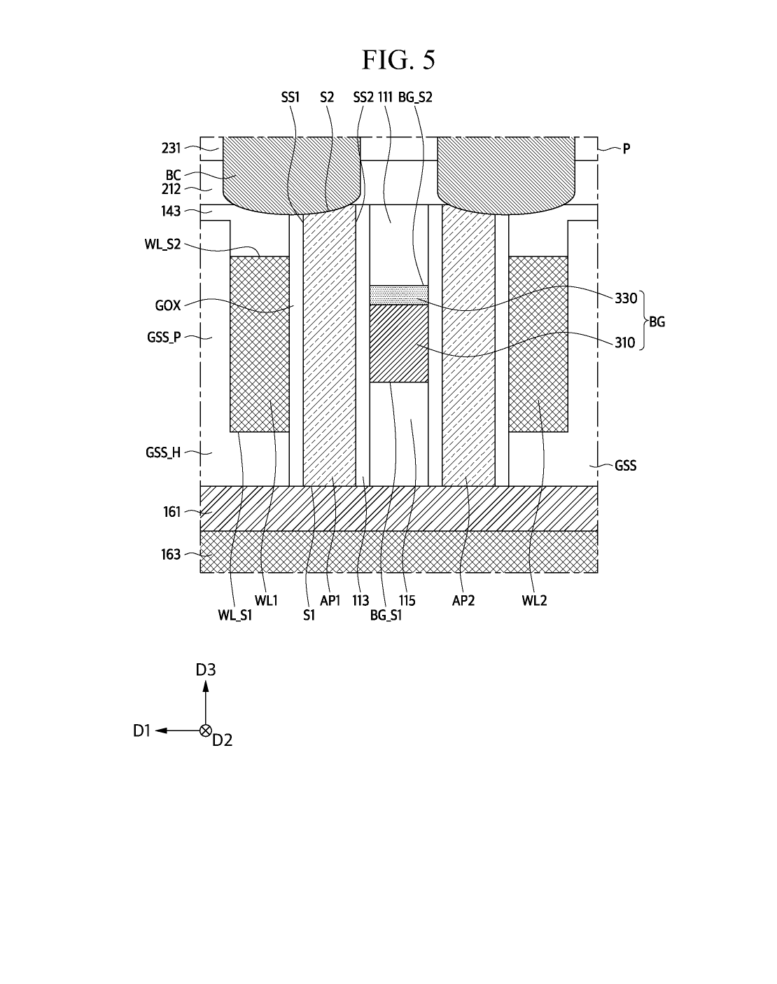

FIG. 5 is an enlarged view of part P of FIG. 2 for illustrating a semiconductor device according to example embodiments. To facilitate understanding of the present disclosure, the difference from what is described with reference to FIGS. 1 - 4 is mainly described.

Referring to FIG. 5, the back gate electrode structure BG may include the back gate body pattern 310 and the second back gate work function adjustment pattern 330. In comparison to the back gate electrode structure BG illustrated in FIG. 4, the back gate electrode structure BG illustrated in FIG. 5 may not include the first back gate work function adjustment pattern 320. The back gate body pattern 310 may contact the back gate capping pattern 115. The back gate body pattern 310 may define the first surface BG_S1 of the back gate electrode structure. A lower surface of the back gate body pattern 310 may be the first surface BG_S1 of the back gate electrode structure.

According to some example embodiments, a back gate work function adjustment pattern may not be disposed between the back gate body pattern 310 and the bit line BL along the third direction D3. By changing a position of a work function adjustment pattern, leakage current such as gate-induced dynamic leakage or GIDL in a transistor composed of the word lines WL1 and WL2, the active patterns AP1 and AP2, the bit line BL, and the contact pattern BC may be efficiently controlled.

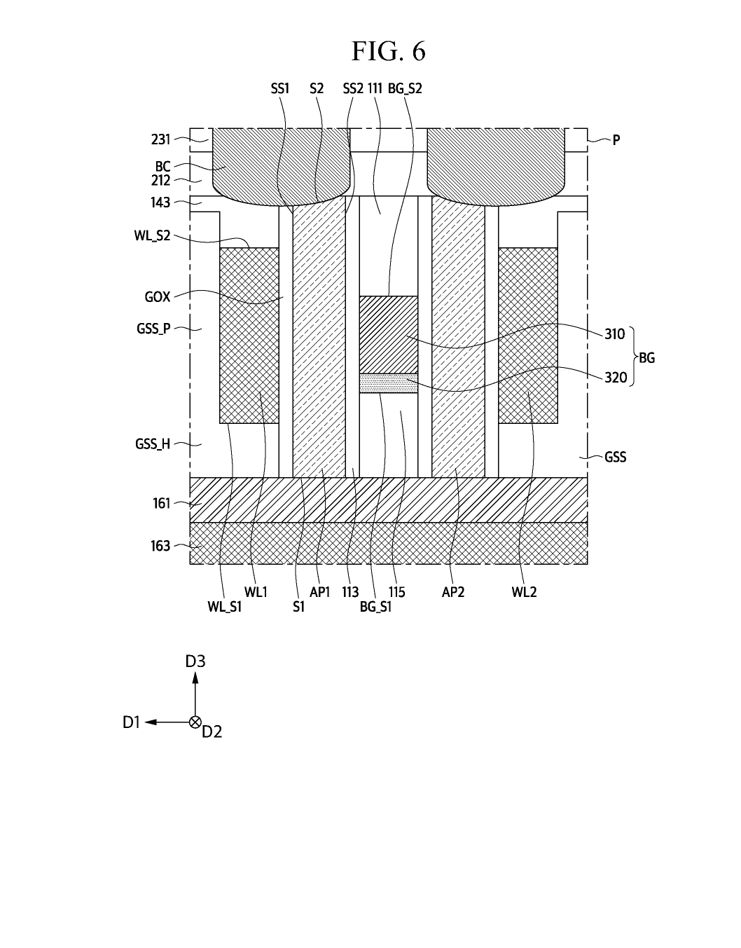

FIG. 6 is an enlarged view of part P of FIG. 2 for illustrating a semiconductor device according to example embodiments. To facilitate understanding of the present disclosure, the difference from what is described with reference to FIGS. 1 - 4 is mainly described.

Referring to FIG. 6, the back gate electrode structure BG may include the back gate body pattern 310 and the first back gate work function adjustment pattern 320. In comparison to the back gate electrode structure BG illustrated in FIG. 4, the back gate electrode structure BG illustrated in FIG. 6 may not include the second back gate work function adjustment pattern 330. The back gate body pattern 310 may contact the back gate separation pattern 111. The back gate body pattern 310 may define the second surface BG_S2 of the back gate electrode structure. An upper surface of the back gate body pattern 310 may be the second surface BG_S2 of the back gate electrode structure.

According to some example embodiments, a back gate work function adjustment pattern may not be disposed between the back gate body pattern 310 and the data storage pattern DSP along the third direction D3. By changing a position of a work function adjustment pattern, leakage current such as gate-induced dynamic leakage or GIDL in a transistor composed of the word lines WL1 and WL2, the active patterns AP1 and AP2, the bit line BL, and the contact pattern BC may be efficiently controlled.

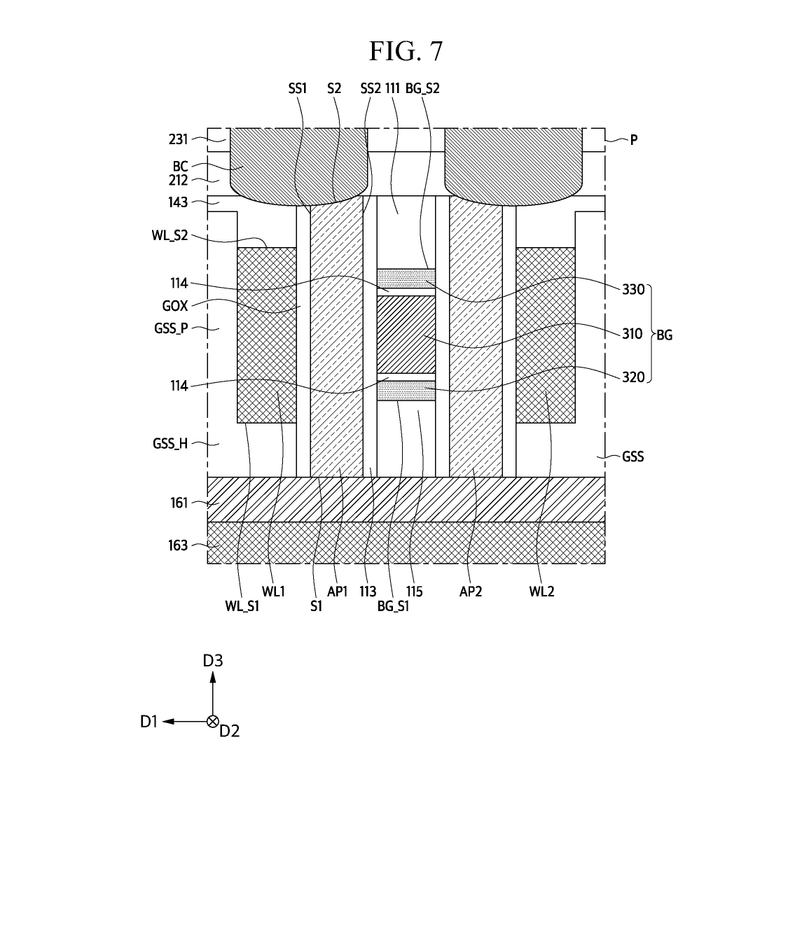

FIG. 7 is an enlarged view of part P of FIG. 2 for illustrating a semiconductor device according to example embodiments. To facilitate understanding of the present disclosure, the difference from what is described with reference to FIGS. 1 - 4 is mainly described.

Referring to FIG. 7, the back gate work function adjustment patterns 320 and 330 may be spaced apart from the back gate body pattern 310. A back gate interlayer insulating pattern 114 may be disposed between the first back gate work function adjustment pattern 320 and the back gate body pattern 310 and between the second back gate work function adjustment pattern 330 and the back gate body pattern 310. The first back gate work function adjustment pattern 320, the back gate interlayer insulating pattern 114, the back gate body pattern 310, the back gate interlayer insulating pattern 114, and the second back gate work function adjustment pattern 330 may be stacked in sequence in the third direction D3.

According to some example embodiments, the back gate interlayer insulating pattern 114 may cover the upper surface and the lower surface of the back gate body pattern 310. The back gate interlayer insulating pattern 114 may include an insulating material. For example, the back gate interlayer insulating pattern 114 may include at least one of silicon oxide (SiO2), silicon nitride (SiN), silicon oxynitride (SiON), silicon carbonitride (SiCN), silicon oxycarbonitride (SiOCN), and a combination thereof.

According to some example embodiments, the back gate work function adjustment patterns 320 and 330 may be physically spaced apart from the back gate body pattern 310 such that voltage applied to the back gate work function adjustment patterns 320 and 330 and voltage applied to the back gate body pattern 310 may be controlled independently from each other. Therefore, by individually adjusting each voltage applied to the back gate body pattern 310 and the back gate work function adjustment patterns 320 and 330, transistor leakage current such as gate-induced dynamic leakage or GIDL may be more finely controlled.

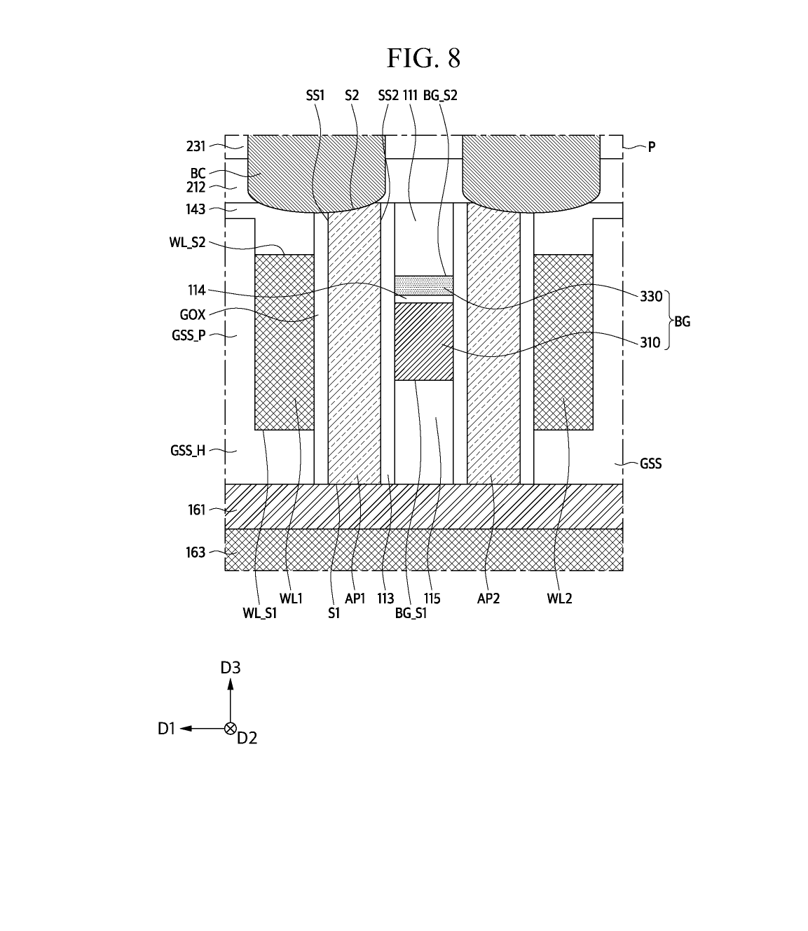

FIG. 8 is an enlarged view of part P of FIG. 2 for illustrating a semiconductor device according to example embodiments. To facilitate understanding of the present disclosure, the difference from what is described with reference to FIG. 7 is mainly described.

Referring to FIG. 8, the back gate electrode structure BG may include the back gate body pattern 310 and the second back gate work function adjustment pattern 330. The back gate body pattern 310, the back gate interlayer insulating pattern 114, and the second back gate work function adjustment pattern 330 may be stacked in sequence in the third direction D3. In comparison to the back gate electrode structure BG illustrated in FIG. 7, the back gate electrode structure BG illustrated in FIG. 8 may not include the first back gate work function adjustment pattern 320. The back gate body pattern 310 may contact the back gate capping pattern 115. The back gate body pattern 310 may define the first surface BG_S1 of the back gate electrode structure. The lower surface of the back gate body pattern 310 may be the first surface BG_S1 of the back gate electrode structure.

According to some example embodiments, a back gate work function adjustment pattern may not be disposed between the back gate body pattern 310 and the bit line BL along the third direction D3. By changing a position of a work function adjustment pattern, leakage current such as gate-induced dynamic leakage or GIDL in a transistor composed of the word lines WL1 and WL2, the active patterns AP1 and AP2, the bit line BL, and the contact pattern BC may be efficiently controlled. Furthermore, by individually adjusting each voltage applied to the back gate body pattern 310 and the second back gate work function adjustment pattern 330, transistor leakage current may be more finely controlled.

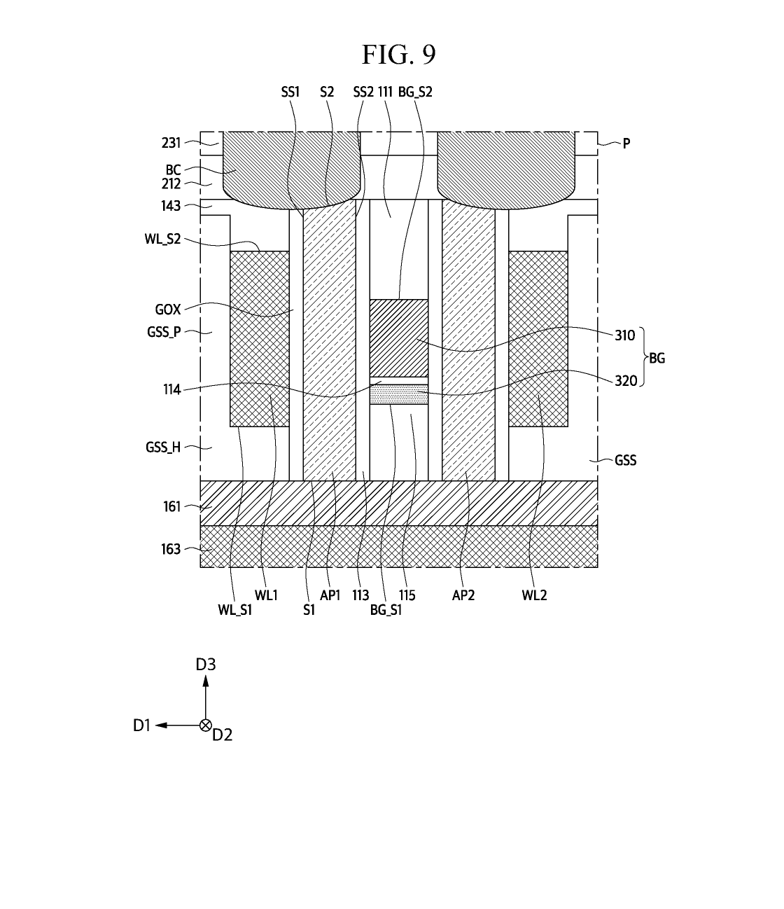

FIG. 9 is an enlarged view of part P of FIG. 2 for illustrating a semiconductor device according to example embodiments. To facilitate understanding of the present disclosure, the difference from what is described with reference to FIG. 7 is mainly described.

Referring to FIG. 9, the back gate electrode structure BG may include the back gate body pattern 310 and the first back gate work function adjustment pattern 320. The first back gate work function adjustment pattern 320, the back gate interlayer insulating pattern 114, and the back gate body pattern 310 may be stacked in sequence in the third direction D3. In comparison to the back gate electrode structure BG illustrated in FIG. 7, the back gate electrode structure BG illustrated in FIG. 9 may not include the second back gate work function adjustment pattern 330. The back gate body pattern 310 may contact the back gate separation pattern 111. The back gate body pattern 310 may define the second surface BG_S2 of the back gate electrode structure. The upper surface of the back gate body pattern 310 may be the second surface BG_S2 of the back gate electrode structure.

According to some example embodiments, a back gate work function adjustment pattern may not be disposed between the back gate body pattern 310 and the data storage pattern DSP along the third direction D3. By changing a position of a work function adjustment pattern, leakage current in a transistor composed of the word lines WL1 and WL2, the active patterns AP1 and AP2, the bit line BL, and the contact pattern BC may be efficiently controlled. Furthermore, by individually adjusting each voltage applied to the back gate body pattern 310 and the first back gate work function adjustment pattern 320, transistor leakage current such as gate-induced dynamic leakage or GIDL may be more finely controlled.

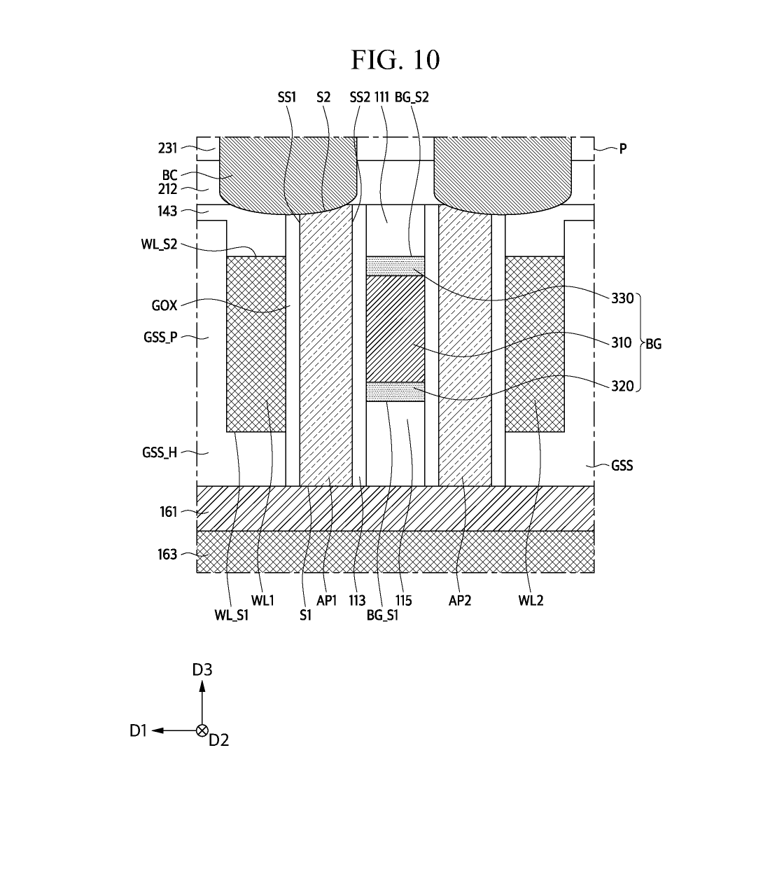

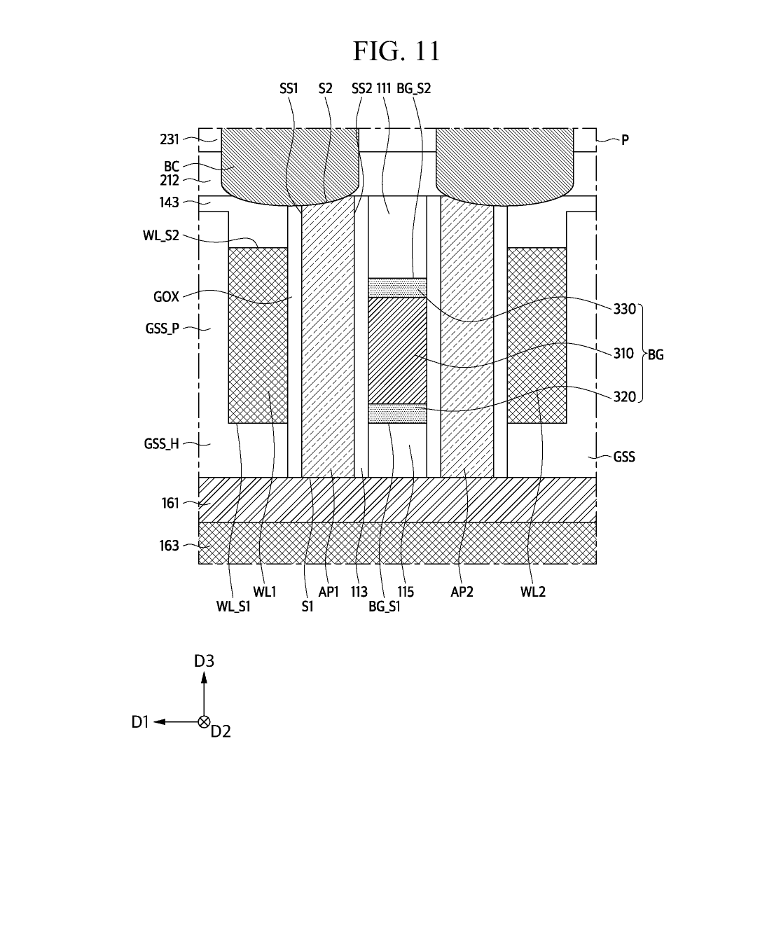

FIG. 10 is an enlarged view of part P of FIG. 2 for illustrating a semiconductor device according to example embodiments. To facilitate understanding of the present disclosure, the difference from what is described with reference to FIGS. 1 - 4 is mainly described.

Referring to FIG. 10, the second surface WL_S2 of each of the word lines WL1 and WL2 and the second surface BG_S2 of the back gate electrode structure may be disposed on the same plane. With respect to the bit line BL, the height of the second surface WL_S2 of each of the word lines WL1 and WL2 may be identical to the height of the second surface BG_S2 of the back gate electrode structure. The height of the back gate electrode structure BG along the third direction D3 may be smaller than the heights of the word lines WL1 andWL12 along the third direction D3. With respect to the bit line BL, the first surface WL_S1 of each of the word lines WL1 andWL12 may be disposed lower than the first surface BG_S1 of the back gate electrode structure. With respect to the bit line BL, the height of the first surface WL_S1 of each of the word lines WL1 andWL12 may be smaller than the height of the first surface BG_S1 of the back gate electrode structure.

According to some example embodiments, the back gate electrode structure BG may be overlapped by the word lines WL1 and WL2 and the active patterns AP1 and AP2 when viewed in plan from the first direction D1. Specifically, in the third direction D3, the height of the back gate electrode structure BG may be less than the height of the word lines WL1 and WL2 as well as the active patterns AP1 and AP2, while the bottom surface BG_S1 of the back gate electrode structure BG may be above the bottom surfaces of the word lines WL1 and WL2, as well as the bottom surfaces of the active patterns AP1 and AP2, and the top surface BG_S2 of the back gate electrode structure BG may be substantially coplanar with the top surfaces of the word lines WL1 and WL2 and be below the top surfaces of the active patterns AP1 and AP2. By adjusting portions of the word lines WL1 and WL2 and the active patterns AP1 and AP2 overlapping the back gate electrode structure BG when viewed in the first direction D1, transistor leakage current such as gate-induced dynamic leakage or GIDL may be efficiently controlled.

FIG. 11 is an enlarged view of part P of FIG. 2 for illustrating a semiconductor device according to example embodiments. To facilitate understanding of the present disclosure, the difference from what is described with reference to FIGS. 1 - 4 is mainly described.

Referring to FIG. 11, the first surface WL_S1 of each of the word lines WL1 and WL2 and the first surface BG_S1 of the back gate electrode structure may be disposed on the same plane. With respect to the bit line BL, the height of the first surface WL_S1 of each of the word lines WL1 and WL2 may be identical to the height of the first surface BG_S1 of the back gate electrode structure. The height of the back gate electrode structure BG along the third direction D3 may be smaller than the heights of the word lines WL1 and WL2 along the third direction D3. With respect to the bit line BL, the second surface WL_S2 of each of the word lines WL1 and WL2 may be disposed higher than the second surface BG_S2 of the back gate electrode structure. With respect to the bit line BL, the height of the second surface WL_S2 of each of the word lines WL1 and WL2 may be greater than the height of the second surface BG_S2 of the back gate electrode structure.

According to some example embodiments, the back gate electrode structure BG may be overlapped by the word lines WL1 and WL2 and the active patterns AP1 and AP2 when viewed in plan from the first direction D1. Specifically, in the third direction D3, the height of the back gate electrode structure BG may be less than the height of the word lines WL1 and WL2 as well as the active patterns AP1 and AP2, while the bottom surface BG_S1 of the back gate electrode structure BG may be substantially coplanar with the bottom surfaces of the word lines WL1 and WL2, as well as the bottom surfaces of the active patterns AP1 and AP2, and the top surface BG_S2 of the back gate electrode structure BG may be substantially coplanar with the top surfaces of the word lines WL1 and WL2 and be below the top surfaces of the active patterns AP1 and AP2. By adjusting portions of the word lines WL1 and WL2 and the active patterns AP1 and AP2 overlapping the back gate electrode structure BG, transistor leakage current such as gate-induced dynamic leakage or GIDL may be efficiently controlled.

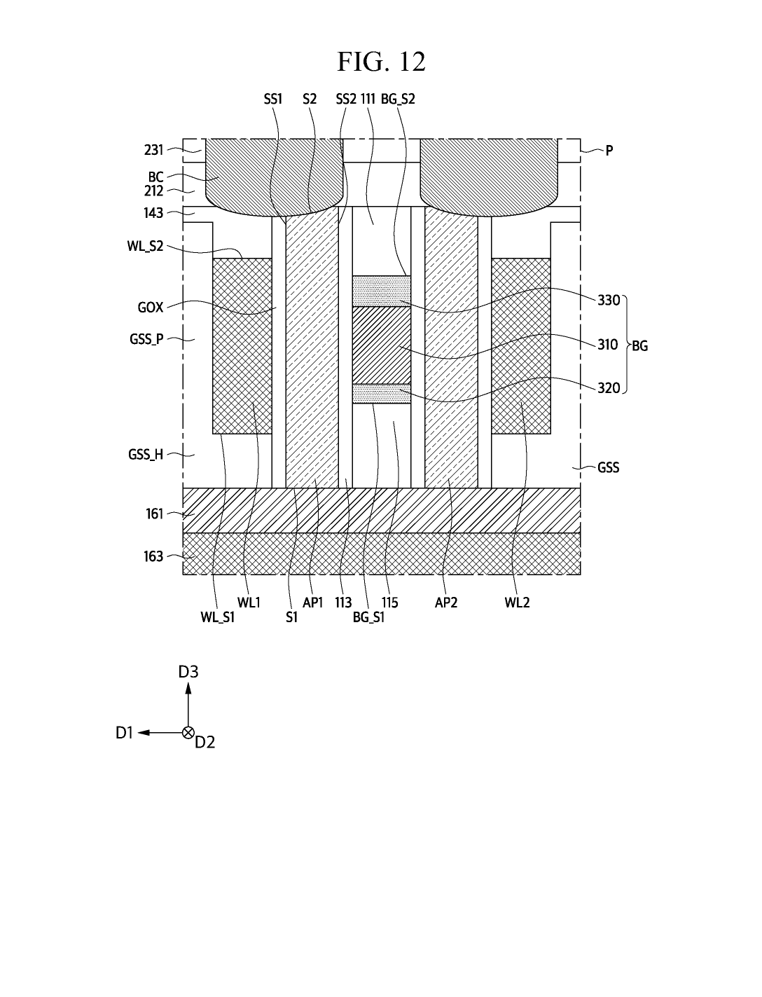

FIG. 12 is an enlarged view of part P of FIG. 2 for illustrating a semiconductor device according to example embodiments. To facilitate understanding of the present disclosure, the difference from what is described with reference to FIGS. 1 - 4 is mainly described.

Referring to FIG. 12, a thickness of the first back gate work function adjustment pattern 320 and a thickness of the second back gate work function adjustment pattern 330 along the third direction D3 may be different from each other. For example, the thickness of the first back gate work function adjustment pattern 320 along the third direction D3 may be smaller than the thickness of the second back gate work function adjustment pattern 330 along the third direction D3. However, example embodiments are not limited thereto. For example, the thickness of the first back gate work function adjustment pattern 320 along the third direction D3 may be greater than the thickness of the second back gate work function adjustment pattern 330 along the third direction D3.

According to some example embodiments, by adjusting an area where each of the first back gate work function adjustment pattern 320 and the second back gate work function adjustment pattern 330 that is overlapped by the word lines WL1 and WL2 and the active patterns AP1 and AP2 when viewed in the first direction D1, transistor leakage current such as gate-induced dynamic leakage or GIDL may be efficiently controlled.

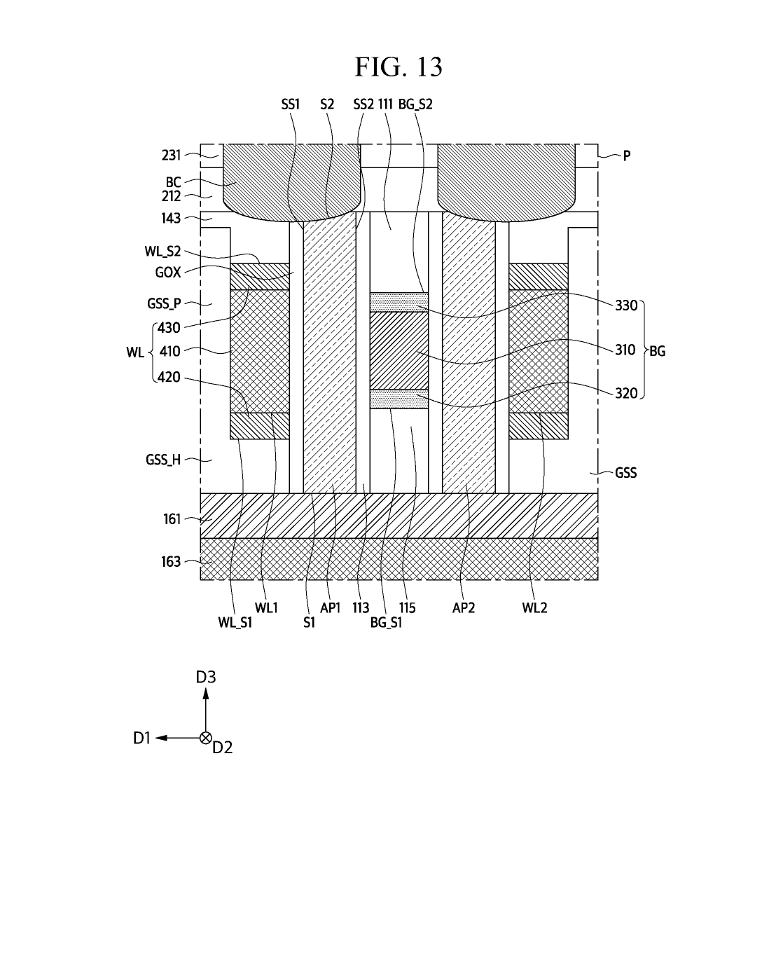

FIG. 13 is an enlarged view of part P of FIG. 2 for illustrating a semiconductor device according to example embodiments. To facilitate understanding of the present disclosure, the difference from what is described with reference to FIGS. 1 - 4 is mainly described.

Referring to FIG. 13, the word lines WL1 and WL2 may include a word line body pattern 410 and word line work function adjustment patterns 420 and 430. The word line body pattern 410 and the word line work function adjustment patterns 420 and 430 may overlap with each other in the third direction D3. That is, word line work function adjustment patterns 420 and 430 may be respectively below and above the word line body pattern 410 in the third direction D3 while having substantially equal widths in the first direction D1.

According to some example embodiments, the word line body pattern 410 may be disposed between a first word line work function adjustment pattern 420 and a second word line work function adjustment pattern 430. The word line body pattern 410 may be overlapped by the plurality of active patterns AP1 and AP2 and the back gate electrode structure BG when viewed in plan from the first direction D1.

According to some example embodiments, the word line work function adjustment patterns 420 and 430 may include the first word line work function adjustment pattern 420 and the second word line work function adjustment pattern 430. The word line work function adjustment patterns 420 and 430 may overlap with the word line body pattern 410 in the third direction D3. That is, word line work function adjustment patterns 420 and 430 may be respectively below and above the word line body pattern 410 in the third direction D3 while having substantially equal widths in the first direction D1. The word line work function adjustment patterns 420 and 430 may contact the word line body pattern 410. The first word line work function adjustment pattern 420 and the second word line work function adjustment pattern 430 may be spaced apart from each other with the word line body pattern 410 in between. The first word line work function adjustment pattern 420 may be disposed between the word line body pattern 410 and the bit line BL. The second word line work function adjustment pattern 430 may be disposed between the word line body pattern 410 and the data storage pattern DSP.

According to some example embodiments, the word line work function adjustment patterns 420 and 430 may be disposed on one or both ends of each of the word lines WL1 and WL2 along the third direction D3. The two ends of each of the word lines WL1 and WL2 along the third direction D3 may be the first surface WL_S1 and the second surface WL_S2 of each of the word lines WL1 and WL2. The word line work function adjustment patterns 420 and 430 may define one of the first surface WL_S1 and the second surface WL_S2 of each of the word lines WL1 and WL2. For example, the first word line work function adjustment pattern 420 may define the first surface WL_S1 of each of the word lines WL1 and WL2. A lower surface of the first word line work function adjustment pattern 420 may be the first surface WL_S1 of each of the word lines WL1 and WL2. The second word line work function adjustment pattern 430 may define the second surface WL_S2 of each of the word lines WL1 and WL2. An upper surface of the second word line work function adjustment pattern 430 may be the second surface WL_S2 of each of the word lines WL1 and WL2.

According to some example embodiments, the first word line work function adjustment pattern 420 and the second word line work function adjustment pattern 430 may include a material different from a material of the word line body pattern 410. The first word line work function adjustment pattern 420 and the second word line work function adjustment pattern 430 may include a material having a work function smaller than that of the word line body pattern 410. The first word line work function adjustment pattern 420 and the second word line work function adjustment pattern 430 may include, for example, at least one of polysilicon doped with an impurity, lanthanum oxide (LaO), and titanium aluminum carbide (TiAlC). However, example embodiments are not limited thereto.

According to some example embodiments, by adjusting work functions of the word lines WL1 and WL2 through the first word line work function adjustment pattern 420 and the second word line work function adjustment pattern 430, the threshold voltage of the VCT may be efficiently controlled.

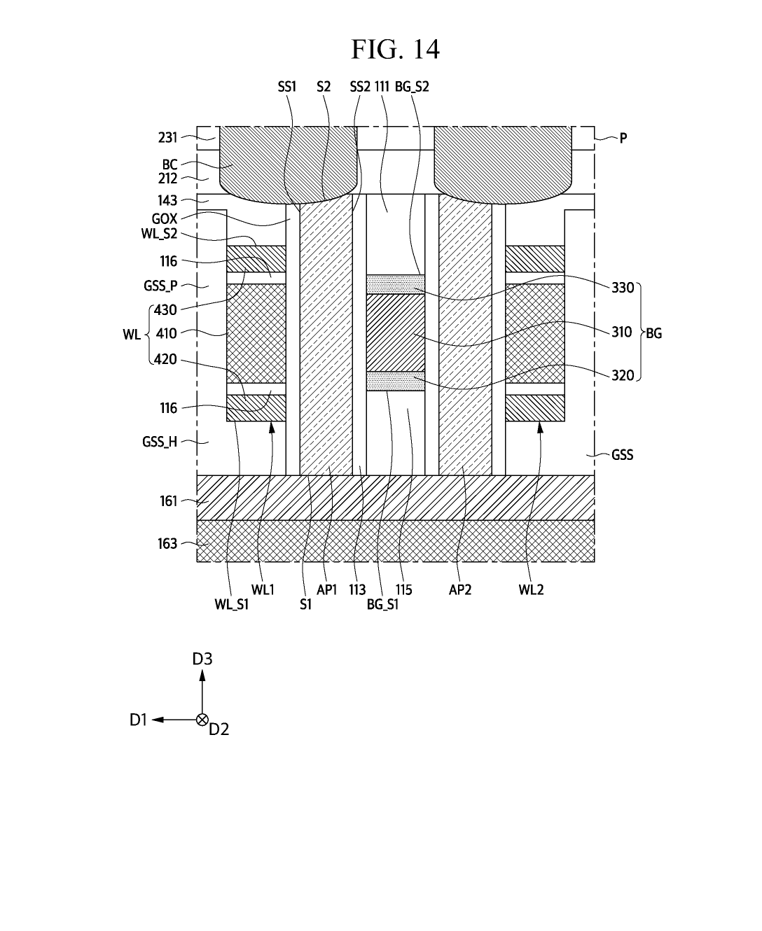

FIG. 14 is an enlarged view of part P of FIG. 2 for illustrating a semiconductor device according to example embodiments. To facilitate understanding of the present disclosure, the difference from what is described with reference to FIG. 13 is mainly described.

Referring to FIG. 14, the word line work function adjustment patterns 420 and 430 may be spaced apart from the word line body pattern 410. A word line interlayer insulating pattern 116 may be disposed between the first word line work function adjustment pattern 420 and the word line body pattern 410 and between the second word line work function adjustment pattern 430 and the word line body pattern 410. The first word line work function adjustment pattern 420, the word line interlayer insulating pattern 116, the word line body pattern 410, the word line interlayer insulating pattern 116, and the second word line work function adjustment pattern 430 may be stacked in sequence in the third direction D3.

According to some example embodiments, the word line interlayer insulating pattern 116 may cover an upper surface and a lower surface of the word line body pattern 410. The word line interlayer insulating pattern 116 may include an insulating material. For example, the word line interlayer insulating pattern 116 may include at least one of silicon oxide (SiO2), silicon nitride (SiN), silicon oxynitride (SiON), silicon carbonitride (SiCN), silicon oxycarbonitride (SiOCN), and a combination thereof.

According to some example embodiments, the word line work function adjustment patterns 420 and 430 may be physically spaced apart from the word line body pattern 410 such that voltage applied to the word line work function adjustment patterns 420 and 430 and voltage applied to the word line body pattern 410 may be controlled independently from each other. Therefore, by individually adjusting each voltage applied to the word line body pattern 410 and the word line work function adjustment patterns 420 and 430, the threshold voltage of the VCT may be more finely controlled.

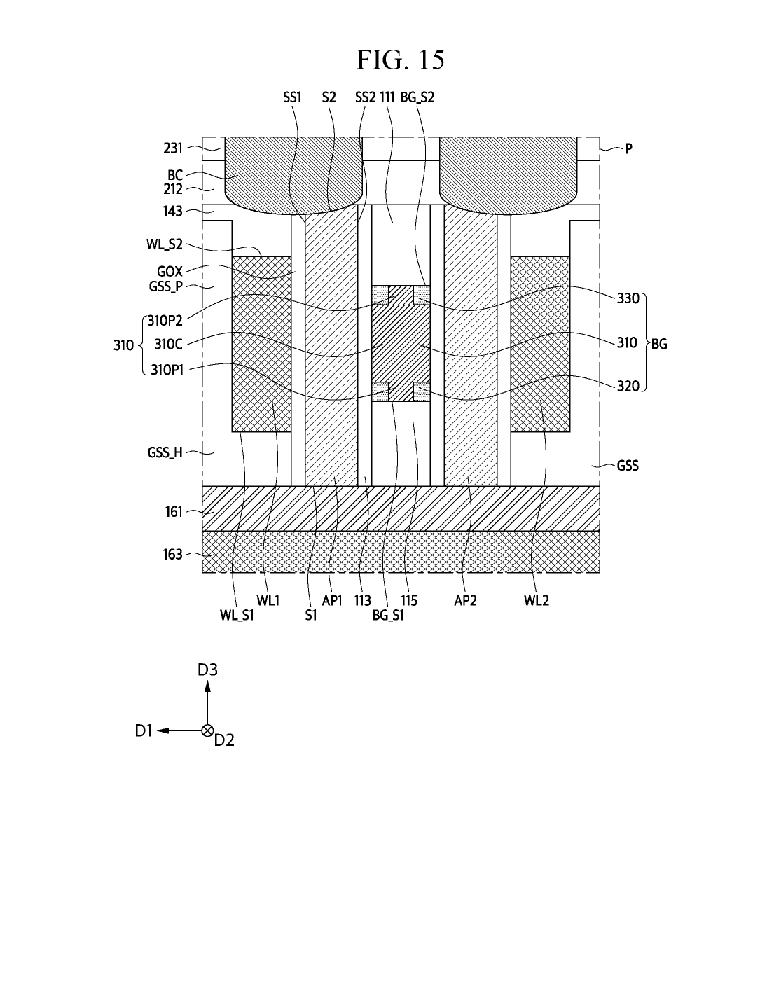

FIG. 15 is an enlarged view of part P of FIG. 2 for illustrating a semiconductor device according to example embodiments. To facilitate understanding of the present disclosure, the difference from what is described with reference to FIGS. 1 - 4 is mainly described.

Referring to FIG. 15, the back gate body pattern 310 may include a back gate body central portion 310C, a first protruding portion 310P1, and a second protruding portion 310P2. The back gate body central portion 310C may be between the first protruding portion 310P1 and the second protruding portion 310P2 in the third direction D3.

According to some example embodiments, the back gate body central portion 310C may be disposed between the first back gate work function adjustment pattern 320 and the second back gate work function adjustment pattern 330 along the third direction D3.

According to some example embodiments, each of the first protruding portion 310P1 and the second protruding portion 310P2 may protrude from the back gate body central portion 310C. The first protruding portion 310P1 may protrude from the back gate body central portion 310C toward the bit line BL. The second protruding portion 310P2 may protrude from the back gate body central portion 310C toward the data storage pattern DSP. The first protruding portion 310P1 and the second protruding portion 310P2 may be respectively below the second back gate work function adjustment pattern 330 and above the first back gate work function adjustment pattern 320 in the third direction D3.

According to some example embodiments, the first protruding portion 310P1 may be surrounded by (e.g., in-between) the first back gate work function adjustment pattern 320. A lower surface of the first protruding portion 310P1 and the lower surface of the first back gate work function adjustment pattern 320 may be disposed on the same plane. The lower surface of the first back gate work function adjustment pattern 320 and the lower surface of the first protruding portion 310P1 may be the first surface BG_S1 of the back gate electrode structure.

According to some example embodiments, the second protruding portion 310P2 may be surrounded by (e.g., in-between) the second back gate work function adjustment pattern 330. An upper surface of the second protruding portion 310P2 and the upper surface of the second back gate work function adjustment pattern 330 may be disposed on the same plane. The upper surface of the second back gate work function adjustment pattern 330 and the upper surface of the second protruding portion 310P2 may be the second surface BG_S2 of the back gate electrode structure.

According to some example embodiments, by adjusting an area where the back gate body pattern 310 and the back gate work function adjustment patterns 320 and 330 overlap in the third direction D3, resistance generated between the back gate body pattern 310 and the back gate work function adjustment patterns 320 and 330 may be mitigated.

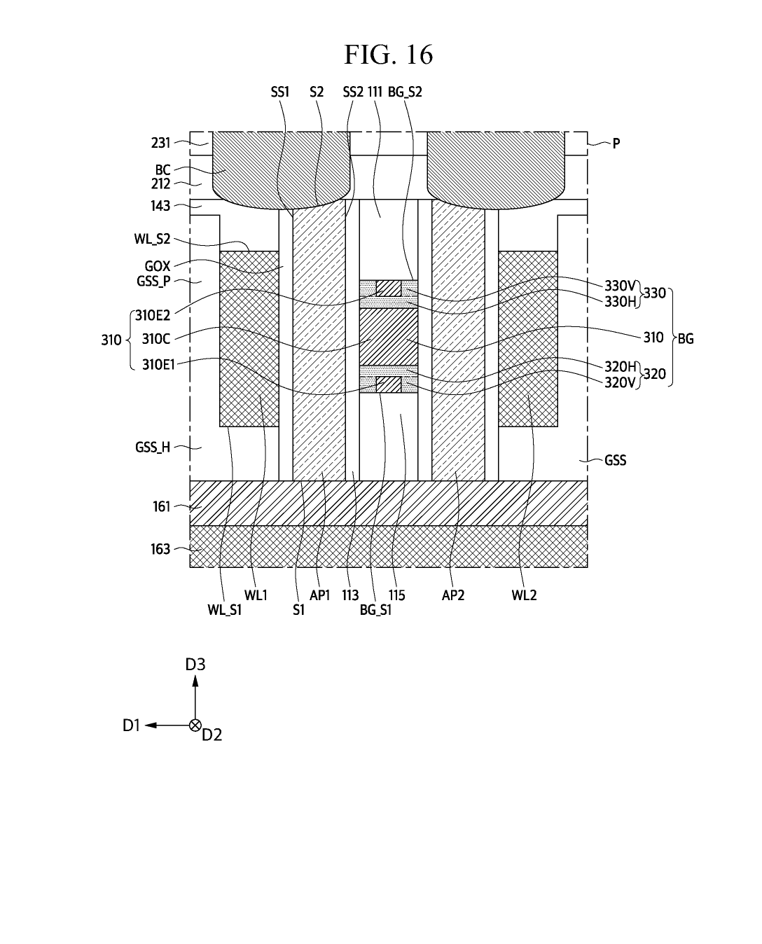

FIG. 16 is an enlarged view of part P of FIG. 2 for illustrating a semiconductor device according to example embodiments. To facilitate understanding of the present disclosure, the difference from what is described with reference to FIGS. 1 - 4 is mainly described.

Referring to FIG. 16, the back gate work function adjustment patterns 320 and 330 may include horizontal portions 320H and 330H and vertical portions 320V and 330V respectively. The first back gate work function adjustment pattern 320 may include a first horizontal portion 320H and a first vertical portion 320V. The second back gate work function adjustment pattern 330 may include a second horizontal portion 330H and a second vertical portion 330V.

According to some example embodiments, the first horizontal portion 320H may be disposed between the back gate body pattern 310 and a first buffer portion 310E1. The first vertical portion 320V may protrude from the first horizontal portion 320H toward the bit line BL. The first vertical portion 320V may be disposed at a side of the first buffer portion 310E1. The second horizontal portion 330H may be disposed between the back gate body pattern 310 and a second buffer portion 310E2. The second vertical portion 330V may protrude from the second horizontal portion 330H toward the data storage pattern DSP. The second vertical portion 330V may be disposed at a side of the second buffer portion 310E2.

According to some example embodiments, the back gate body pattern 310 may include the back gate body central portion 310C, the first buffer portion 310E1, and the second buffer portion 310E2. The back gate body central portion 310C is between the first buffer portion 310E1 and the second buffer portion 310E2 in the third direction D3. The back gate body central portion 310C, the first buffer portion 310E1, and the second buffer portion 310E2 may be spaced apart from each other.

According to some example embodiments, the back gate body central portion 310C may be disposed between the first back gate work function adjustment pattern 320 and the second back gate work function adjustment pattern 330. The back gate body central portion 310C may be disposed between the first horizontal portion 320H and the second horizontal portion 330H.

According to some example embodiments, the first buffer portion 310E1 may be spaced apart from the back gate body central portion 310C with the first back gate work function adjustment pattern 320 in between. The first buffer portion 310E1 may be surrounded by the first back gate work function adjustment pattern 320. For example, an upper surface and a side surface of the first buffer portion 310E1 may be surrounded by (e.g., in-between) the first back gate work function adjustment pattern 320. The first buffer portion 310E1 may be surrounded by the first horizontal portion 320H and the first vertical portion 320V. A lower surface of the first buffer portion 310E1 and a lower surface of the first vertical portion 320V may be disposed on the same plane. The lower surface of the first buffer portion 310E1 and the lower surface of the first vertical portion 320V may be the first surface BG_S1 of the back gate electrode structure.

According to some example embodiments, the second buffer portion 310E2 may be spaced apart from the back gate body central portion 310C with the second back gate work function adjustment pattern 330 in between. The second buffer portion 310E2 may be surrounded by the second back gate work function adjustment pattern 330. For example, a lower surface and a side surface of the second buffer portion 310E2 may be surrounded by (e.g., in-between) the second back gate work function adjustment pattern 330. The second buffer portion 310E2 may be surrounded by the second horizontal portion 330H and the second vertical portion 330V. An upper surface of the second buffer portion 310E2 and an upper surface of the second vertical portion 330V may be disposed on the same plane. The upper surface of the second buffer portion 310E2 and the upper surface of the second vertical portion 330V may be the second surface BG_S2 of the back gate electrode structure.

According to some example embodiments, by adjusting an area where the back gate body pattern 310 and the back gate work function adjustment patterns 320 and 330 overlap, resistance generated between the back gate body pattern 310 and the back gate work function adjustment patterns 320 and 330 may be mitigated.

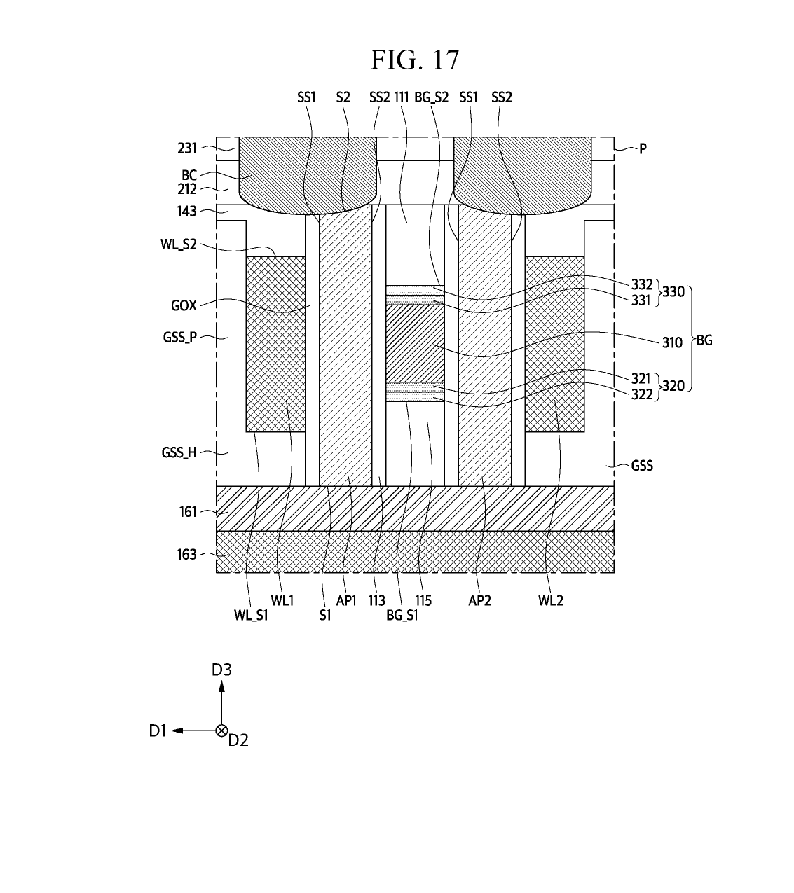

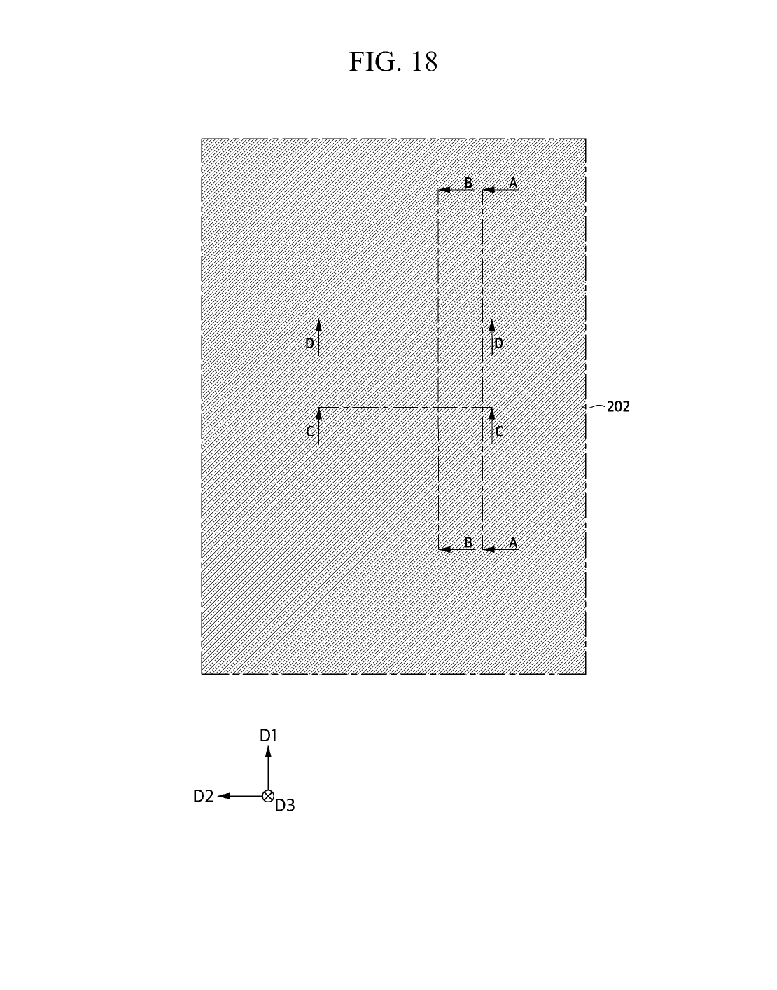

FIG. 17 is an enlarged view of part P of FIG. 2 for illustrating a semiconductor device according to example embodiments. To facilitate understanding of the present disclosure, the difference from what is described with reference to FIGS. 1 - 4 is mainly described.

Referring to FIG. 17, the back gate work function adjustment patterns 320 and 330 may include a multilayer. The first back gate work function adjustment pattern 320 may include a first sub-work function adjustment pattern 321 and a second sub-work function adjustment pattern 322. The second back gate work function adjustment pattern 330 may include a third sub-work function adjustment pattern 331 and a fourth sub-work function adjustment pattern 332.

According to some example embodiments, the first sub-work function adjustment pattern 321 may include a material different from a material included in the second sub-work function adjustment pattern 322. A work function of the material included in the first sub-work function adjustment pattern 321 may be different from a work function of the material included in the second sub-work function adjustment pattern 322. For example, the work function of the material included in the first sub-work function adjustment pattern 321 may be greater than the work function of the material included in the second sub-work function adjustment pattern 322.

According to some example embodiments, the third sub-work function adjustment pattern 331 may include a material different from a material included in the fourth sub-work function adjustment pattern 332. A work function of the material included in the third sub-work function adjustment pattern 331 may be different from a work function of the material included in the fourth sub-work function adjustment pattern 332. For example, the work function of the material included in the third sub-work function adjustment pattern 331 may be greater than the work function of the material included in the fourth sub-work function adjustment pattern 332.

FIG. 17 illustrates that both the first back gate work function adjustment pattern 320 and the second back gate work function adjustment pattern 330 include the multilayer, but example embodiments are not limited thereto. For example, one of the first back gate work function adjustment pattern 320 and the second back gate work function adjustment pattern 330 may include a multilayer and the other may include a single layer.

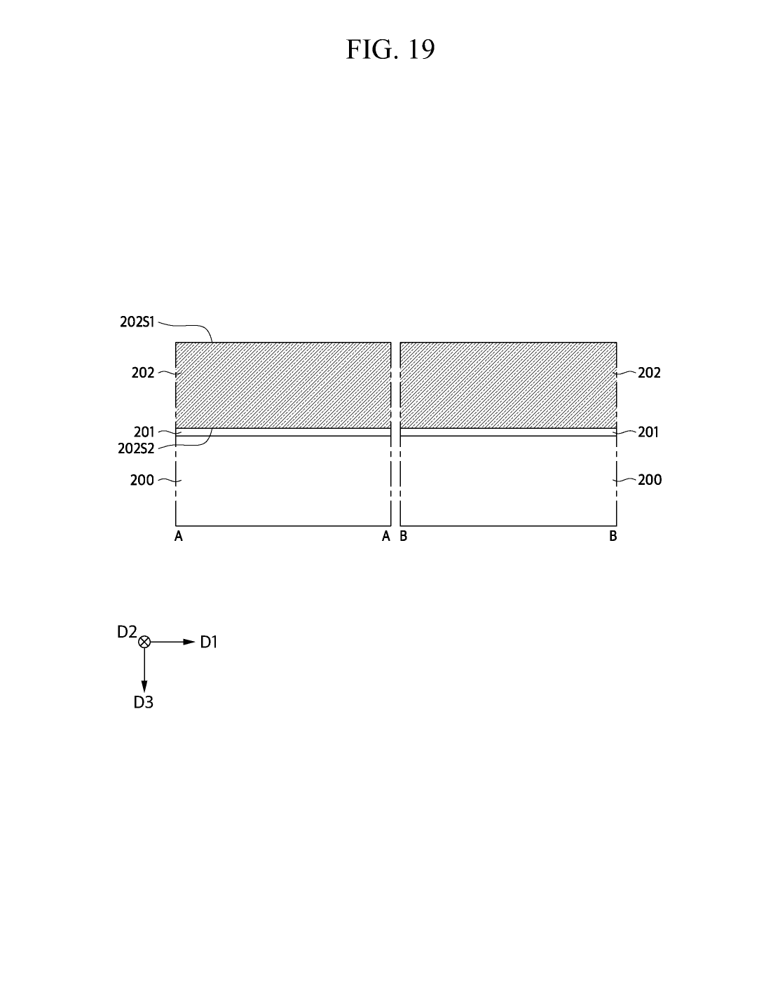

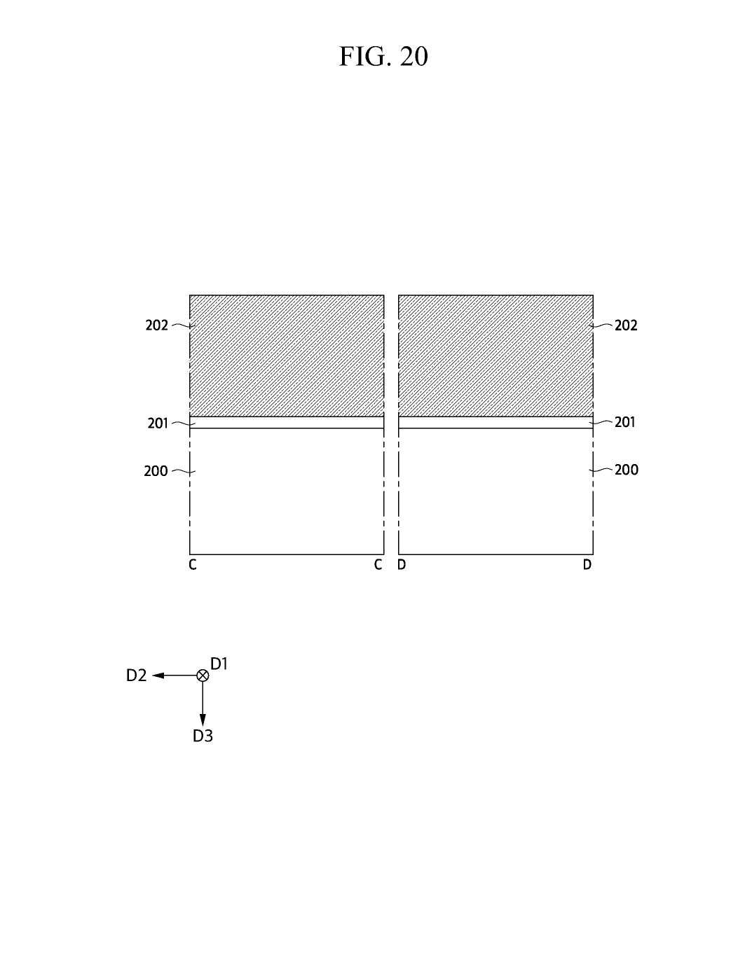

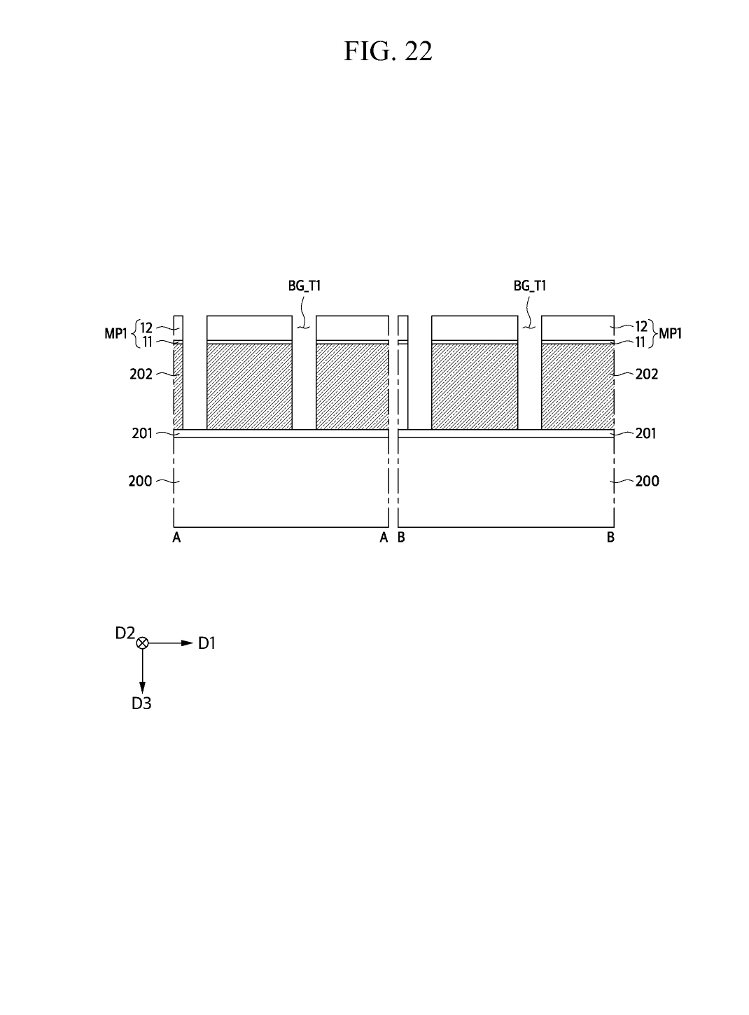

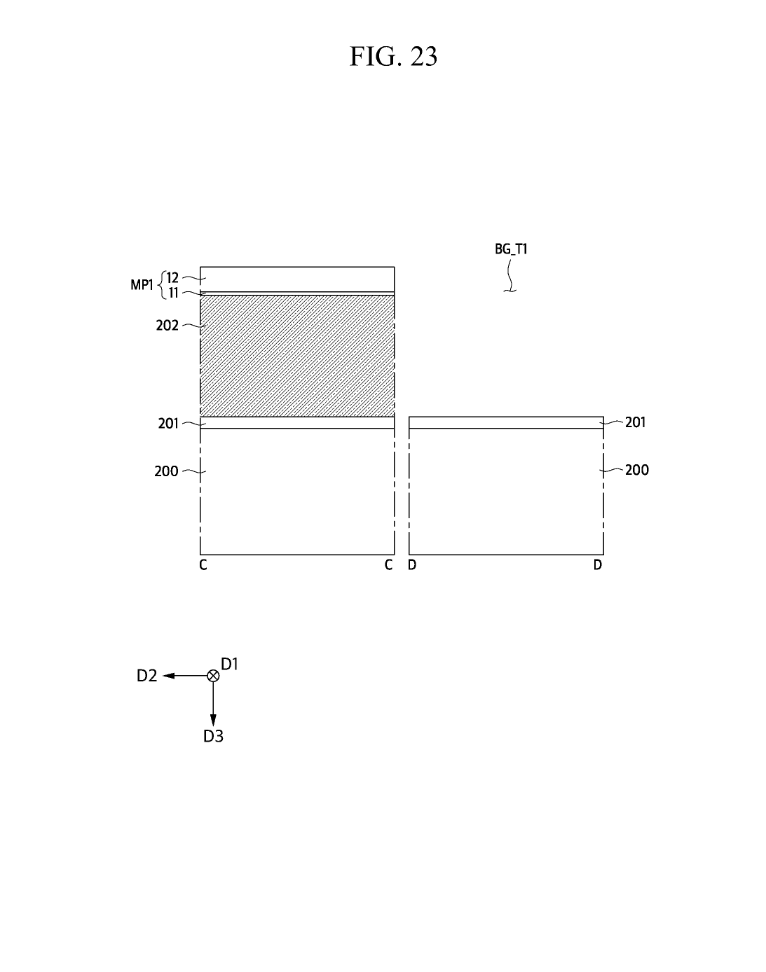

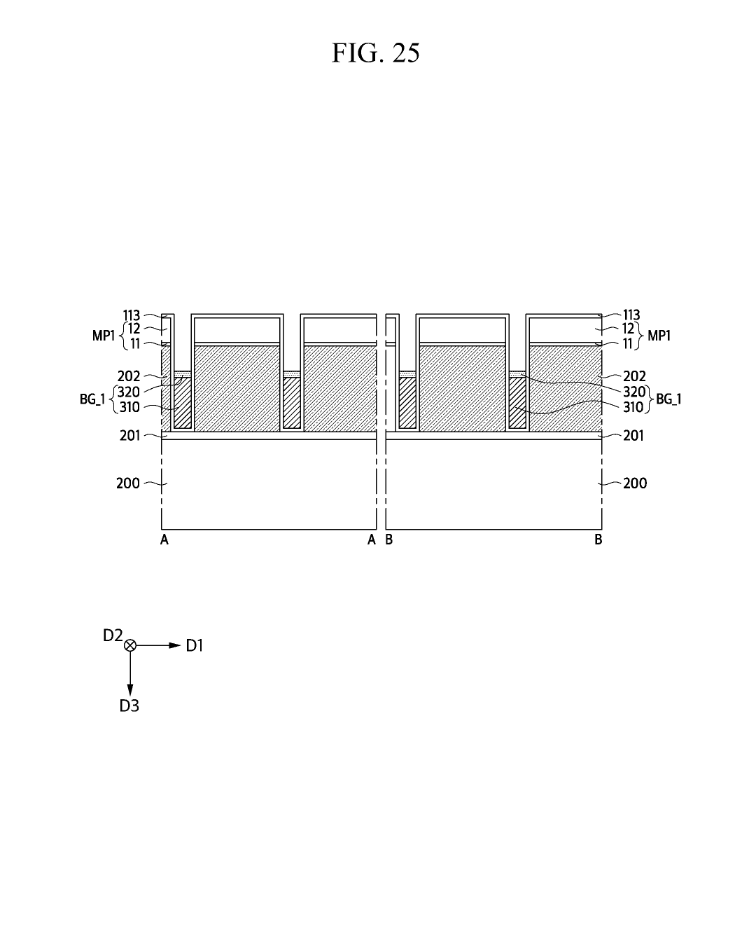

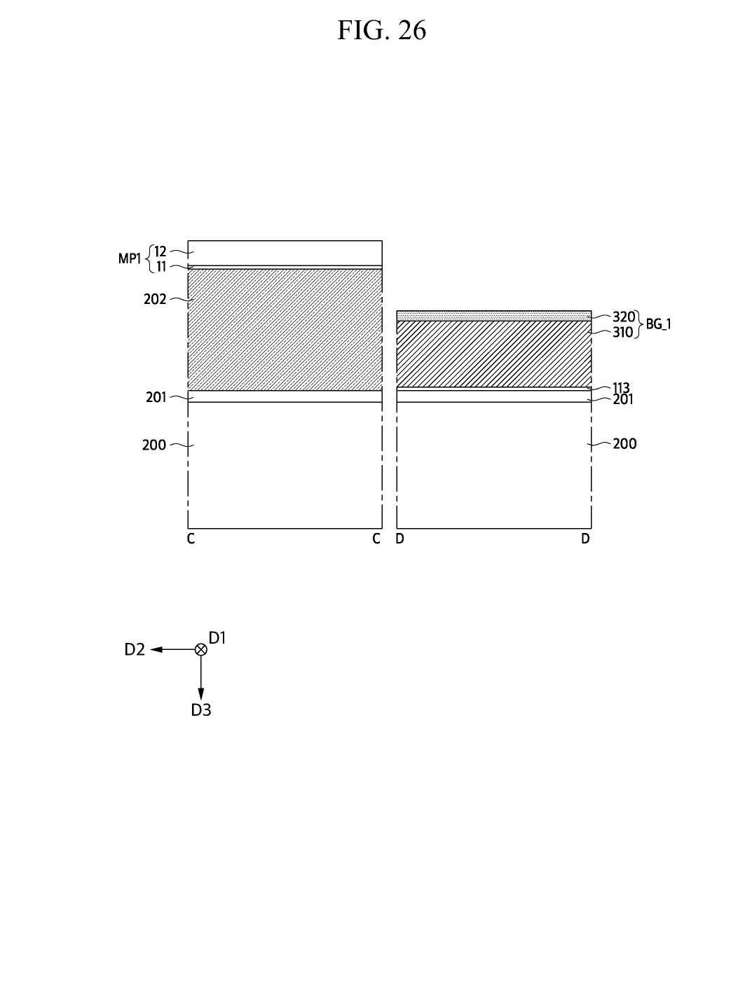

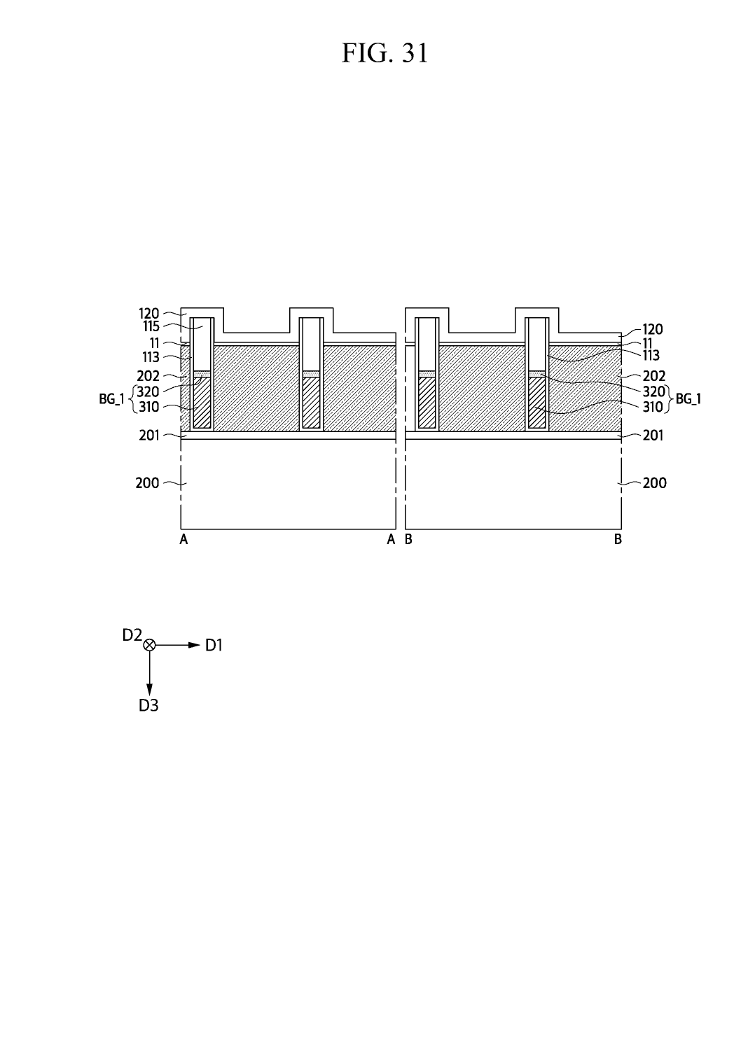

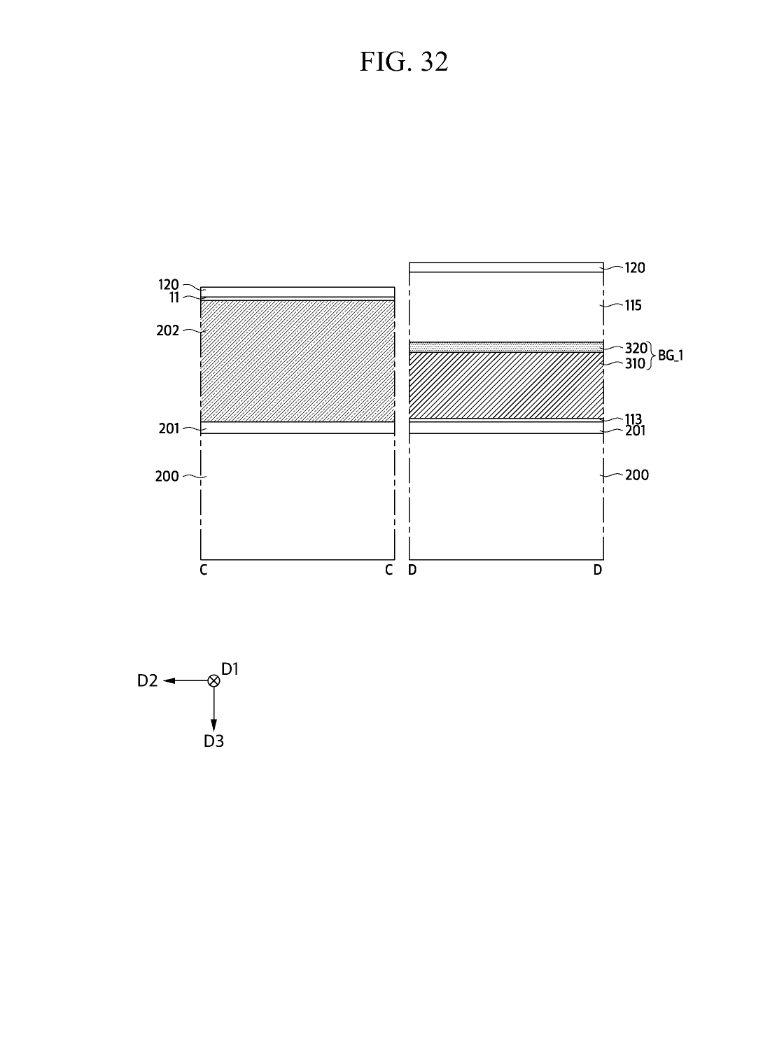

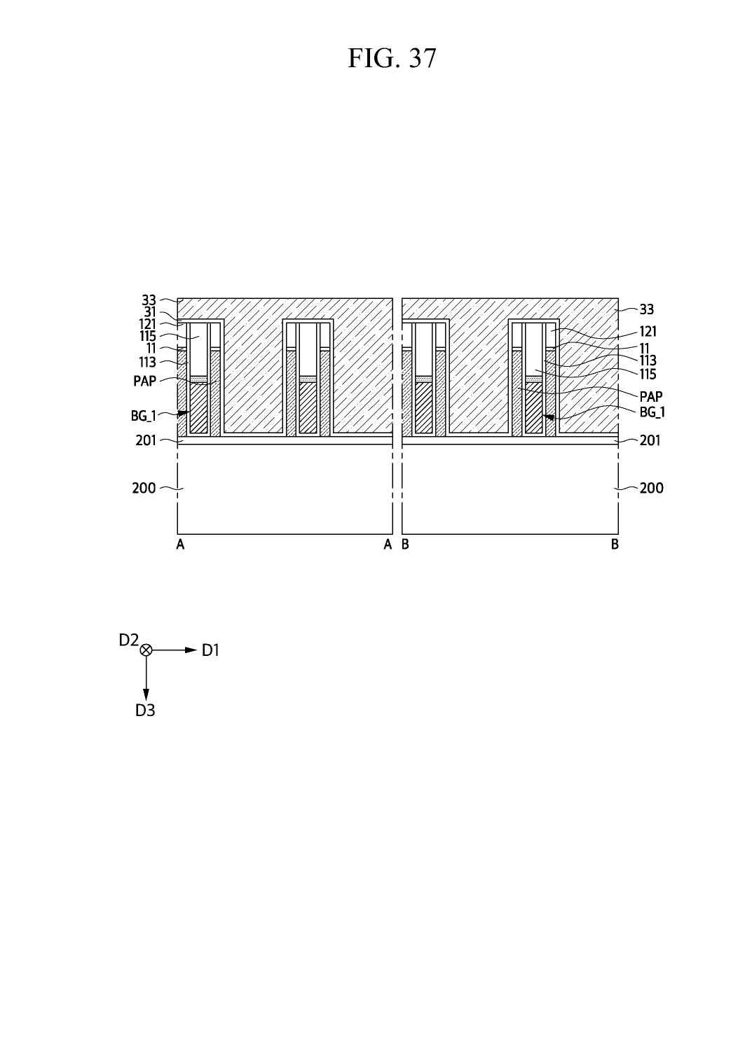

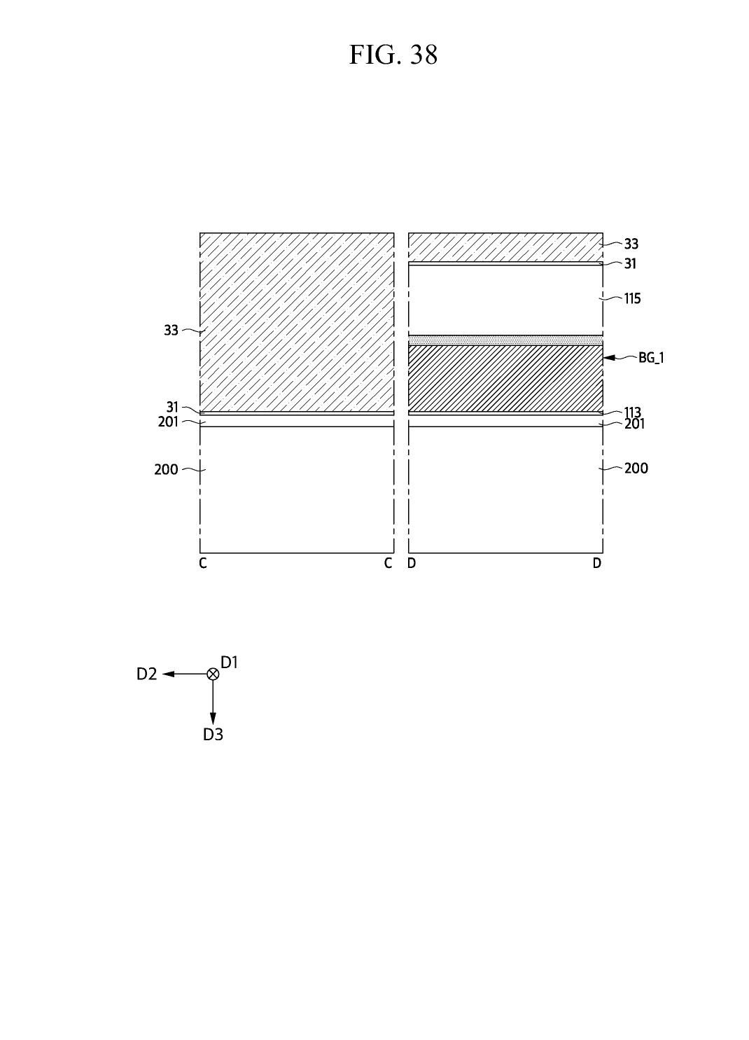

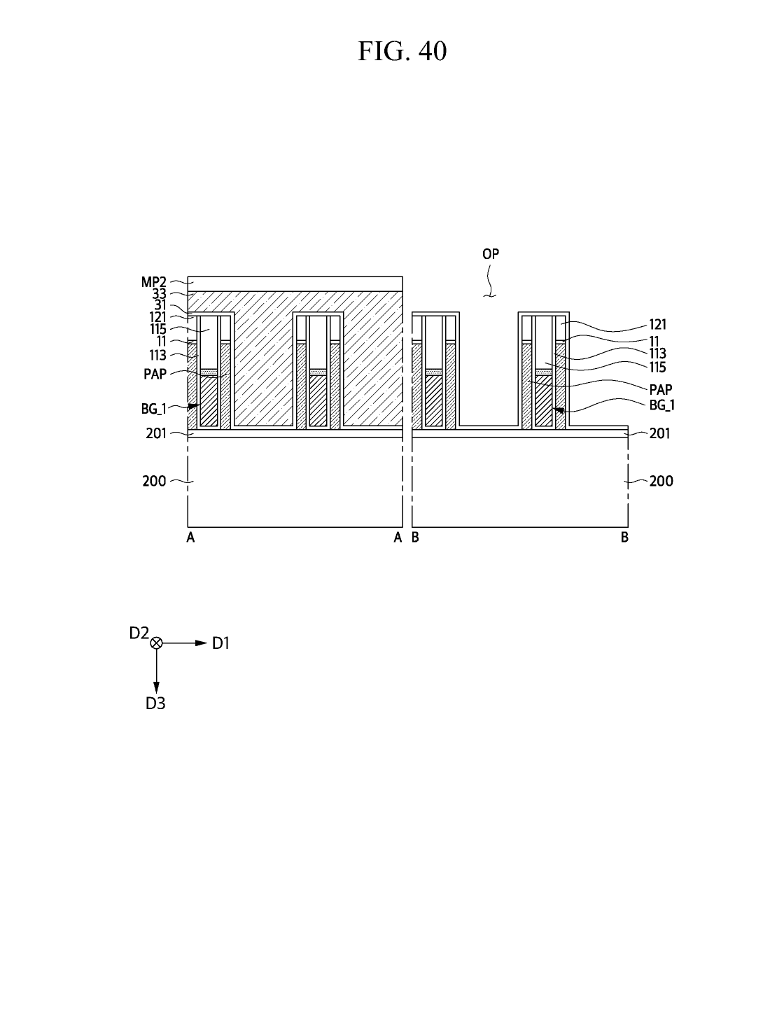

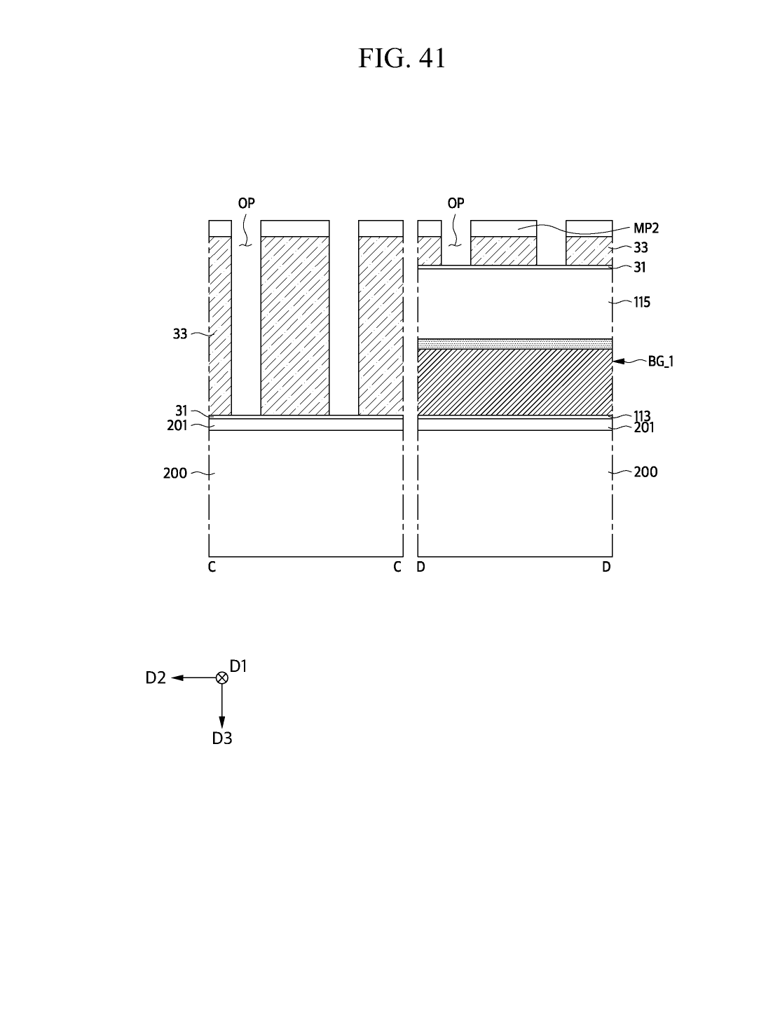

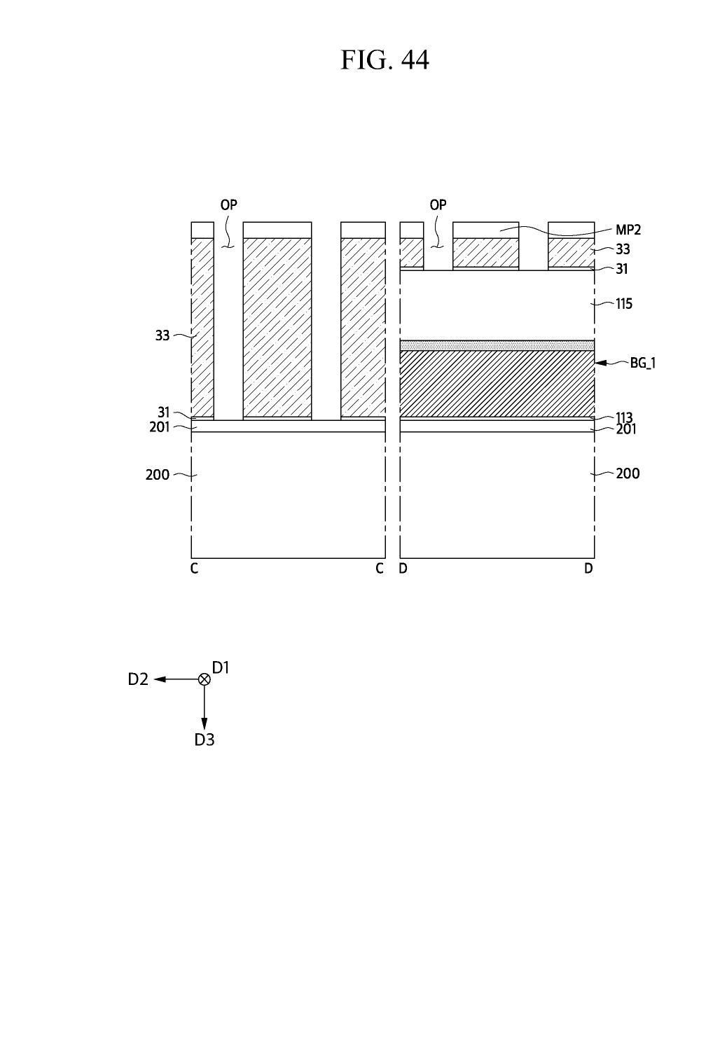

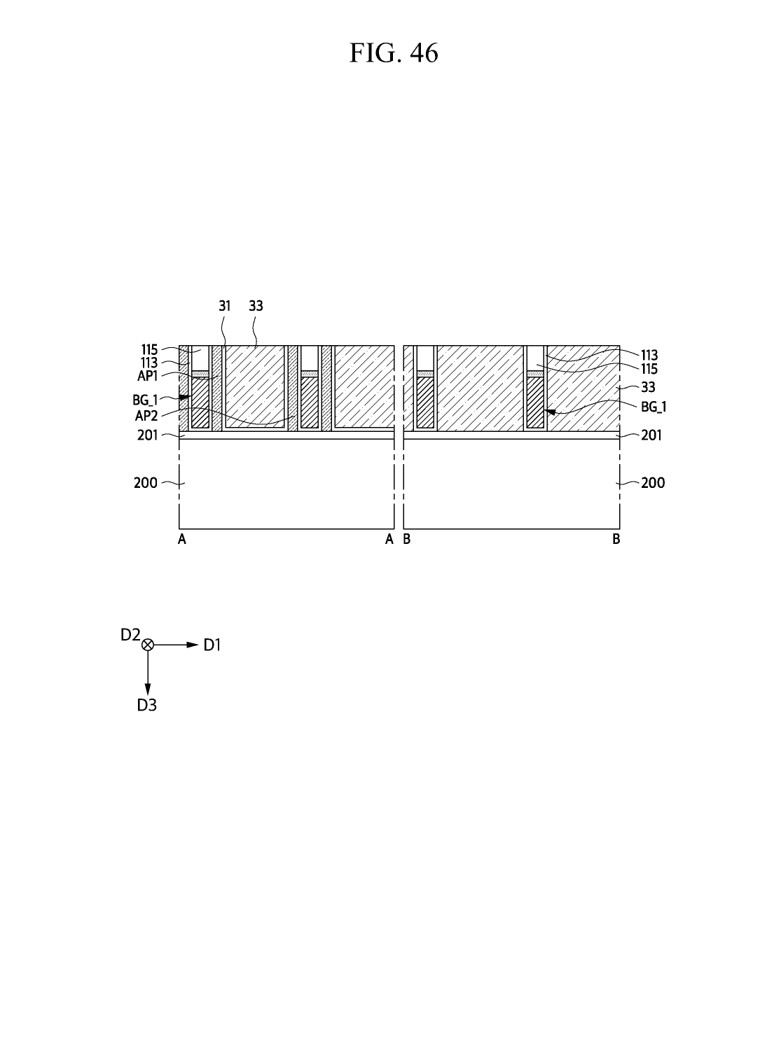

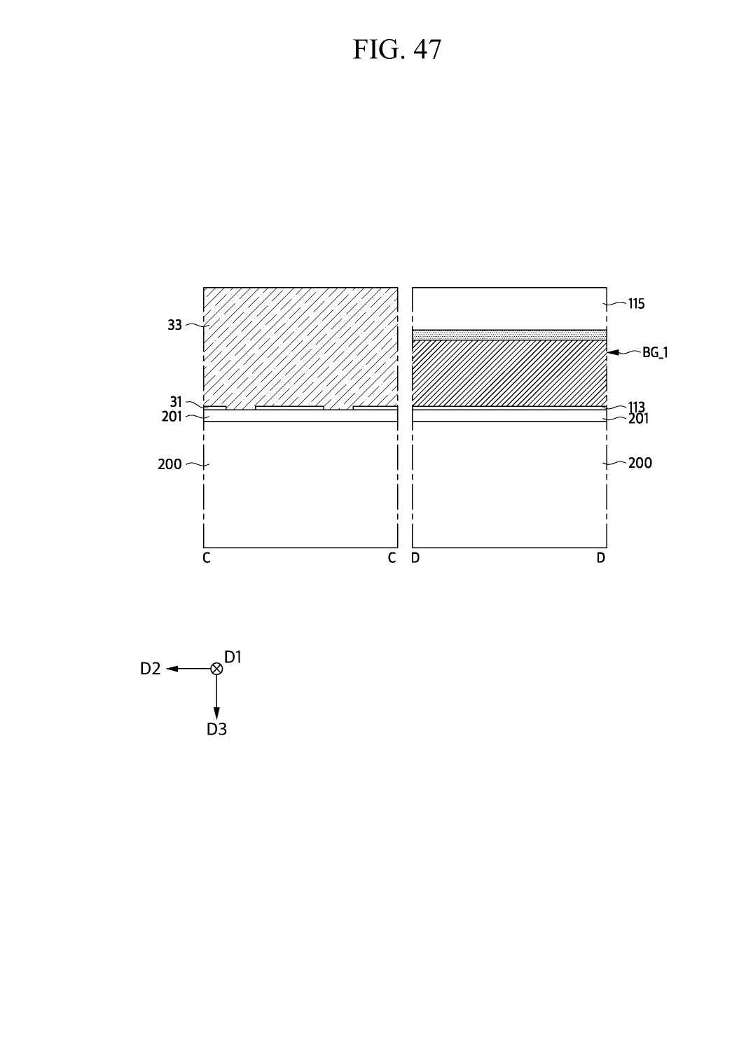

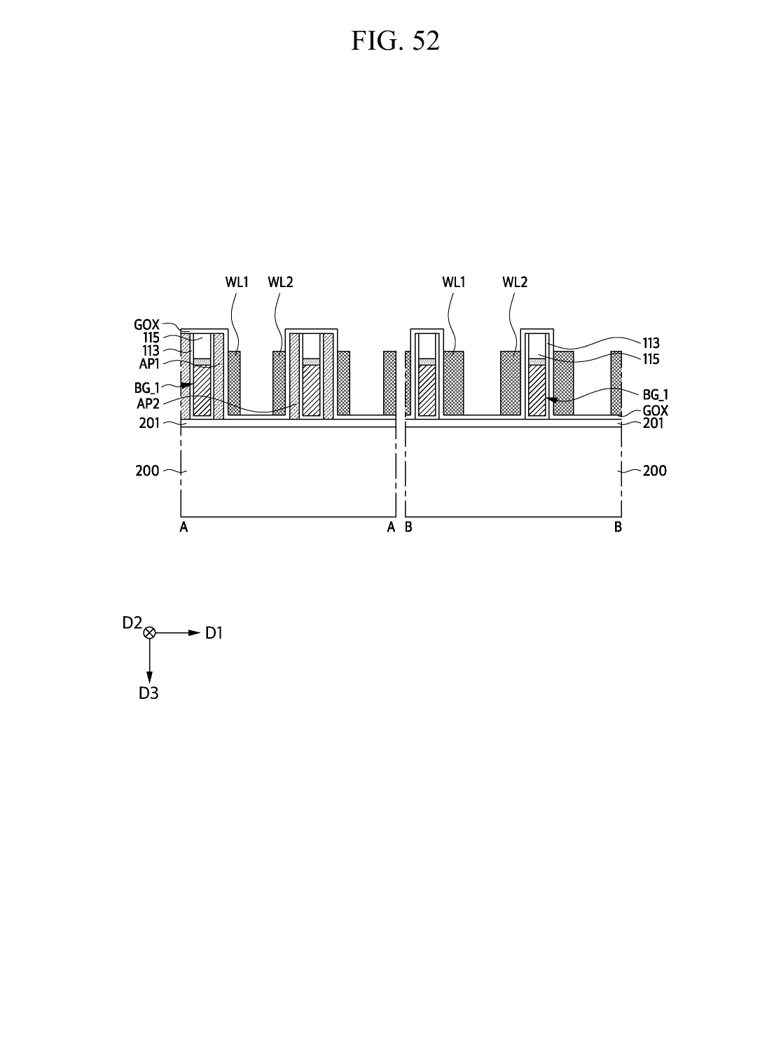

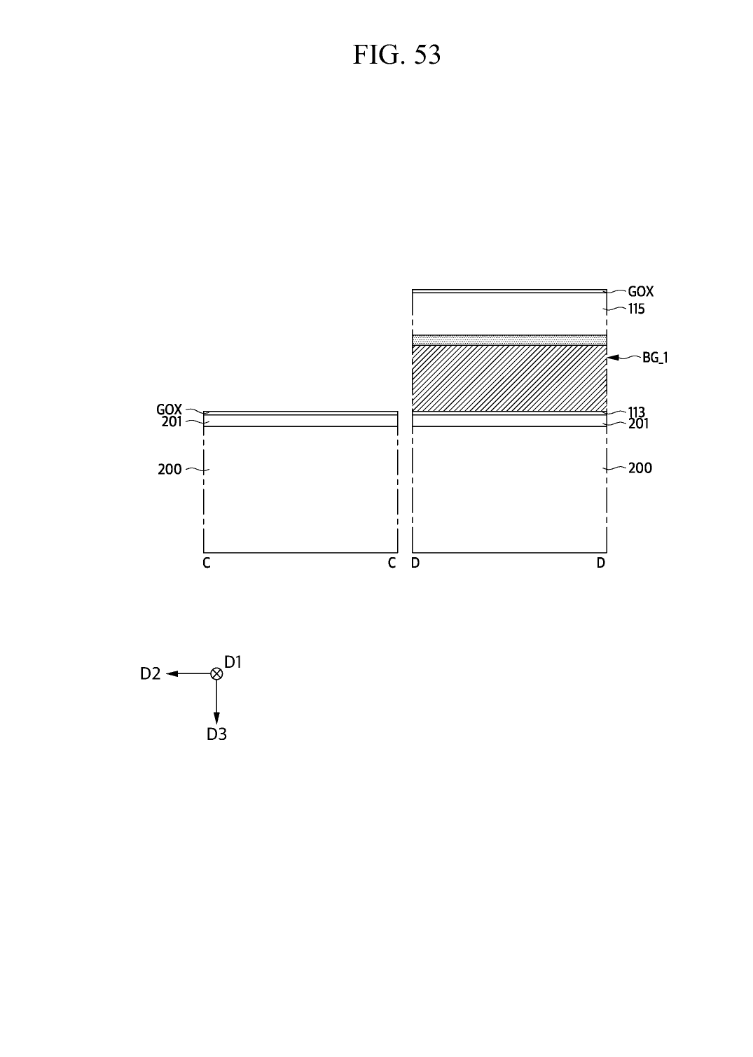

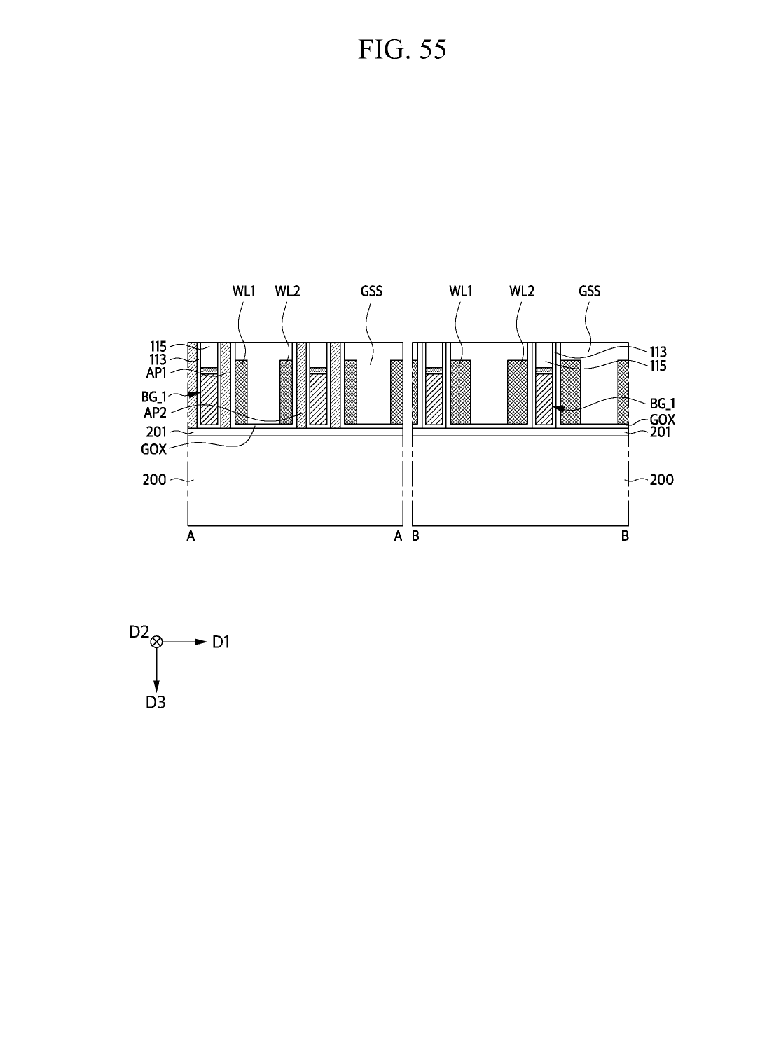

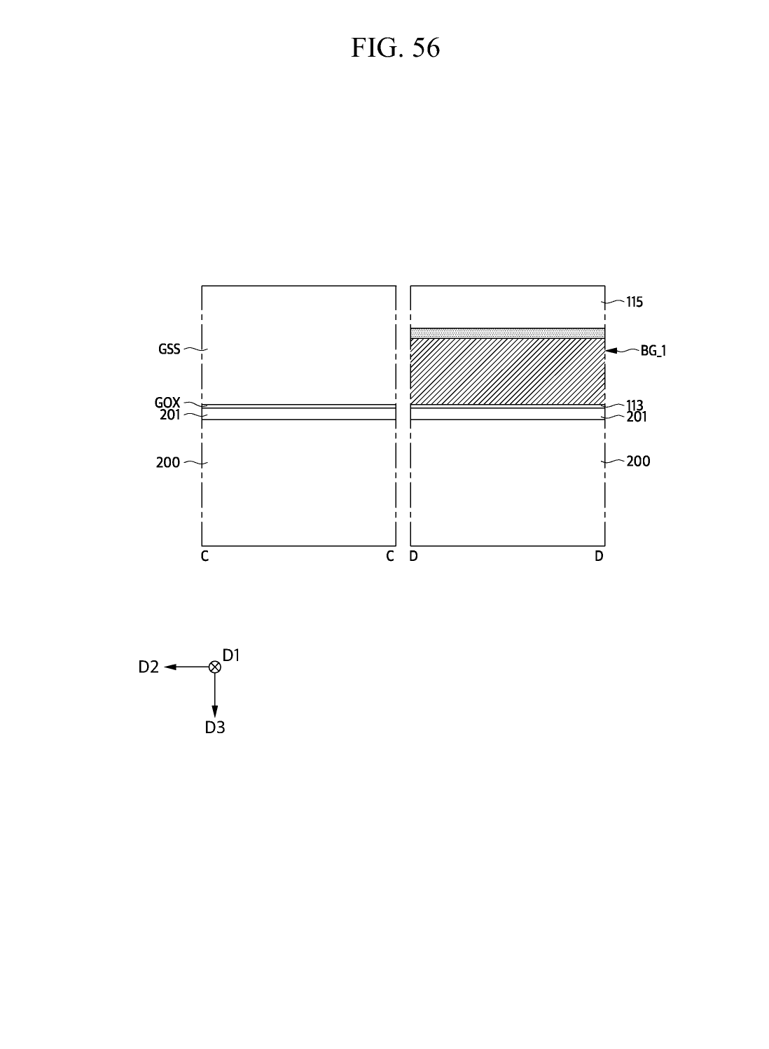

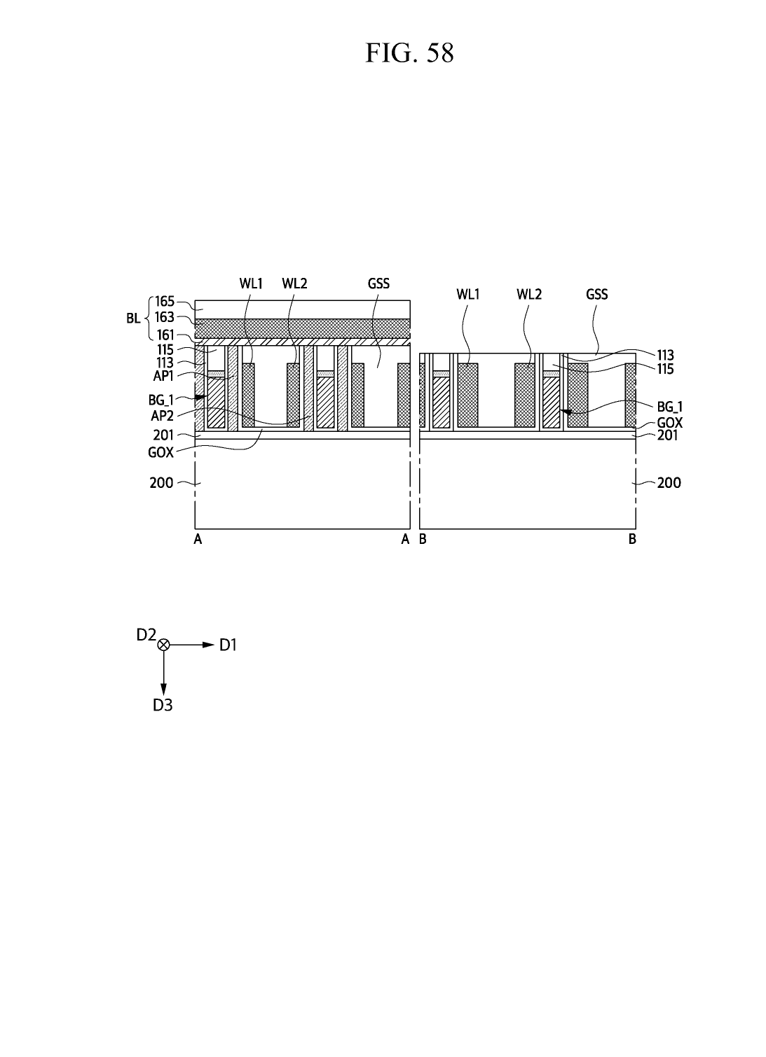

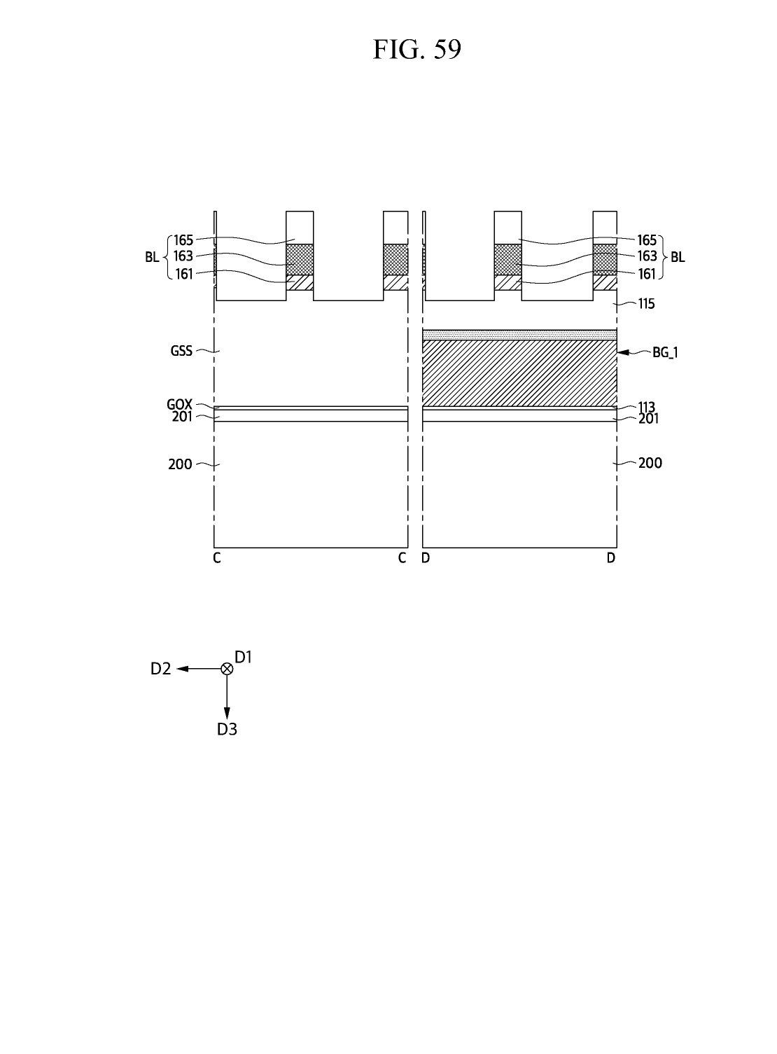

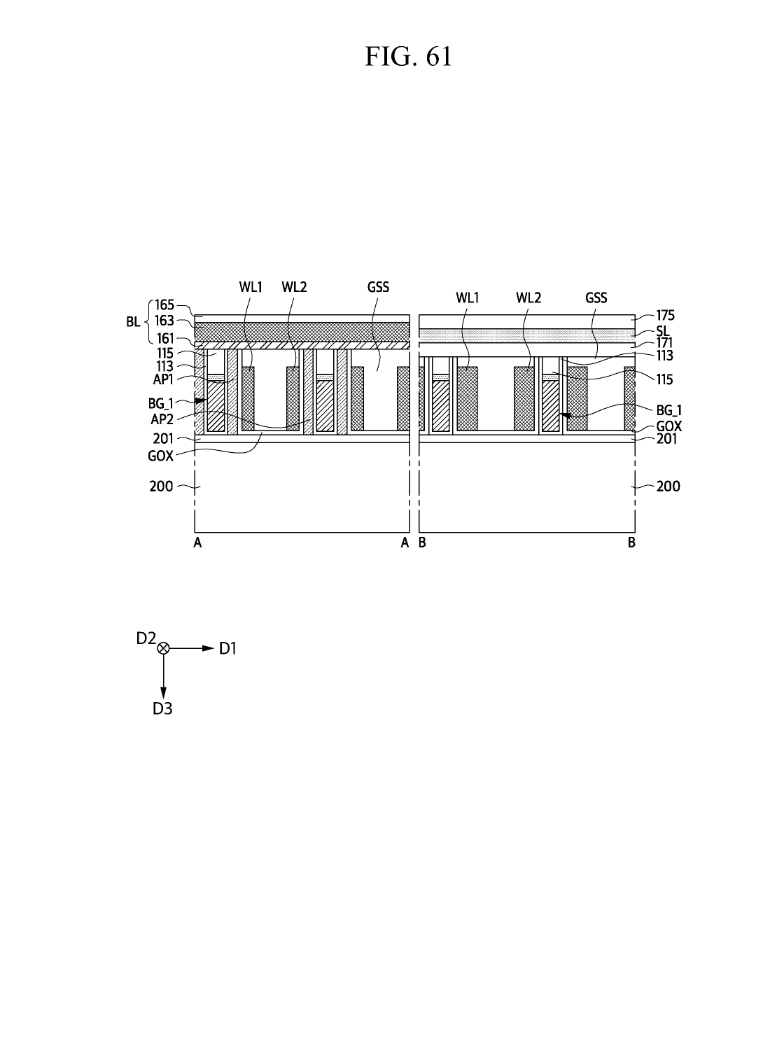

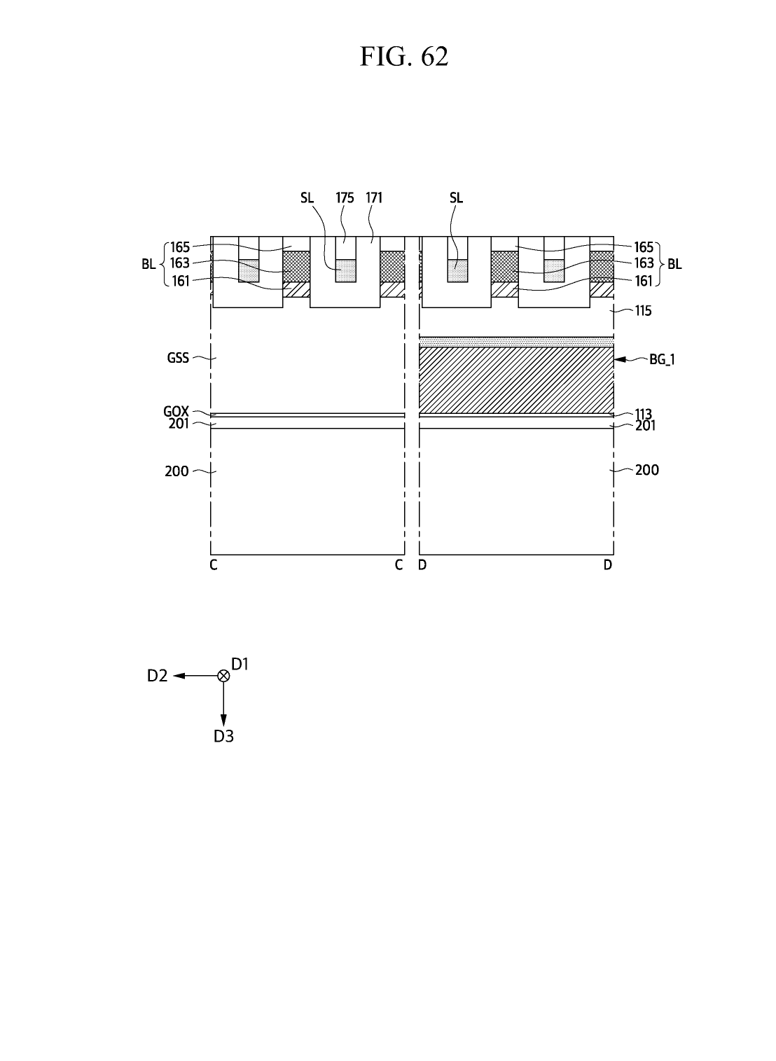

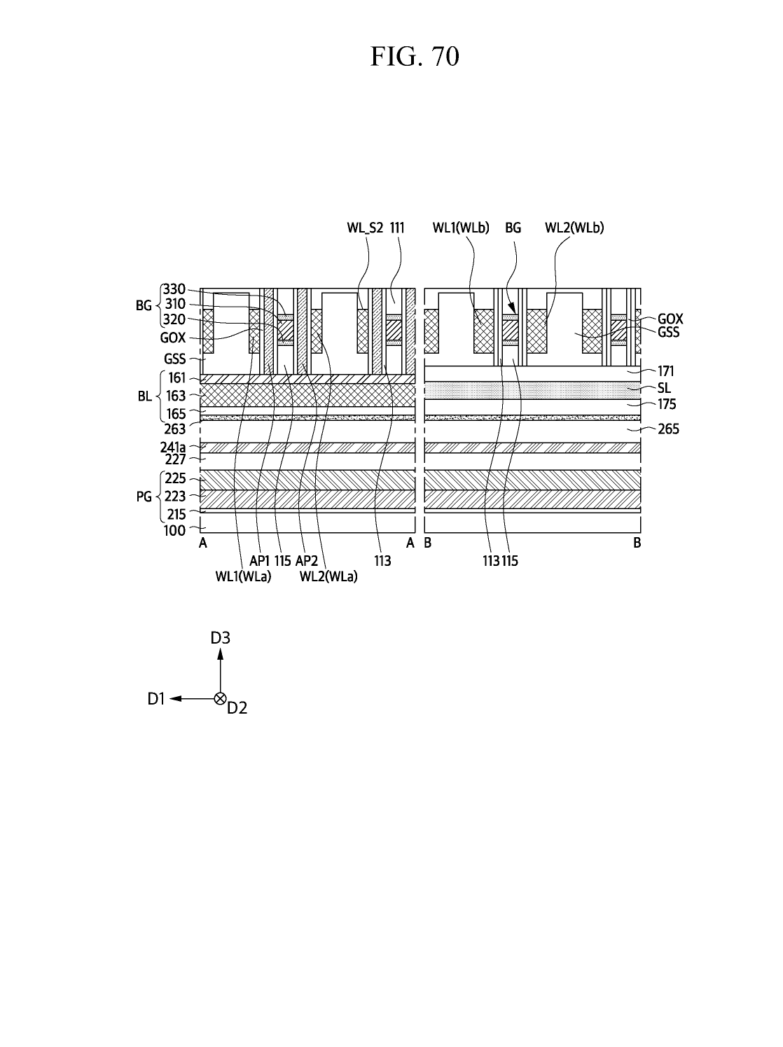

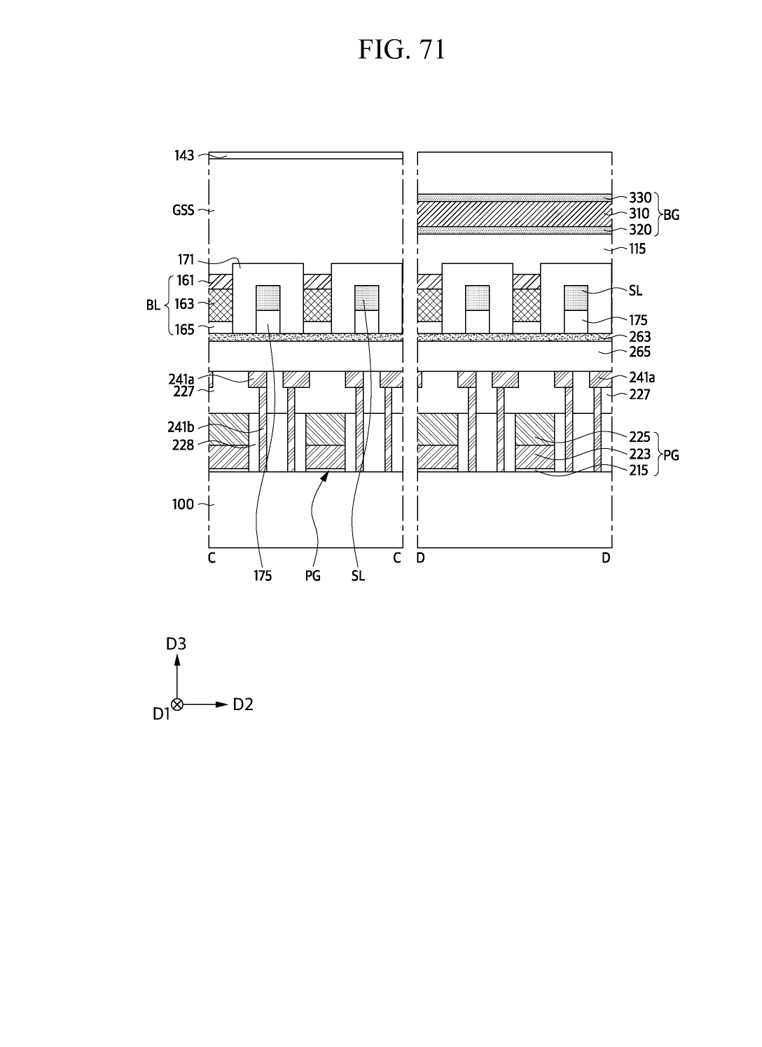

FIGS. 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 4950, 51, 52, 53, 54, 55, 56, 57, 58, 59, 60, 61, 62, 63, 64, 65, 66, 67, 68, 69, 70 and 71 are diagrams illustrating operations of a method of fabricating a semiconductor device according to some example embodiments.

Referring to FIGS. 18 - 20, a buried insulating layer 201 and an active layer 202 may be formed above a sub-substrate 200.

According to some example embodiments, the buried insulating layer 201 and the active layer 202 may be provided above the sub-substrate 200. The sub-substrate 200, the buried insulating layer 201, and the active layer 202 may be a silicon-on-insulator (SOI) substrate. The sub-substrate 200 may be, for example, a silicon substrate, a germanium substrate, and/or a silicon-germanium substrate.

According to some example embodiments, the buried insulating layer 201 may be buried oxide (BOX) formed by a separation by implanted oxygen (SIMOX) process or a bonding and layer transfer process. In contrast, the buried insulating layer 201 may be an insulating layer formed in a manner of chemical vapor deposition. The buried insulating layer 201 may include, for example, a silicon oxide layer, a silicon nitride layer, a silicon oxynitride layer, and/or a low-permittivity insulating layer.

According to some example embodiments, the active layer 202 may be a single-crystal semiconductor layer. The active layer 202 may be, for example, a single-crystal silicon substrate, a germanium substrate, and/or a silicon-germanium substrate. The active layer 202 may have a first surface 202S1 and a second surface 202S2 disposed opposite to each other in the third direction D3, and the second surface 202S2 of the active layer 202 may contact the buried insulating layer 201.

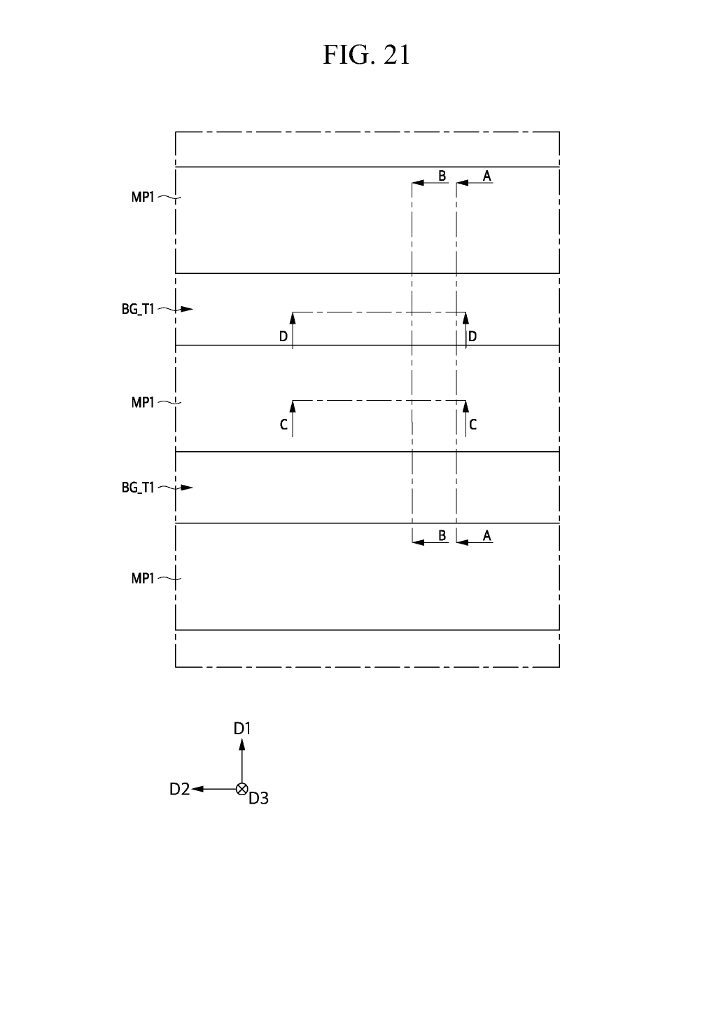

Referring to FIGS. 21 - 23, a first back gate trench BG_T1 may be formed using a back gate mask pattern MP1.

According to some example embodiments, the back gate mask pattern MP1 may be formed on the active layer 202. The back gate mask pattern MP1 may have opening portions in the form of a line extending along the second direction D2. The back gate mask pattern MP1 may include a first lower mask layer 11 and a first upper mask layer 12, which are stacked in sequence. The first upper mask layer 12 may include a material having etch selectivity with respect to the first lower mask layer 11. As an example, the first lower mask layer 11 may include silicon oxide and the first upper mask layer 12 may include silicon nitride, but example embodiments are not limited thereto.

Subsequently, using the back gate mask pattern MP1 as an etch mask, the active layer 202 may be anisotropically etched. Accordingly, the first back gate trench BG_T1 extending in the second direction D2 may be formed in the active layer 202. The first back gate trench BG_T1 may expose the buried insulating layer 201. The first back gate trench BG_T1 may be provided as a plurality of first back gate trenches BG_T1, and the plurality of first back gate trenches BG_T1 may be spaced apart from each other in the first direction D1.

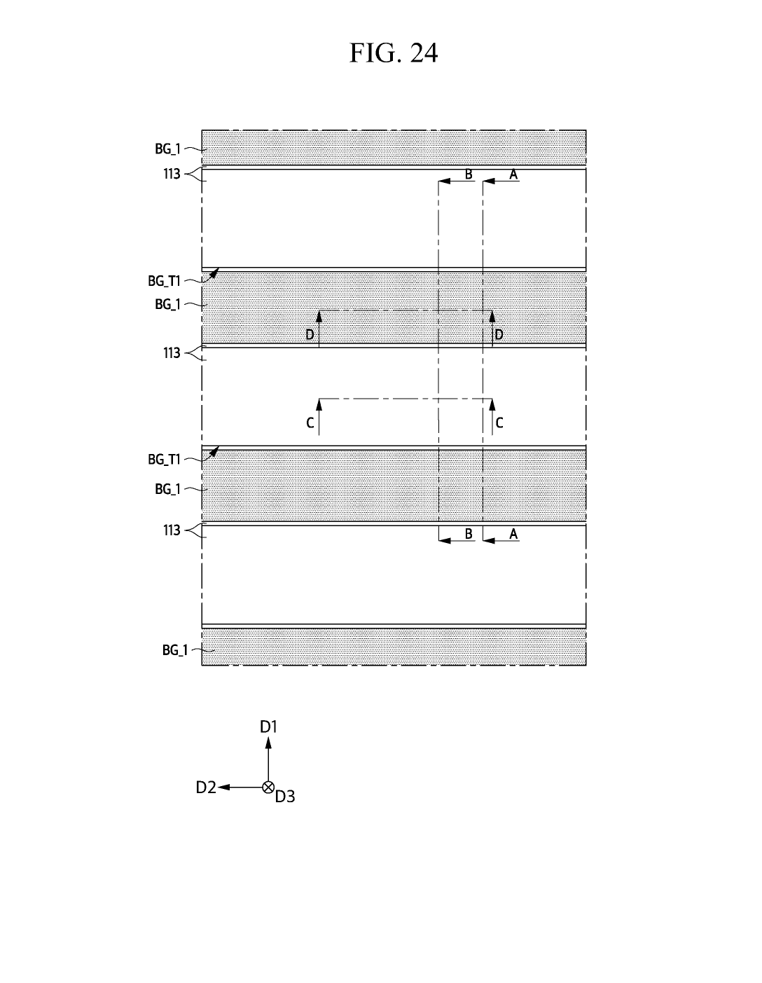

Referring to FIGS. 24 - 26, the back gate side insulating pattern 113 and a pre-back gate electrode BG_1 may be formed within the first back gate trench BG_T1. Hereinafter, “pre-” may represent an element before completion.

According to some example embodiments, the back gate side insulating pattern 113 may be formed along a sidewall and a bottom surface of the first back gate trench BG_T1 and an upper surface of the back gate mask pattern MP1. The back gate body pattern 310 and the first back gate work function adjustment pattern 320 may be formed on the back gate side insulating pattern 113. The back gate body pattern 310 and the first back gate work function adjustment pattern 320 may fill the first back gate trench BG_T1. Subsequently, by isotropically etching the back gate body pattern 310 and the first back gate work function adjustment pattern 320, the pre-back gate electrodes BG_1 extending in the second direction D2 may be formed. The pre-back gate electrode BG_1 may fill a portion of the first back gate trench BG_T1.

According to some example embodiments, before the back gate side insulating pattern 113 is formed, a gas phase doping (GPD) process or a plasma doping (PLAD) process may be performed. Through the above process, the active layer 202 exposed by the first back gate trench BG_T1 may be doped with an impurity.

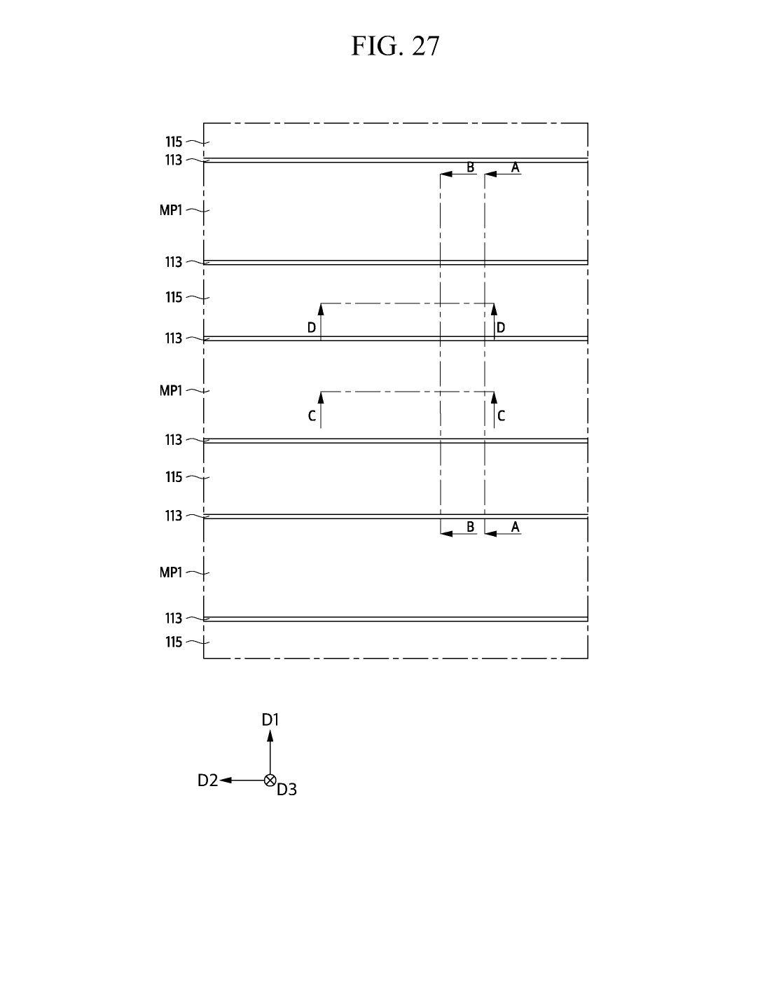

Referring to FIGS. 27 - 29, the back gate capping pattern 115 may be formed on the pre-back gate electrode BG_1.

According to some example embodiments, the back gate capping pattern 115 may fill the remainder of the first back gate trench BG_T1. If the back gate capping pattern 115 and the back gate side insulating pattern 113 include the same material (for example, silicon oxide), the back gate side insulating pattern 113 on the upper surface of the back gate mask pattern MP1 may be removed while the back gate capping pattern 115 is formed.

Before the back gate capping pattern 115 is formed, a GPD process or a PLAD process may be performed. Through this, the active layer 202 may be doped with impurities through the first back gate trench BG_T1 where the pre-back gate electrode BG_1 is formed.

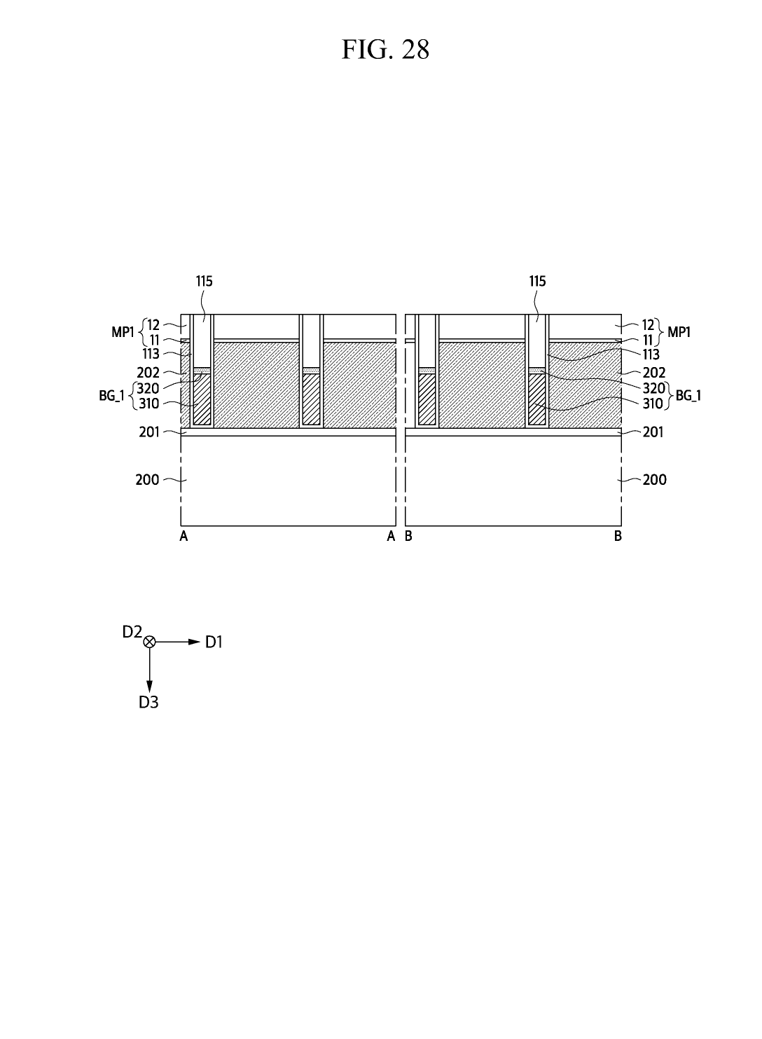

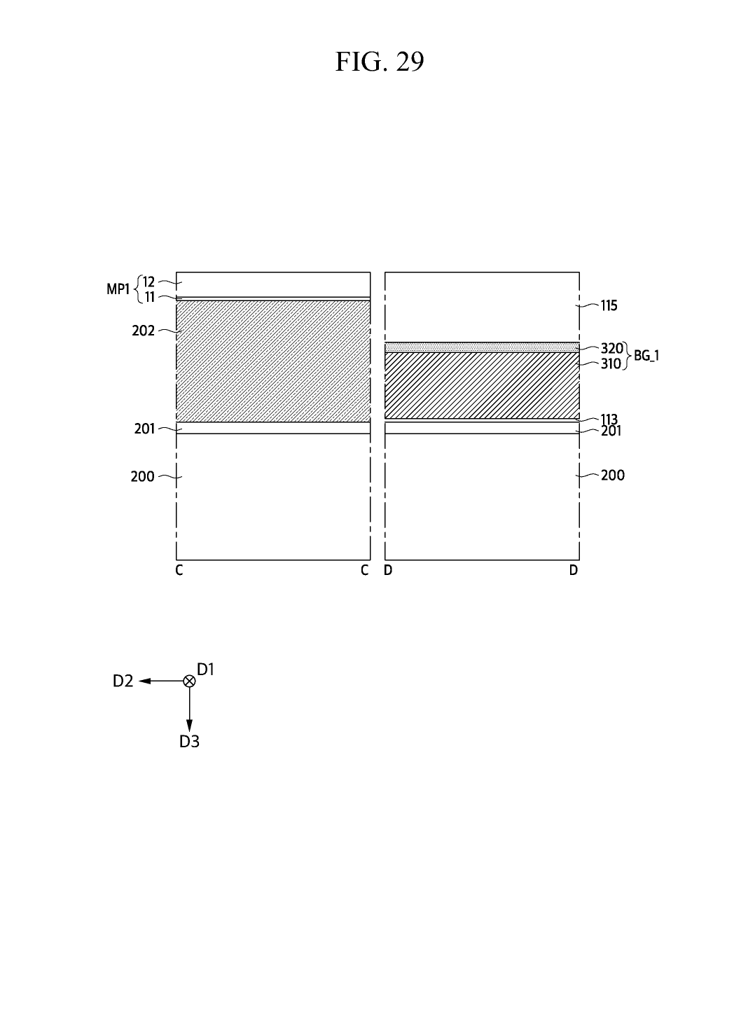

According to some example embodiments, after the back gate capping pattern 115 is formed, the first upper mask layer 12 of FIGS. 28 and 29 may be removed. The back gate capping pattern 115 may have the form of protruding higher than an upper surface of the first lower mask layer 11.

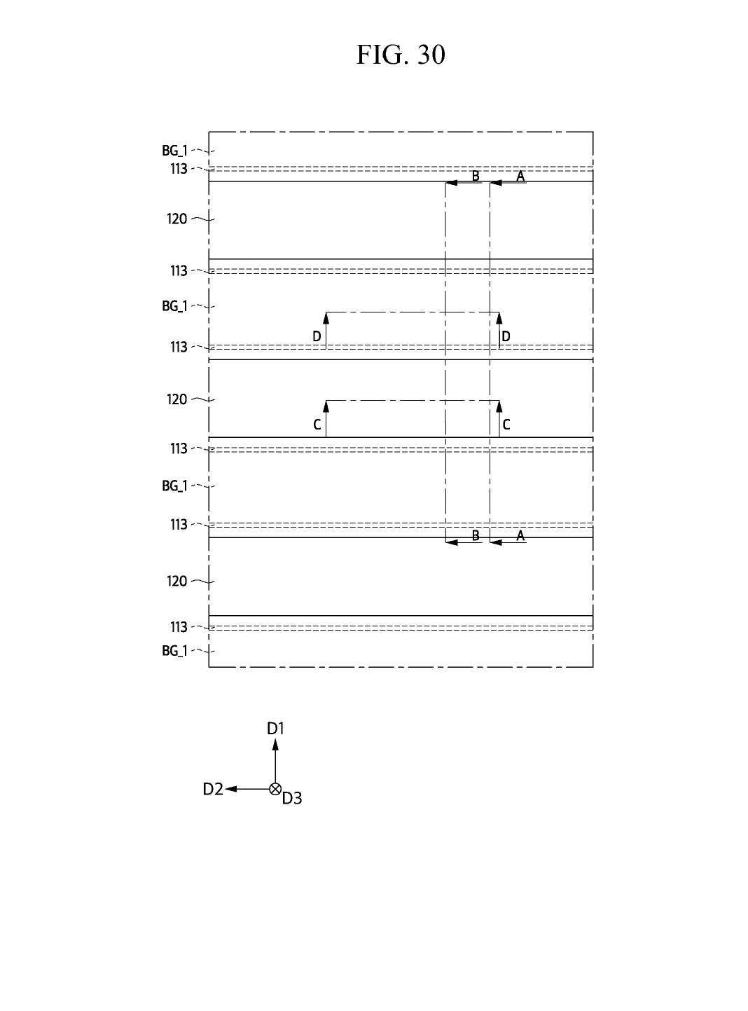

Referring to FIGS. 30 - 32, a spacer layer 120 may be formed along the upper surface of the first lower mask layer 11, a sidewall of the back gate side insulating pattern 113, and an upper surface of the back gate capping pattern 115. The spacer layer 120 may be formed in a uniform thickness. Based on a deposition thickness of the spacer layer 120, a width of an active pattern of a VCT may be determined. The spacer layer 120 may include an insulating material. The spacer layer 120 may include, for example, silicon oxide, silicon oxynitride, silicon nitride, silicon carbide (SiC), silicon carbonitride (SiCN), and a combination thereof. The spacer layer 120 may extend along a surface profile of the back gate capping pattern 115 protruding higher than the upper surface of the first lower mask layer 11.

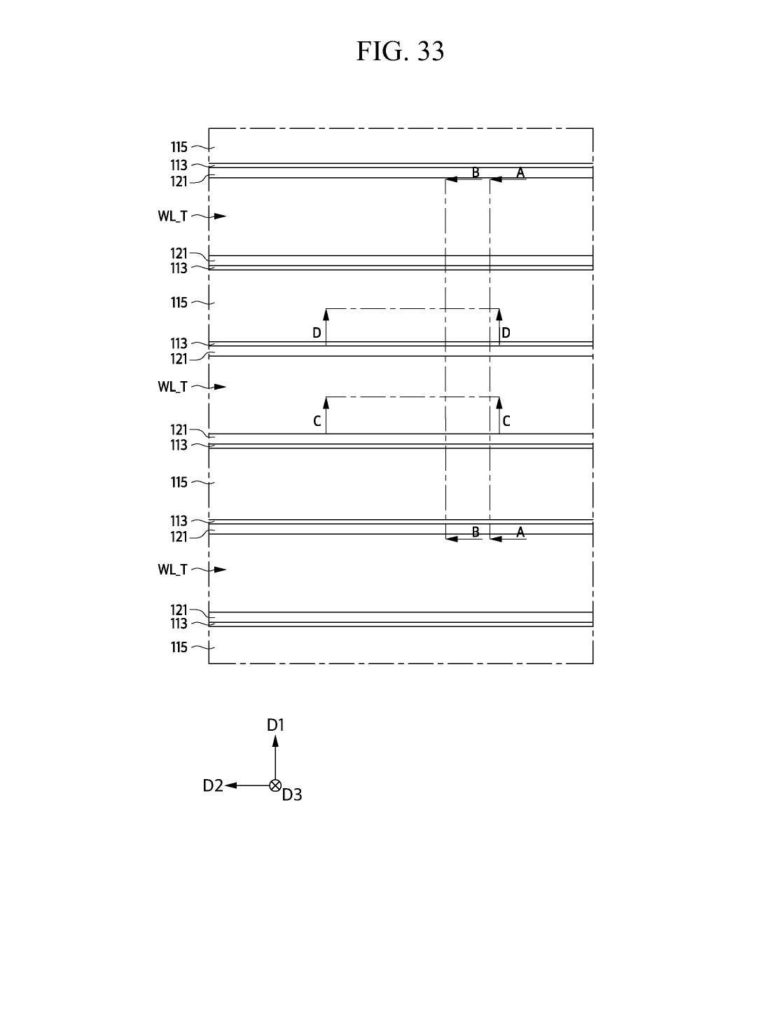

Referring to FIGS. 33 - 35, as an anisotropic etching process on the spacer layer 120 is performed, a pair of spacer patterns 121 may be formed on sidewalls of the back gate side insulating pattern 113.

According to some example embodiments, using the spacer pattern 121 as an etch mask, an anisotropic etching process on the active layer 202 may be performed. Through this, a pair of pre-active patterns PAP separated from each other may be formed at opposite sides of the back gate side insulating pattern 113. As the pre-active pattern PAP is formed, the buried insulating layer 201 may be exposed.

According to some example embodiments, the pre-active pattern PAP may overlap with the first pre-back gate electrode BG_1 when viewed in plan from the first direction D1. The pre-active pattern PAP may have the shape of a line extending in the second direction D2. The pre-active pattern PAP may be provided as a plurality of pre-active patterns PAP. A word line trench WL_T may be formed between the plurality of pre-active patterns PAP spaced apart from each other in the first direction D1.

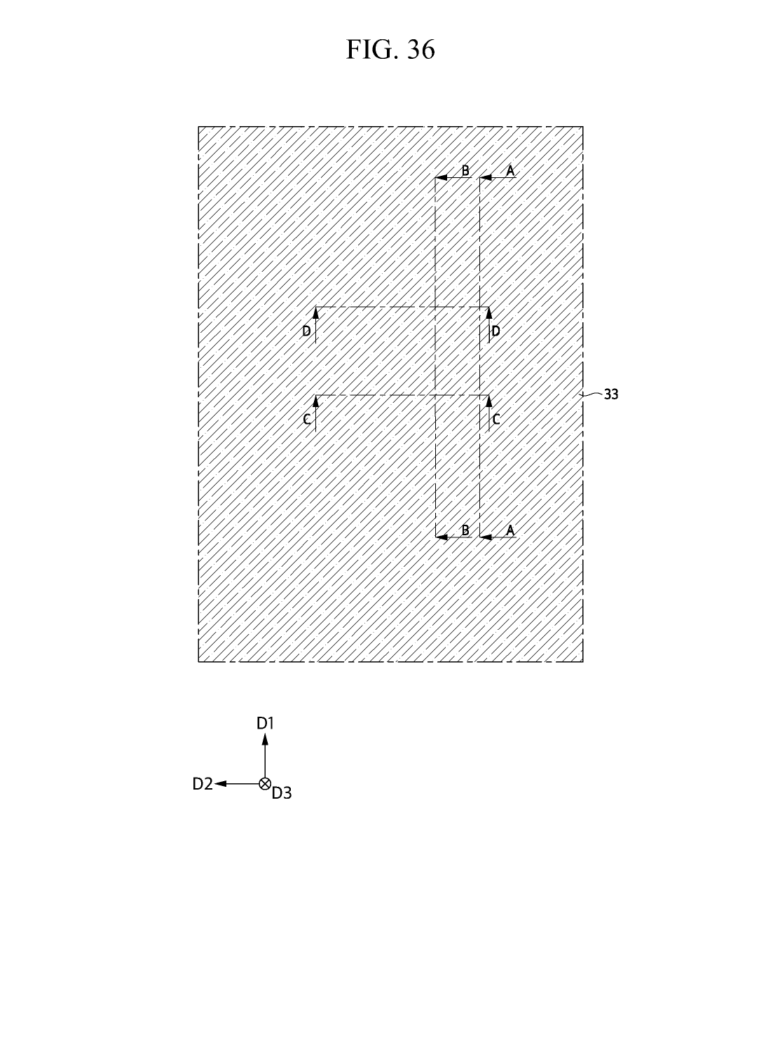

Referring to FIGS. 36 - 38, an etch stop layer 31 may be formed along a sidewall and a bottom surface of the word line trench WL_T.

According to some example embodiments, the etch stop layer 31 and a sacrificial layer 33 may be formed within the word line trench WL_T. The sacrificial layer 33 may fill the word line trench WL_T. The sacrificial layer 33 may have a substantially flat upper surface.

According to some example embodiments, the etch stop layer 31 may be formed by depositing an insulating material, for example, silicon oxide, but is not limited thereto. The sacrificial layer 33 may be formed of an insulating material having etch selectivity with respect to the etch stop layer 31. As an example, the sacrificial layer 33 may be one of insulating materials and a silicon oxide layer formed using a spin-on glass (SOG) technique, but is not limited thereto.

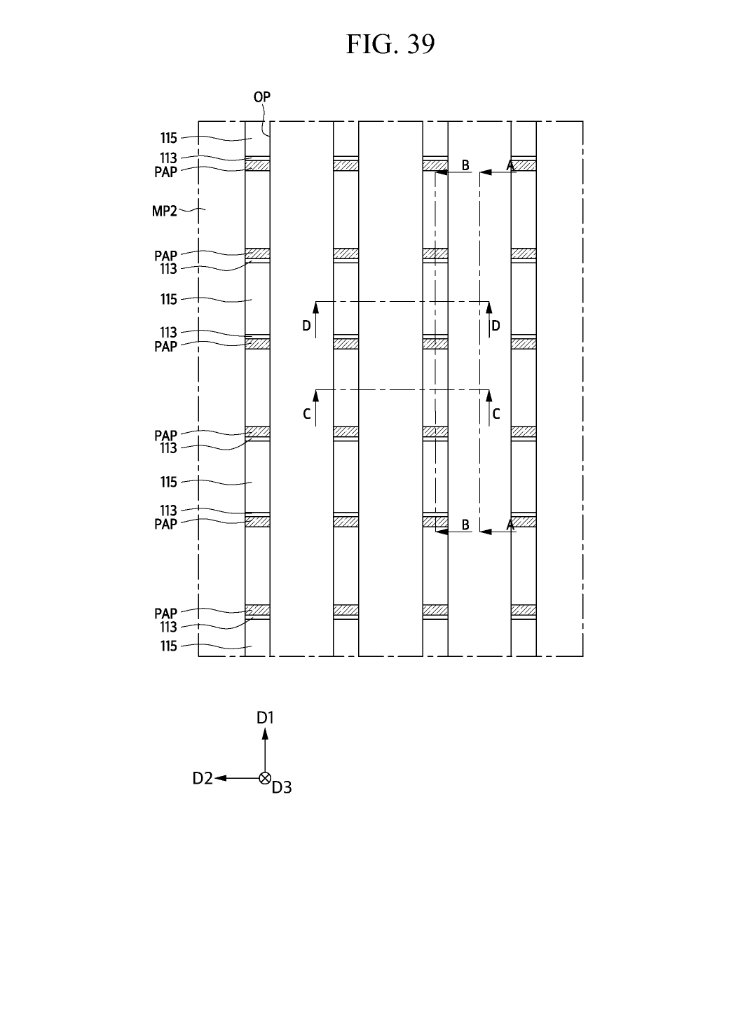

Referring to FIGS. 39 - 41, a second mask pattern MP2 may be formed on the sacrificial layer 33.

According to some example embodiments, the second mask pattern MP2 may be formed of a material having etch selectivity with respect to the sacrificial layer 33. The second mask pattern MP2 may have the form of a line extending in the first direction D1. The second mask pattern MP2 may be provided as a plurality of second mask patterns MP2 spaced apart from each other in the second direction D2.

Subsequently, by etching the sacrificial layer 33 using the second mask pattern MP2 as an etch mask, an opening OP may be formed. The opening OP may expose the etch stop layer 31. The opening OP may penetrate the sacrificial layer 33 in the third direction D3.

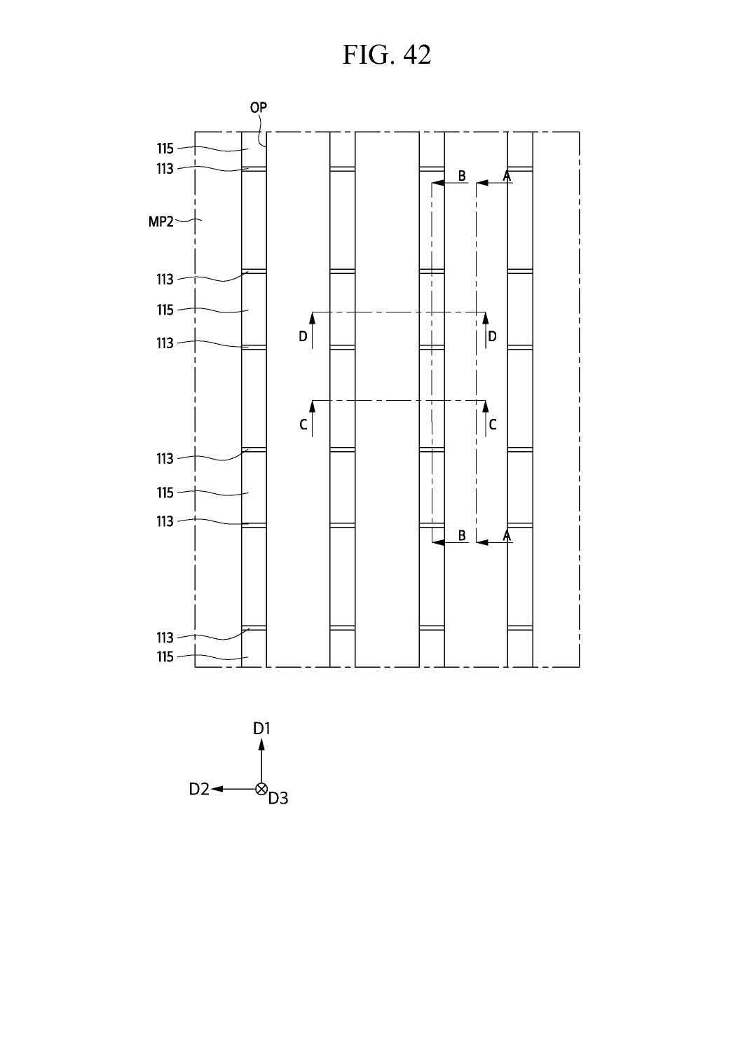

Referring to FIGS. 42 - 44, the etch stop layer 31 exposed by the opening OP may be removed.

According to some example embodiments, the opening OP may expose an upper surface of the buried insulating layer 201. Further, the opening OP may expose a portion of the pre-active pattern PAP.

Subsequently, by etching the pre-active pattern PAP exposed by the opening OP, the first active pattern AP1 and the second active pattern AP2 may be formed at opposite sides of the first pre-back gate electrode BG_1. On a first sidewall of the first pre-back gate electrode BG_1, the plurality of first active patterns AP1 may be formed to be spaced apart from each other in the second direction D2. On a second sidewall of the first pre-back gate electrode BG_1, the plurality of second active patterns AP2 may be formed to be spaced apart from each other in the second direction D2. As the first active pattern AP1 and the second active pattern AP2 are formed, the opening OP may expose a portion of the back gate side insulating pattern 113.

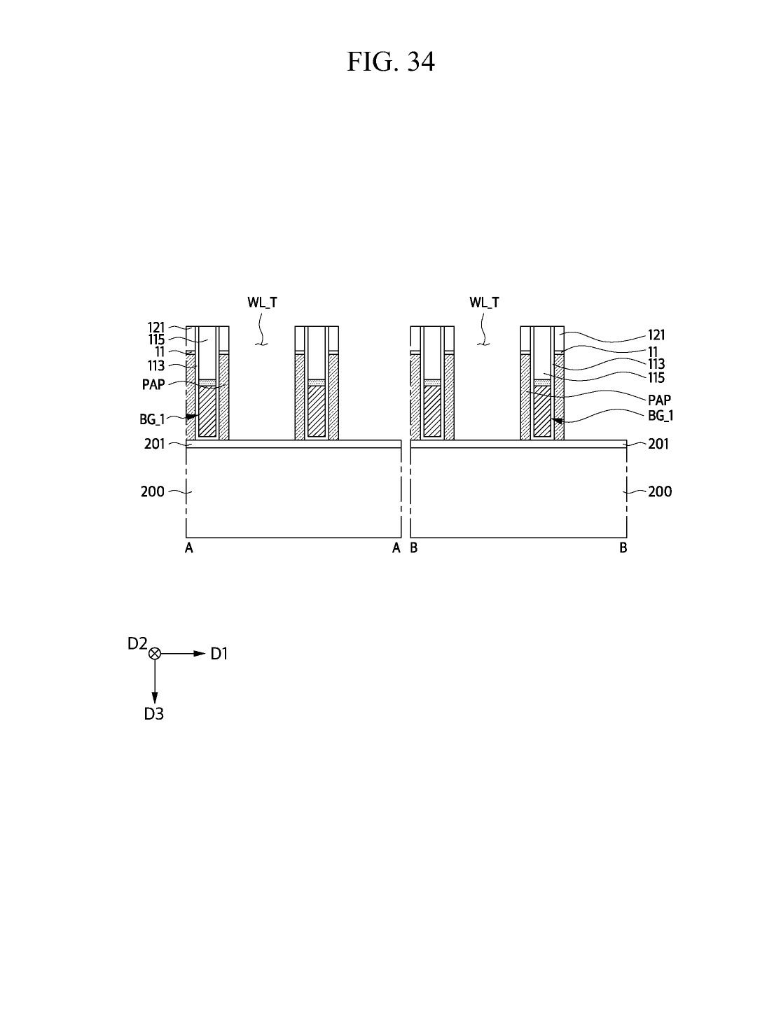

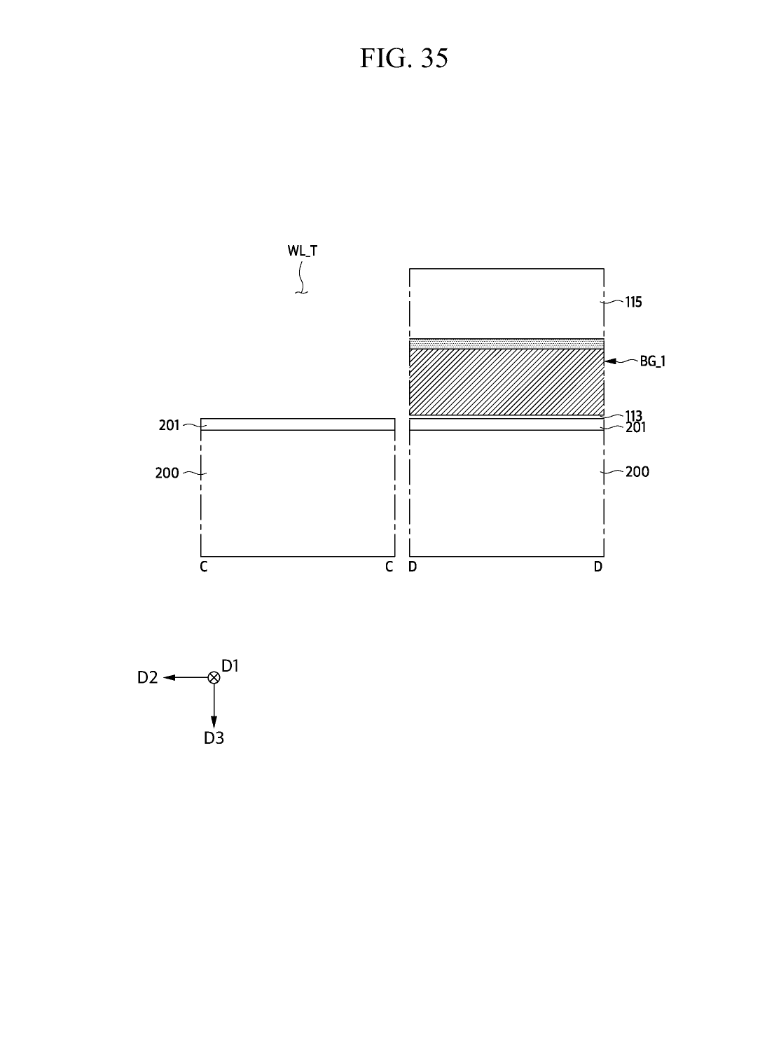

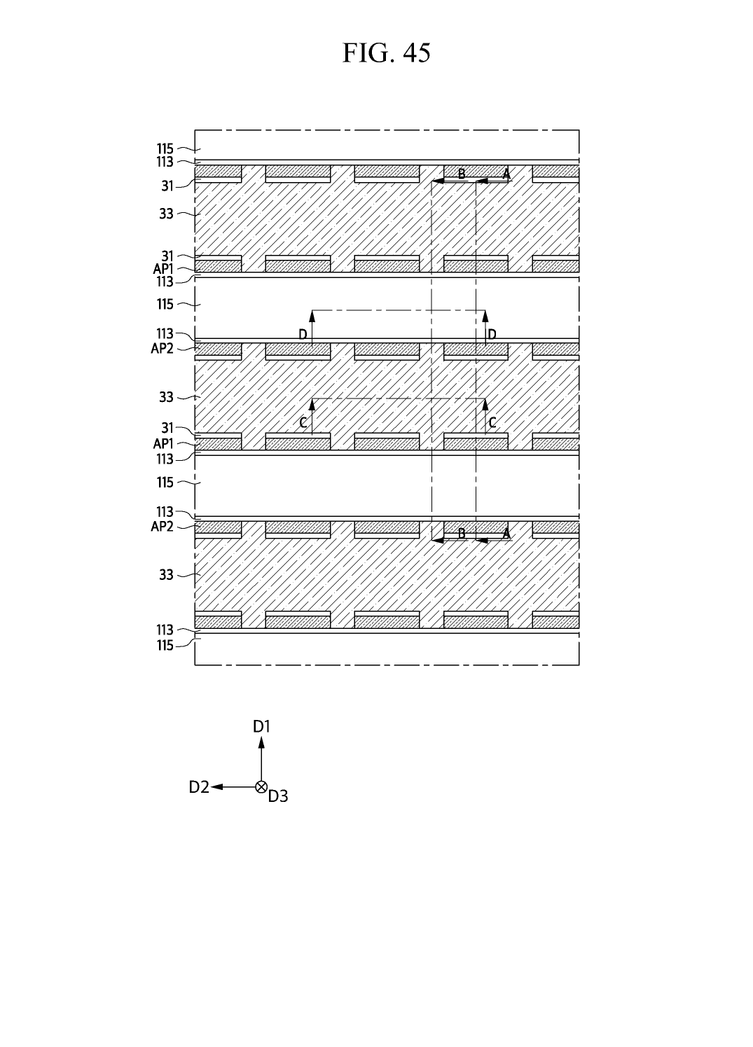

Referring to FIGS. 45 - 47, within the opening OP of FIGS. 42 - 44, the sacrificial layer 33 may be filled. The sacrificial layer 33 filling the opening OP of FIGS. 42 - 44 may have the same material as the sacrificial layer 33 filling the word line trench WL_T of FIGS. 34 and 35.

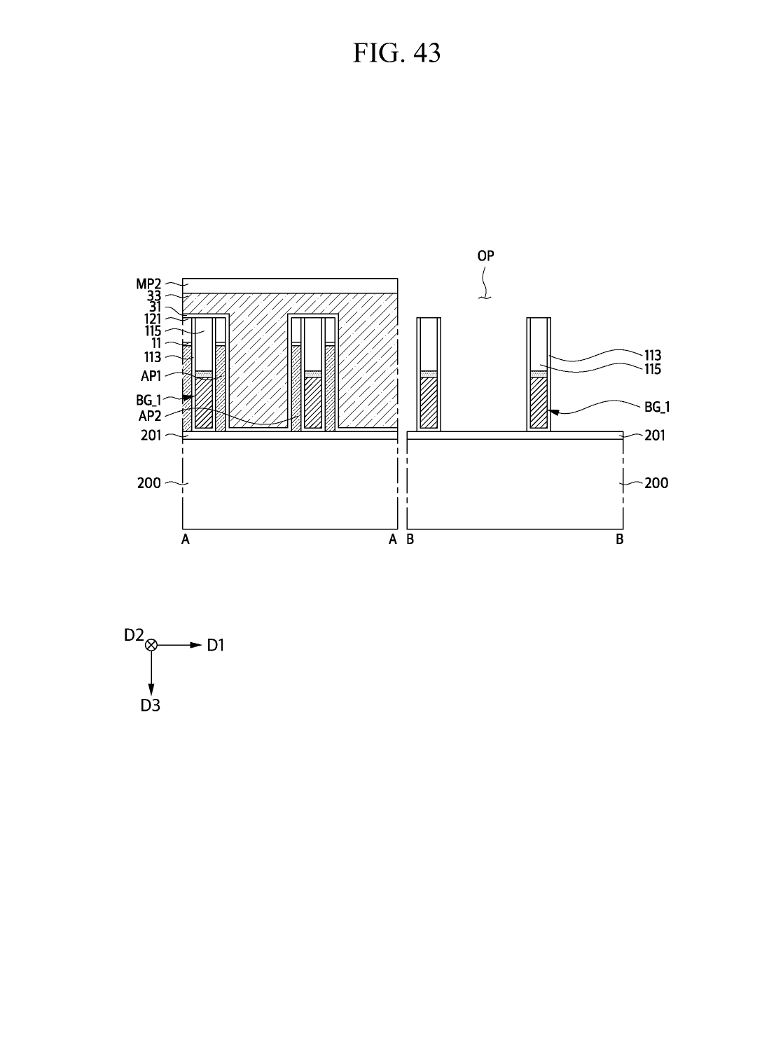

According to some example embodiments, after the sacrificial layer 33 is filled within the opening OP of FIGS. 42 to 44, the second mask pattern MP2 of FIGS. 42 - 44 may be removed. In order to expose the upper surface of the back gate capping pattern 115, a planarization process on the sacrificial layer 33 and the etch stop layer 31 may be performed. Subsequently, the spacer pattern 121 of FIG. 43 and the first lower mask layer 11 of FIG. 43 may be removed. Through this, the first active pattern AP1 and the second active pattern AP2 may be exposed. The spacer pattern 121 of FIG. 43 and the first lower mask layer 11 of FIG. 43 may be removed using a planarization process, but are not limited thereto.

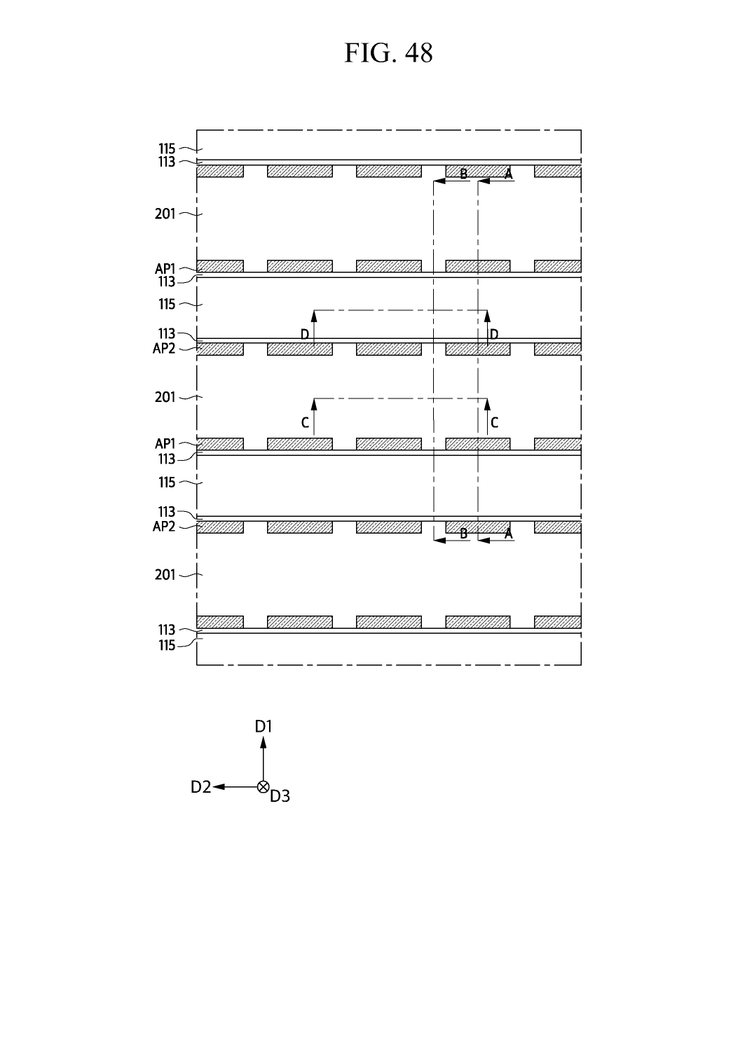

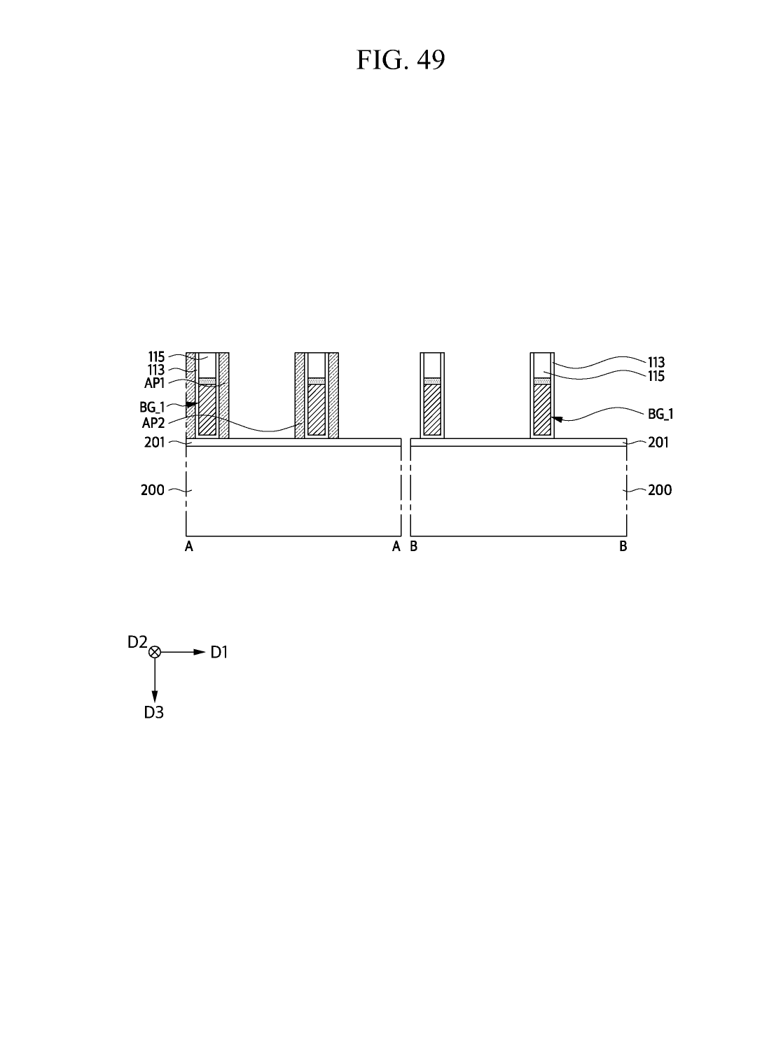

Referring to FIGS. 48 - 50, the sacrificial layer 33 of FIGS. 45 - 47 and the etch stop layer 31 of FIGS. 45 -47 on the buried insulating layer 201 may be removed. Through this, the buried insulating layer 201 may be exposed.

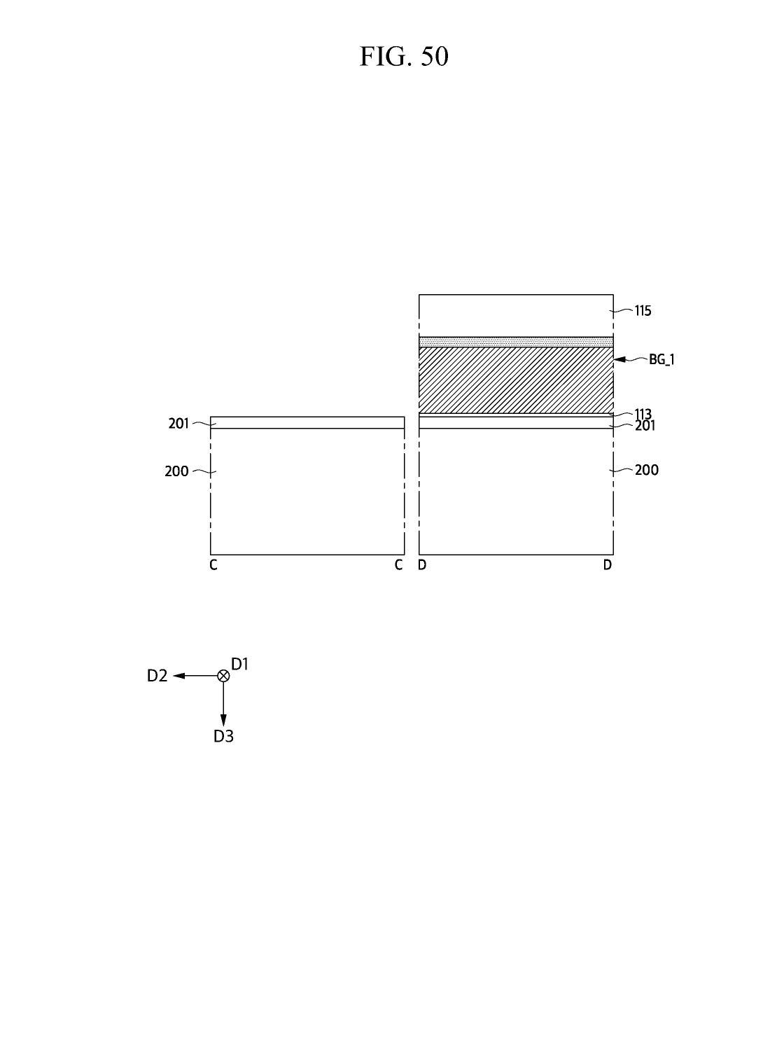

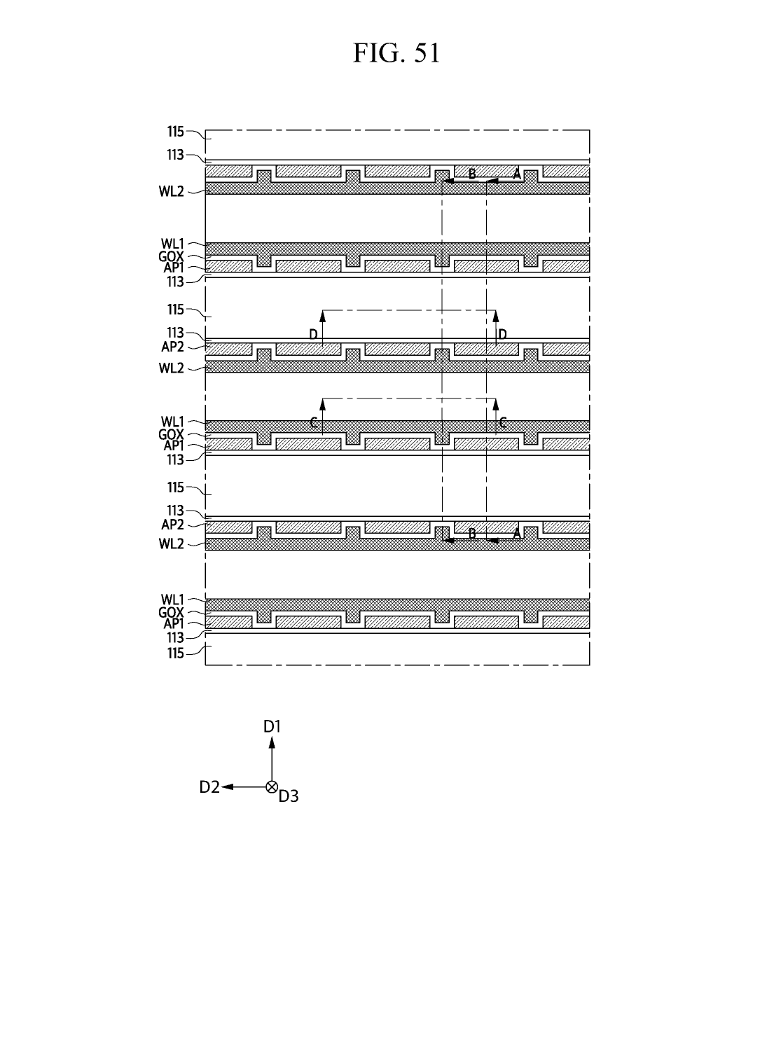

Referring to FIGS. 51 - 53, the gate insulating pattern GOX may be formed along a side surface of the first active pattern AP1, a side surface of the second active pattern AP2, the upper surface of the back gate capping pattern 115, and the upper surface of the buried insulating layer 201.

According to some example embodiments, the gate insulating pattern GOX may be formed using at least one of physical vapor deposition (PVD), thermal chemical vapor deposition (CVD), low pressure chemical vapor deposition (LPCVD), plasma enhanced chemical vapor deposition (PECVD), and atomic layer deposition (ALD) techniques, but is not limited thereto.

Subsequently, the first word line WL1 and the second word line WL2 may be formed on the gate insulating pattern GOX. The first word line WL1 and the second word line WL2 may be formed on the side surface of the first active pattern AP1 and the side surface of the second active pattern AP2. Forming the first word line WL1 and the second word line WL2 may include depositing a gate conductive layer on the gate insulating pattern GOX and then performing an anisotropic etching process on the gate conductive layer. Here, a deposition thickness of the gate conductive layer may be smaller than half a width of the word line trench WL_T of FIGS. 34 and 35 along the first direction D1.

According to some example embodiments, in the anisotropic etching process on the gate conductive layer, the gate insulating pattern GOX may be used as an etch stop layer. The gate insulating pattern GOX may be over-etched, and the buried insulating layer 201 may be exposed. Based on the anisotropic etching process on the gate conductive layer, the first word line WL1 and the second word line WL2 may have various shapes. An upper surface of the first word line WL1 and an upper surface of the second word line WL2 may be positioned at a lower level than upper surfaces of the first active pattern AP1 and the second active pattern AP2.

As an example, after the first word line WL1 and the second word line WL2 are formed, a GPD process or a PLAD process may be performed. Through this, the first active pattern AP1 and the second active pattern AP2 may be doped with impurities through the gate insulating pattern GOX exposed by the first word line WL1 and the second word line WL2.

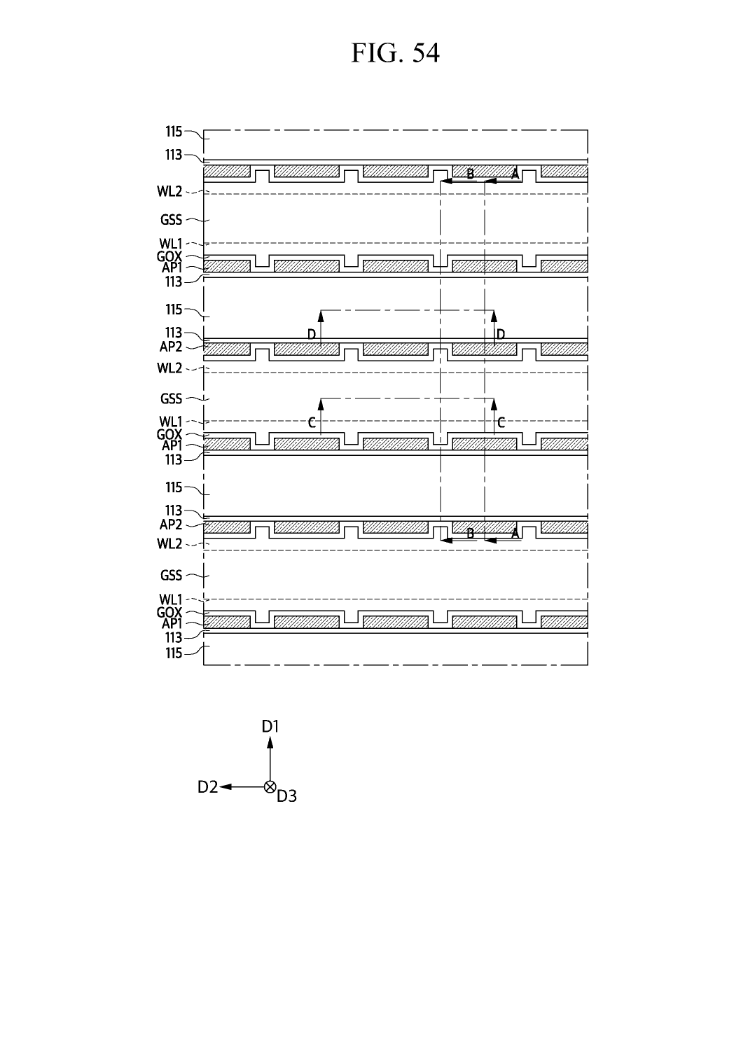

Referring to FIGS. 54 - 56, the gate separation pattern GSS may be formed on the first word line WL1 and the second word line WL2. For example, an upper surface of the gate separation pattern GSS may be placed on the same plane as the upper surface of the back gate capping pattern 115.

According to some example embodiments, a planarization process on the gate separation pattern GSS and the gate insulating pattern GOX may be performed such that the upper surfaces of the first active pattern AP1 and the second active pattern AP2 may be exposed. For example, the planarization process may include a chemical mechanical polishing (CMP) process, but is not limited thereto and changed in various manners.

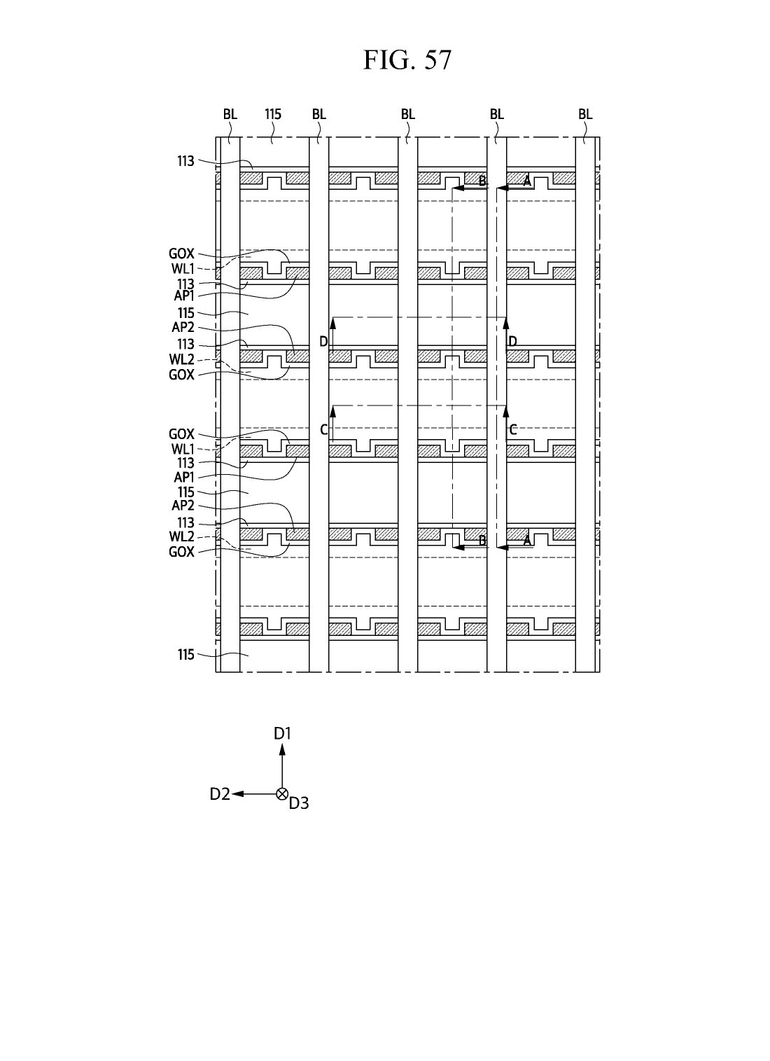

Referring to FIGS. 57 - 59, the bit line BL extending in the first direction D1 may be formed on the gate separation pattern GSS and the back gate capping pattern 115.

According to some example embodiments, the bit line BL may include the bit line mask pattern 165, the metal pattern 163, and the semiconductor pattern 161. While the bit line BL is formed, a portion of the back gate capping pattern 115 and a portion of the gate separation pattern GSS may be etched. For example, a portion of the back gate capping pattern 115 and a portion of the gate separation pattern GSS, over which the bit line BL is not provided in the third direction D3, may be etched more than the back gate capping pattern 115 and the gate separation pattern GSS over which the bit line BL is provided in the third direction D3. Upper surfaces of the back gate capping pattern 115 and the gate separation pattern GSS, over which the bit line BL is not provided in the third direction D3, may be disposed lower than upper surfaces of the back gate capping pattern 115 and the gate separation pattern GSS over which the bit line BL is provided in the third direction D3.

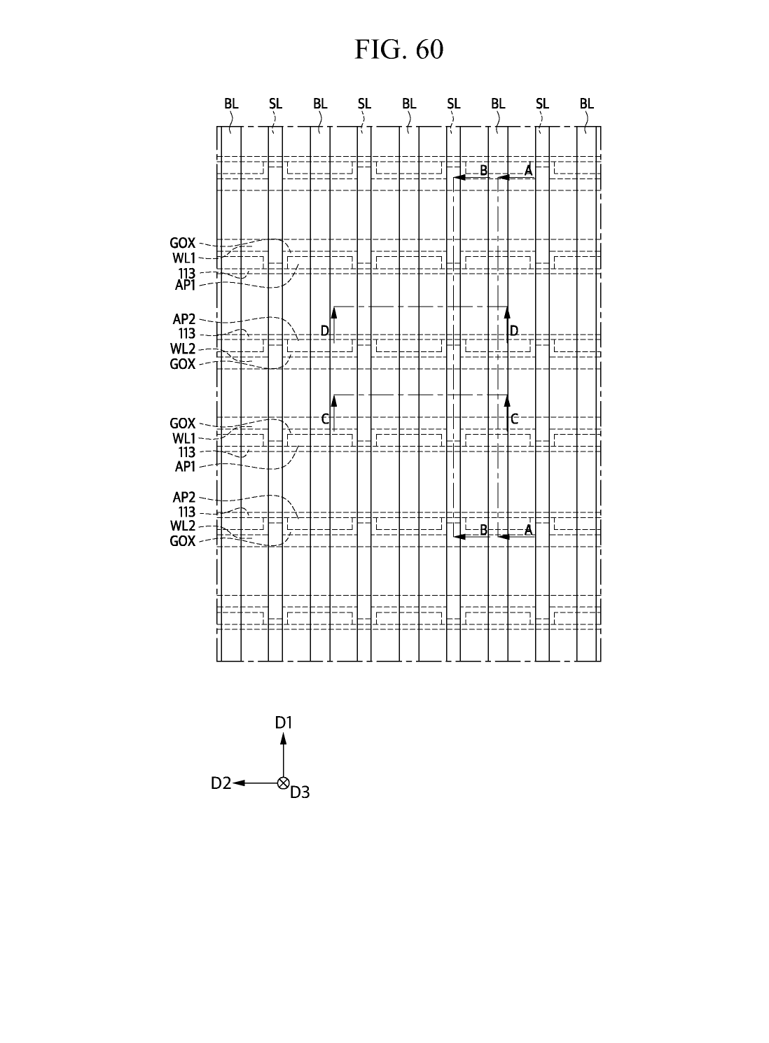

Referring to FIGS. 60 - 62, between the bit lines adjacent in the second direction D2, the shielding line SL may be formed.

According to some example embodiments, the shielding insulating liner 171 may be formed along the bit lines BL spaced apart in the second direction D2, the upper surface of the back gate capping pattern 115, and the upper surface of the gate separation pattern GSS. The shielding insulating liner 171 may define a shielding region between the bit lines BL adjacent in the second direction D2. The shielding line SL may be formed within the shielding region of the shielding insulating liner 171.

According to some example embodiments, the shielding line SL may be formed between the bit lines BL. As an example, forming the shielding line SL may include forming a shielding conductive layer for filling the shielding region on the shielding insulating liner 171 and recessing an upper surface of the shielding conductive layer. Subsequently, the shielding insulating capping layer 175 may be formed on the shielding line SL. The bonding insulating layer 263 of FIGS. 2 and 3 may be further formed on the shielding insulating capping layer 175, the shielding insulating liner 171, and the bit line BL.

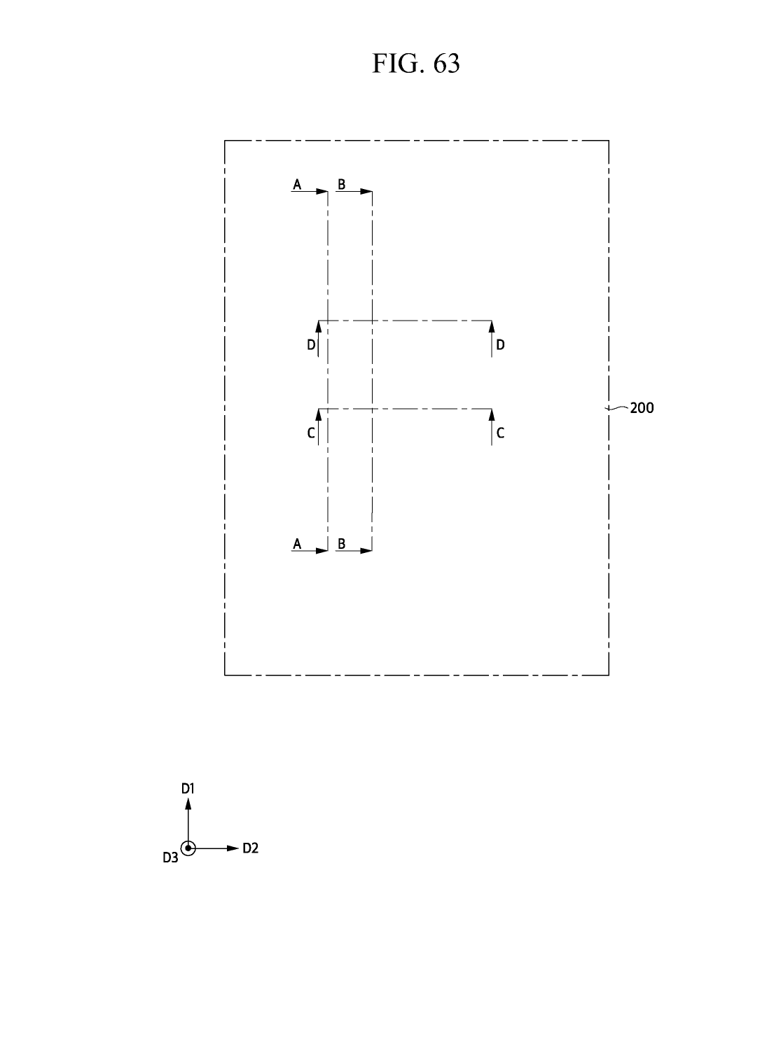

Referring to FIGS. 63 - 65, the sub-substrate 200 where the pre-back gate electrode BG_1, the plurality of word lines WL1 and WL2, the plurality of active patterns AP1 and AP2, the bit line BL, and the shielding line SL are formed may be bonded to the substrate 100. Using the bonding insulating layer 263, the substrate 100 and the sub-substrate 200 may be bonded.

According to some example embodiments, the peri-gate structure PG may be previously formed on the substrate 100. The peri-wiring line 241a and the peri-contact plug 241b may be formed above the substrate 100. A peri-upper insulating layer 265 may be formed in sequence above the peri-wiring line 241a and the peri-contact plug 241b. The bonding insulating layer 263 may be formed on the peri-upper insulating layer 265.

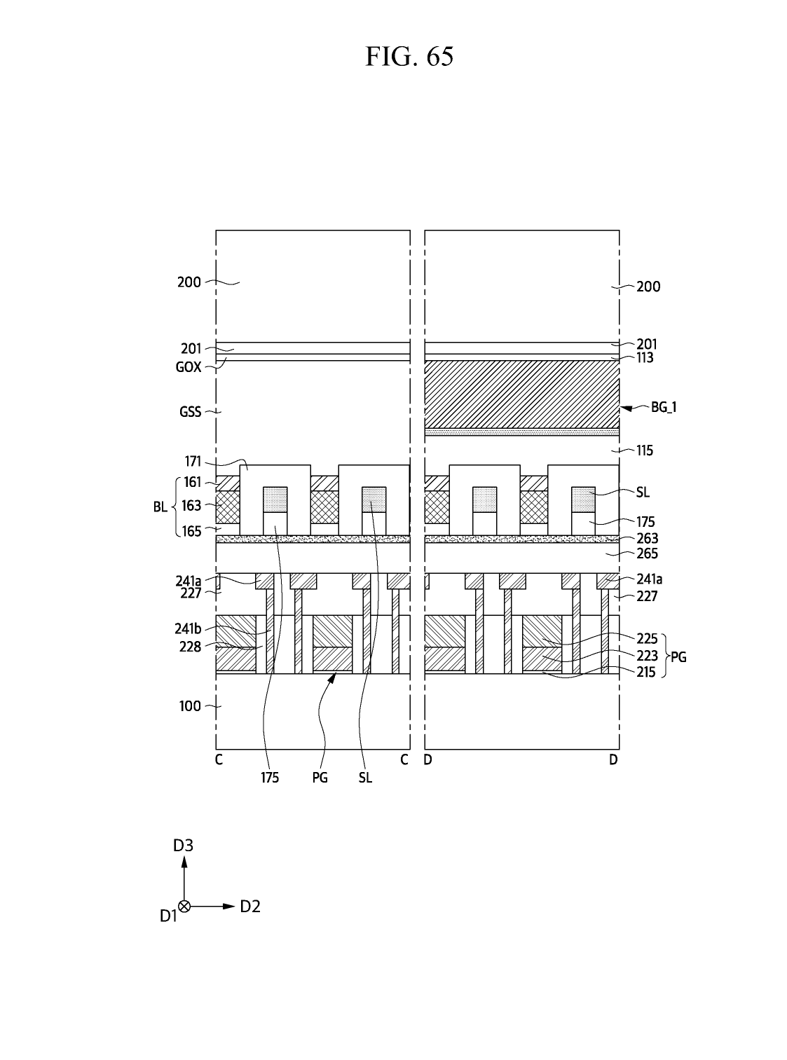

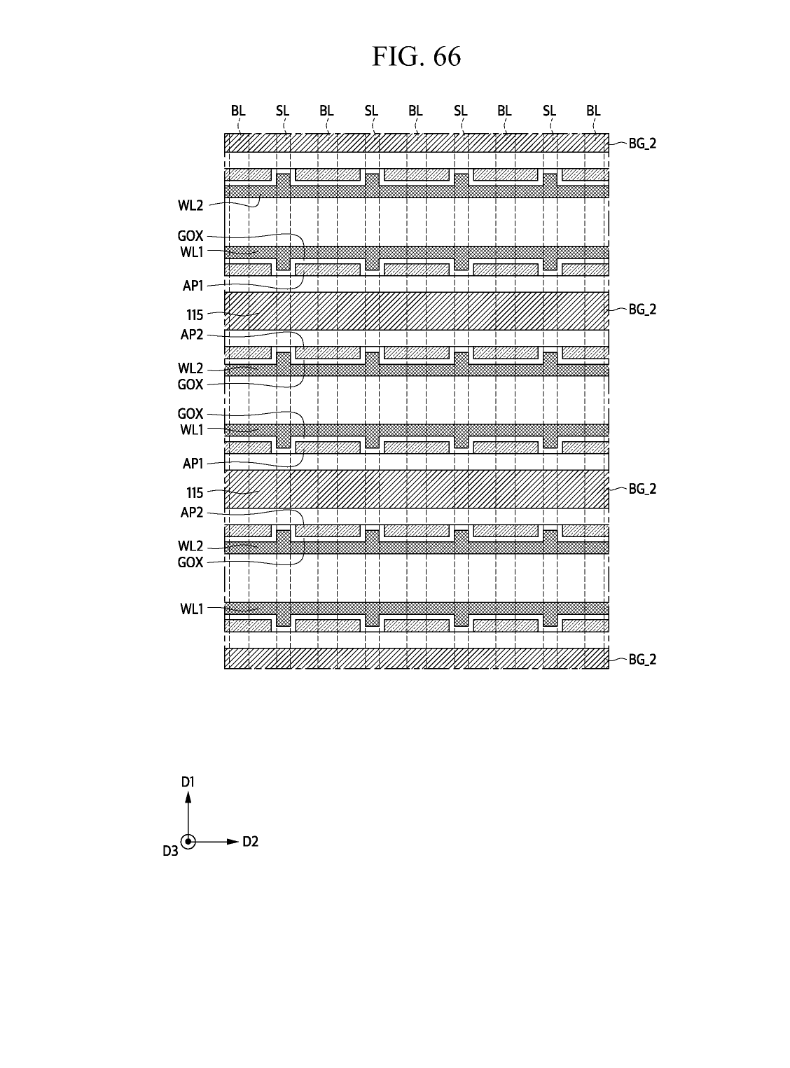

Referring to FIGS. 66 - 68, after the substrate 100 and the sub-substrate 200 of FIGS. 63 - 65 are bonded, a back lapping process for removing the sub-substrate 200 of FIGS. 63 - 65 may be performed. Removing the sub-substrate 200 of FIGS. 63 - 65 may include performing a grinding process and a wet etching process sequentially to expose the buried insulating layer 201 of FIGS. 63 - 65.

Subsequently, by removing the buried insulating layer 201 of FIGS. 63 - 65, the first active pattern AP1 and the second active pattern AP2 may be exposed. As the buried insulating layer 201 of FIGS. 63 - 65 is removed, a portion of the gate insulating pattern GOX and a portion of the back gate side insulating pattern 113 may be exposed.

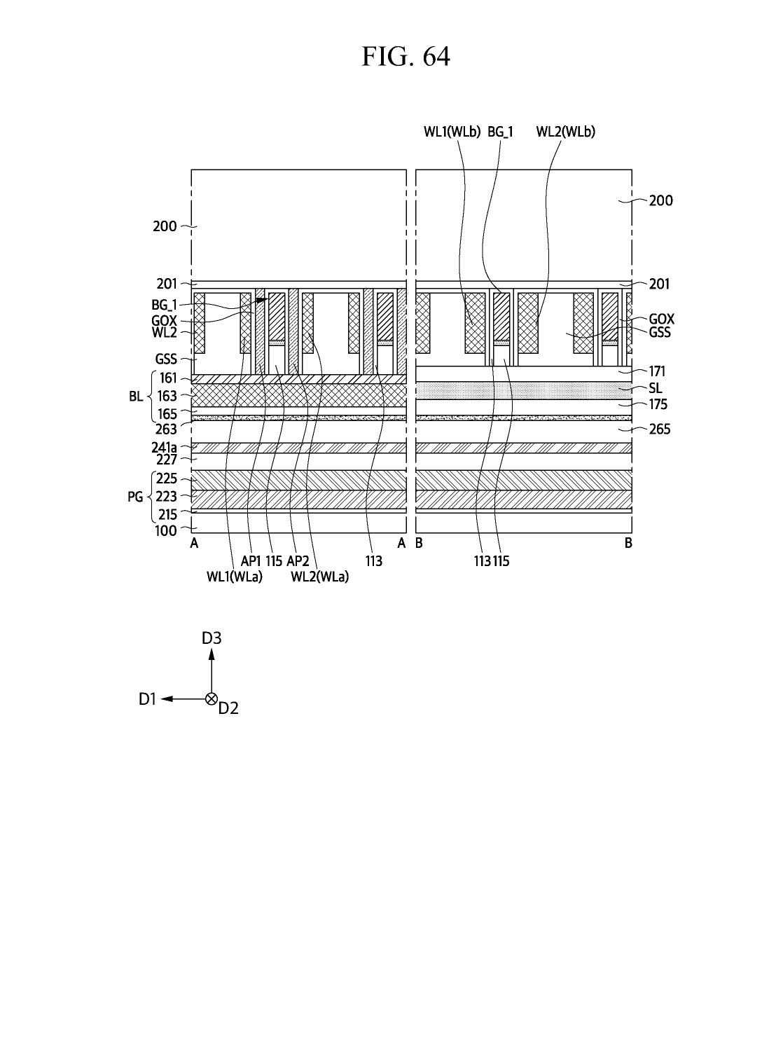

Subsequently, the exposed portions of the gate insulating pattern GOX and the back gate side insulating pattern 113 may be removed. Through this, the first pre-back gate electrode BG_1 of FIGS. 64 and 65, the first word line WL1, and the second word line WL2 may be exposed.

Subsequently, by performing an etch-back process, a portion of the first word line WL1 and a portion of the second word line WL2 may be removed. The gate capping pattern 143 may be formed on the first word line WL1 and the second word line WL2, which are recessed.

Subsequently, by performing the etch-back process, a portion of the first pre-back gate electrode BG_1 of FIGS. 64 and 65 may be removed. As the portion of the first pre-back gate electrode BG_1 of FIGS. 64 and 65 is removed, a second pre-back gate electrode BG_2 may be formed.

According to some example embodiments, a portion of the back gate body pattern 310 may be removed and a second back gate trench BG_T2 may be formed. A bottom surface of the second back gate trench BG_T2 may be disposed lower than the second surface WL_S2 of each of the first word line WL1 and the second word line WL2. After the portion of the back gate body pattern 310 is removed through the etch-back process, an upper surface of the back gate body pattern 310 exposed within the second back gate trench BG_T2 may be disposed lower than the second surface WL_S2 of each of the first word line WL1 and the second word line WL2.

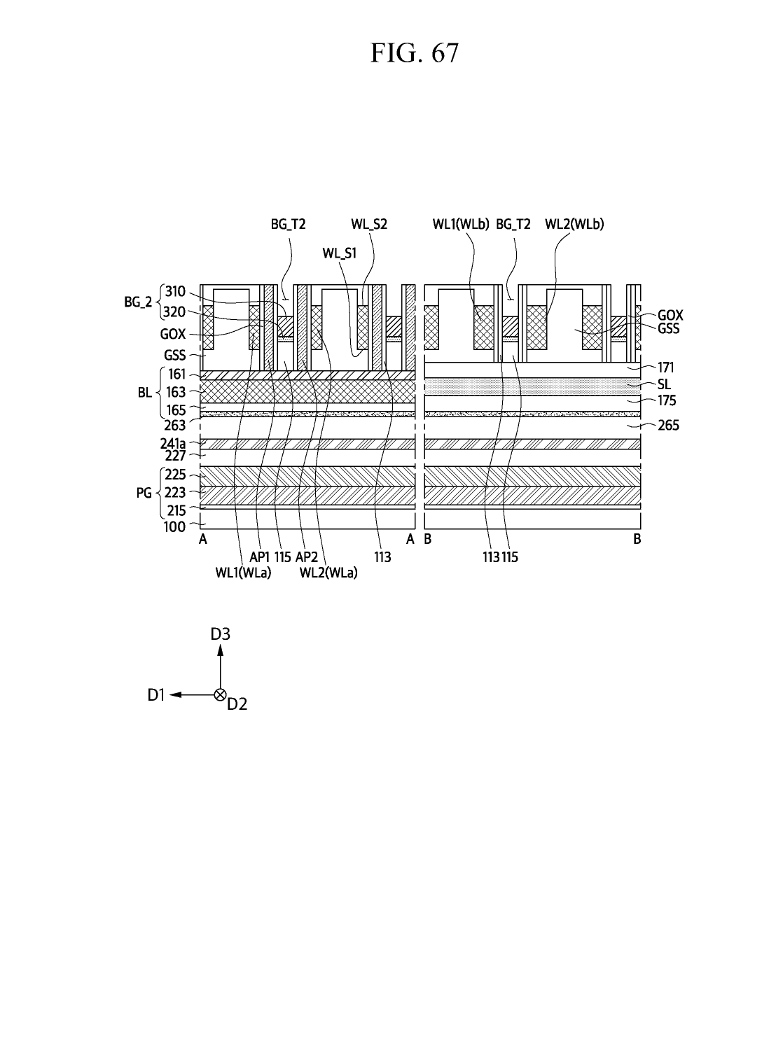

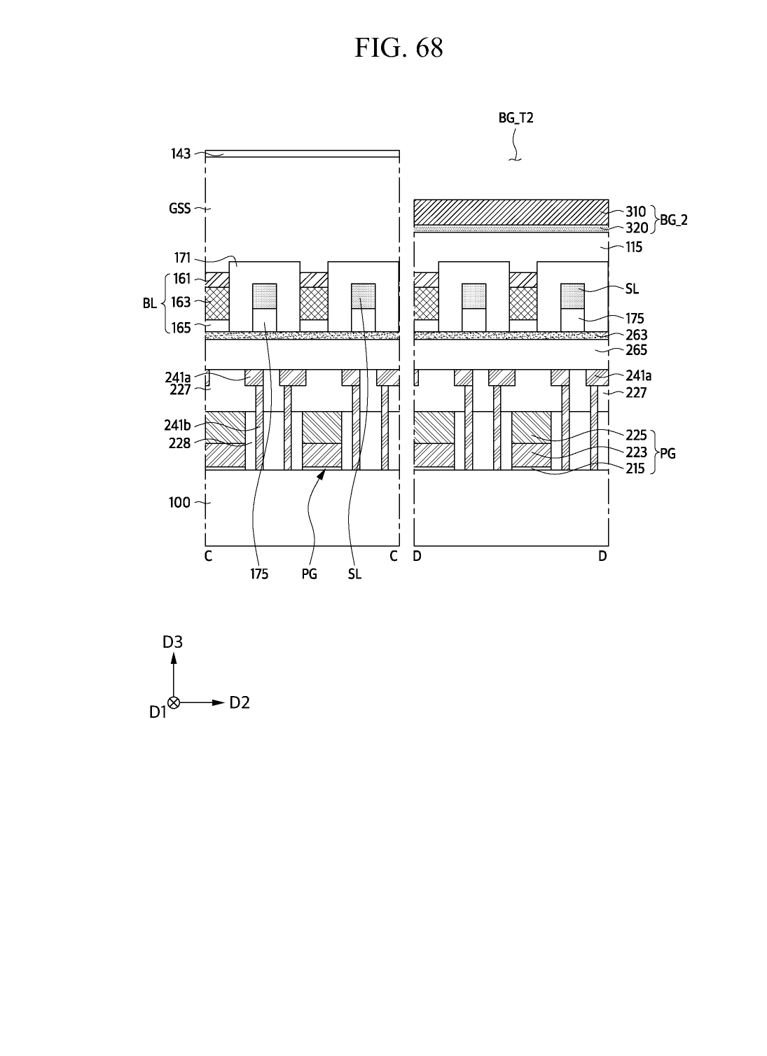

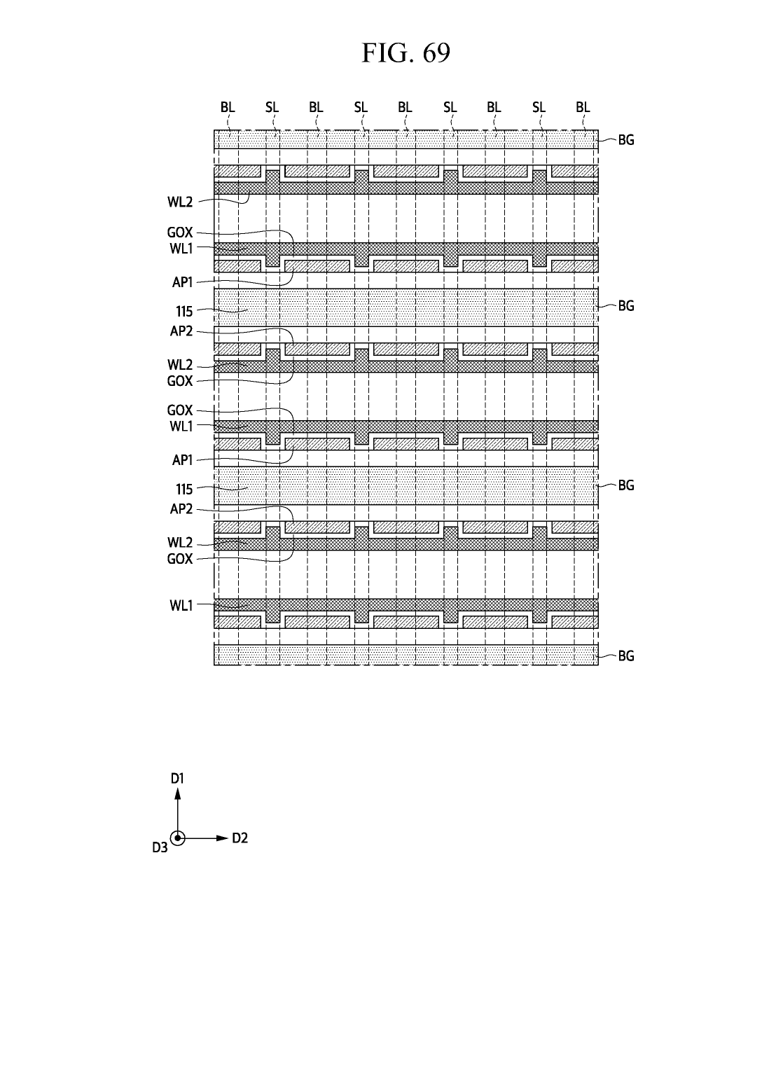

Referring to FIGS. 69 - 71, the back gate electrode structure BG may be formed. The second back gate work function adjustment pattern 330 and the back gate separation pattern 111 may be formed within the second back gate trench BG_T2 of FIGS. 67 and 68. The second back gate work function adjustment pattern 330 may be formed on the back gate body pattern 310. The back gate body pattern 310 may have a first surface facing the bit line BL and a second surface disposed opposite to the first surface in the third direction D3. The second back gate work function adjustment pattern 330 may be formed on the second surface of the back gate body pattern 310. The second back gate work function adjustment pattern 330 may be disposed lower than the second surface WL_S2 of each of the first word line WL1 and the second word line WL2.

Subsequently, referring to FIGS. 2 and 3, a contact hole for exposing the first active pattern AP1 and the second active pattern AP2 may be formed within the contact etch stop layer 212 and the contact separation insulating pattern 231. The contact pattern BC may be formed within the contact hole. The contact patterns BC may be formed on the first active pattern AP1 and the second active pattern AP2. The contact patterns BC may be connected to the first active pattern AP1 and the second active pattern AP2. The data storage patterns DSP may be formed above the contact patterns BC.

A method of fabricating a semiconductor device may include forming, within an active layer, a plurality of back gate trenches spaced apart from each other in a first direction parallel to a first surface of the active layer, extending in a second direction intersecting with the first direction, and penetrating at least a portion of the active layer in a third direction intersecting with the first direction and the second direction, forming a back gate body pattern and a first back gate work function adjustment pattern in sequence within the plurality of back gate trenches, forming, by patterning the active layer, a plurality of active patterns disposed at a side of each of the back gate body pattern and the first back gate work function adjustment pattern in the first direction and spaced apart from each other in the second direction, forming a plurality of word lines, each being disposed at a side of each of the plurality of active patterns in the first direction and extending in the second direction, forming, on first surfaces of the plurality of active patterns, a plurality of bit lines extending in the first direction and spaced apart from each other in the second direction, and forming a second back gate work function adjustment pattern on a second surface of the back gate body pattern disposed, in the third direction, opposite to a first surface of the back gate body pattern facing the bit line.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor device comprising:
a bit line extending in a first direction;
a word line extending in a second direction that intersecting the first direction, the word line being above the bit line in a third direction intersecting the first direction and the second direction;
a back gate electrode structure above the bit line in the third direction, spaced apart from the word line in the first direction, and extending in the second direction; and
an active pattern, on the bit line, between the word line and the back gate electrode structure in the first direction and extending in the third direction,
wherein a height of the back gate electrode structure in the third direction is smaller than a height of the word line in the third direction, and
wherein the back gate electrode structure comprises:
at least one back gate work function adjustment pattern; and
a back gate body pattern contacting the at least one back gate work function adjustment pattern in the third direction.

2. The semiconductor device of claim 1, wherein a work function of a material of the at least one back gate work function adjustment pattern is greater than a work function of a material of the back gate body pattern.

3. The semiconductor device of claim 1, wherein the at least one back gate work function adjustment pattern comprises:
a first back gate work function adjustment pattern on a first surface of the back gate body pattern in the third direction; and
a second back gate work function adjustment pattern on a second surface of the back gate body pattern opposite to the first surface of the back gate body pattern in the third direction.

4. The semiconductor device of claim 3, wherein a thickness of the first back gate work function adjustment pattern in the third direction is different from a thickness of the second back gate work function adjustment pattern in the third direction.

5. The semiconductor device of claim 3, wherein the back gate body pattern comprises:
a back gate body central portion between the first back gate work function adjustment pattern and the second back gate work function adjustment pattern;
a first buffer portion spaced apart from the back gate body central portion and in-between the first back gate work function adjustment pattern in the first direction; and
a second buffer portion spaced apart from the back gate body central portion and in-between the second back gate work function adjustment pattern in the first direction.

6. The semiconductor device of claim 5, wherein the first back gate work function adjustment pattern comprises:
a first horizontal portion between the back gate body central portion and the first buffer portion in the third direction; and
a first vertical portion protruding from the first horizontal portion toward the bit line and at a side of the first buffer portion in the first direction.

7. The semiconductor device of claim 3, wherein the back gate body pattern comprises:
a back gate body central portion between the first back gate work function adjustment pattern and the second back gate work function adjustment pattern in the third direction;
a first protruding portion protruding from the back gate body central portion through the first back gate work function adjustment pattern in the third direction; and
a second protruding portion protruding from the back gate body central portion through the second back gate work function adjustment pattern in the third direction.

8. The semiconductor device of claim 7, wherein, in the third direction, a lower surface of the first protruding portion and a lower surface of the first back gate work function adjustment pattern are substantially coplanar, and
wherein, in the third direction, an upper surface of the second protruding portion and an upper surface of the second back gate work function adjustment pattern are substantially coplanar.

9. The semiconductor device of claim 1, wherein a first surface of the back gate electrode structure facing the bit line in the third direction is substantially coplanar with a first surface of the word line facing the bit line in the third direction or is higher than the first surface of the word line with respect to the bit line.

10. The semiconductor device of claim 1, wherein a second surface of the back gate electrode structure disposed, in the third direction, opposite to a first surface of the back gate electrode structure facing the bit line in the third direction is substantially coplanar with a second surface of the word line disposed, in the third direction, opposite to a first surface of the word line facing the bit line in the third direction or is lower than the second surface of the word line with respect to the bit line.

11. The semiconductor device of claim 1, wherein the back gate work function adjustment pattern contacts the back gate body pattern.

12. The semiconductor device of claim 1, wherein the at least one back gate work function adjustment pattern is spaced apart from the back gate body pattern in the third direction, and
wherein the at least one back gate electrode structure further comprising a back gate interlayer insulating pattern between the back gate work function adjustment pattern and the back gate body pattern in the third direction.

13. The semiconductor device of claim 1, wherein the word line comprises:
a word line work function adjustment pattern; and
a word line body pattern contacting the word line work function adjustment pattern in the third direction.

14. The semiconductor device of claim 13, wherein a work function of a material of the word line work function adjustment pattern is smaller than a work function of a material of the word line body pattern.

15. A semiconductor device comprising:
a plurality of bit lines extending in a first direction and spaced apart from each other in a second direction intersecting the first direction;
a back gate electrode structure extending in the second direction and being above the plurality of bit lines in a third direction intersecting the first direction and the second direction;
a first active pattern on the plurality of bit lines, at a first side of the back gate electrode structure in the first direction and extending in the third direction;
a second active pattern on the plurality of bit lines, at a second side of the back gate electrode structure in the first direction and extending in the third direction;
a first word line above the plurality of bit lines in the third direction, at the first side of the back gate electrode structure and spaced apart from the back gate electrode structure in the first direction with the first active pattern in–between in the first direction; and
a second word line above the plurality of bit lines in the third direction, at the second side of the back gate electrode structure and spaced apart from the back gate electrode structure in the first direction with the second active pattern in-between in the first direction,
wherein the back gate electrode structure comprises a first back gate work function adjustment pattern, a back gate body pattern, and a second back gate work function adjustment pattern, which are stacked in sequence in the third direction, and
wherein a work function of each of the first back gate work function adjustment pattern and the second back gate work function adjustment pattern is greater than a work function of the back gate body pattern.

16. The semiconductor device of claim 15, wherein a height of each of the first word line and the second word line in the third direction is greater than a height of the back gate electrode structure in the third direction and smaller than a height of each of the first active pattern and the second active pattern in the third direction.

17. The semiconductor device of claim 15, wherein the first back gate work function adjustment pattern, the back gate body pattern, and the second back gate work function adjustment pattern are overlapped by the first word line and the second word line when viewed from the first direction.

18. The semiconductor device of claim 15, wherein at least one of the first back gate work function adjustment pattern and the second back gate work function adjustment pattern comprises a multilayer structure.

19. The semiconductor device of claim 15, further comprising:
a shielding line between the plurality of bit lines in the second direction and below the back gate electrode structure, the first word line, and the second word line in the third direction.

20. A semiconductor device comprising:
a bit line extending in a first direction;
a word line extending in a second direction intersecting the first direction, the word line being above the bit line in a third direction intersecting the first direction and the second direction;
a back gate electrode structure above the bit line in the third direction, spaced apart from the word line in the first direction and extending in the second direction;
an active pattern on the bit line, between the word line and the back gate electrode structure in the first direction and extending in the third direction; and
a data storage pattern above the active pattern in the third direction and connected to the active pattern,
wherein a first surface and a second surface of the back gate electrode structure in the third direction are between a first surface and a second surface of the word line in the third direction,
wherein the back gate electrode structure comprises a first back gate work function adjustment pattern, a back gate body pattern, and a second back gate work function adjustment pattern, which are stacked in sequence in the third direction, and
wherein a work function of each of the first back gate work function adjustment pattern and the second back gate work function adjustment pattern is greater than a work function of the back gate body pattern.
